(19) United States
(12) Patent Application Publication
(10) Pub. No.: US 2026/0082534 A1
(43) Pub. Date: Mar. 19, 2026

(54) MEMORY DEVICES BASED ON CFET STRUCTURE AND METHODS FOR MANUFACTURING THE SAME

(71) Applicant: Taiwan Semiconductor Manufacturing Company, Ltd., Hsinchu (TW)

(72) Inventors: Ping-Wei Wang, Hsinchu City (TW); Jui-Lin Chen, Hsinchu City (TW); Lien-Jung Hung, Hsinchu City (TW)

(73) Assignee: Taiwan Semiconductor Manufacturing Company, Ltd., Hsinchu (TW)

(21) Appl. No.: 19/018,563

(22) Filed: Jan. 13, 2025

Related U.S. Application Data
(60) Provisional application No. 63/695,506, filed on Sep. 17, 2024.

(51) Int. Cl. H10B 10/00

(52) U.S. Cl. CPC H10B 10/125

(57) ABSTRACT

A device includes a substrate having a first side and a second side; a first transistor, a second transistor, a third transistor, and a fourth transistor formed on the first side, the first to fourth transistors each formed with a p-type conductivity; a fifth transistor and a sixth transistor formed on the first side and over the first to fourth transistors, the fifth to sixth transistors each formed with an n-type conductivity; first interconnect structures formed on the first side and over the fifth to sixth transistors, each of the first interconnect structures coupled at least to the fifth and sixth transistors and configured to carry a supply voltage; and second interconnect structures formed on the second side, each of the second interconnect structures coupled at least to the first and second transistors and configured to carry a ground voltage.

### CROSS-REFERENCE TO RELATED APPLICATION

This application claims priority to and the benefit of U.S. Provisional Application No. 63/695,506, filed Sep. 17, 2024, entitled “CFET SRAM with NPMOS SWAP,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example circuit diagram of a memory cell, in accordance with some embodiments.

FIGS. 2-5 illustrate layouts that are collectively configured to form the memory cell of FIG. 1 in a CFET structure, in accordance with some embodiments.

FIGS. 6-9 illustrate layouts that are collectively configured to form the memory cell of FIG. 1 in a CFET structure, in accordance with some embodiments.

FIGS. 10-14 illustrate cross-sectional views of a portion of a semiconductor device include the memory cell formed based on the layouts of FIGS. 2-5, in accordance with some embodiments.

FIG. 15 illustrates an example circuit diagram of another memory cell, in accordance with some embodiments.

FIGS. 16-19 illustrate layouts that are collectively configured to form the memory cell of FIG. 15 in a CFET structure, in accordance with some embodiments.

FIGS. 20-23 illustrate layouts that are collectively configured to form the memory cell of FIG. 15 in a CFET structure, in accordance with some embodiments.

FIG. 24 illustrates the perspective view of a portion of a memory cell formed in a CFET structure, in accordance with some embodiments.

FIG. 25 illustrates an example flow chart of a method for forming a semiconductor device including a memory cell configured with a CFET structure, in accordance with some embodiments.

FIGS. 26-34 illustrate cross-sectional views of an example semiconductor device during various fabrication stages, made by the method of FIG. 25, in accordance with some embodiments.

FIG. 35 illustrates an example flow chart of a method for forming a semiconductor device including a memory cell configured with a CFET structure, in accordance with some embodiments.

FIGS. 36-46 illustrate cross-sectional views of an example semiconductor device during various fabrication stages, made by the method of FIG. 35, in accordance with some embodiments.

FIGS. 47-48 illustrate layouts that are collectively configured to form the memory cell of FIG. 1 in a CFET structure, in accordance with some embodiments.

FIGS. 49-50 illustrate cross-sectional views of a portion of a semiconductor device include the memory cell formed based on the layouts of FIGS. 47-48, in accordance with some embodiments.

FIGS. 51-52 illustrate layouts that are collectively configured to form the memory cell of FIG. 15 in a CFET structure, in accordance with some embodiments.

FIGS. 53-54 illustrate cross-sectional views of a portion of a semiconductor device include the memory cell formed based on the layouts of FIGS. 51-52, in accordance with some embodiments.

FIG. 55 illustrates an example circuit diagram of yet another memory cell, in accordance with some embodiments.

FIGS. 56-57 illustrate layouts that are collectively configured to form the memory cell of FIG. 55 in a CFET structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary field-effect transistors (CFETs) are one type of gate-all-around (GAA) field-effect transistors. In general, a GAA FET includes a plural number of nanostructures, such as nanosheets or nanowires, vertically stacked on top of one another. P-type and n-type GAA FETs are formed on the same horizontal plane over a substrate and are separated by isolation structures. In contrast, a CFET is commonly fabricated by vertically stacking a p-type GAA FET and an n-type GAA FET on top of each other. This stacking configuration of n-type and p-type transistors in a single structure eliminates the need for an n-to-p separation, reduces the active area footprint, and increases the transistor density within a chip. This stacking concept is not limited to GAA FETs; for example, CFETs can be formed with FinFET devices or with a combination of GAA FETs and FinFETs.

It has been proposed to form static random access memory (SRAM) cells based on the CFET structures. For example, to form an SRAM cell with six transistors (6 T) generally referred to as a 6 T SRAM cell, a first level including a first pull-up transistor and a second pull-up transistor is first formed on the frontside of a substrate, followed by a second level including a first pull-down transistor, a second pull-down transistor, a first pass-gate transistor, and a second pass-gate transistor formed over the first level (on the frontside of the substrate). In the existing SRAM cells, the pull-up transistors are commonly formed with a p-type conductivity and the pull-down and pass-gate transistors are commonly formed with an n-type conductivity.

With the n-type pull-down transistors formed over the p-type transistors, a tap cell or filler cell is commonly needed for forming a via structure extending from the second level through the substate to a backside of the substrate, when adopting a backside power grid (BPG)/buried power rail (BPR) configuration. In the BPG/BPR configuration, a number of interconnect structures, configured to carry a reference or ground voltage (e.g., VSS), are formed on the backside of the substrate. Such additional tap cells disadvantageously take up a relatively large amount of area. Further, due to the extensive length of the via structure, the VSS may be received by the SRAM cell with additional IR drop. Thus, the existing CFET structures for forming memory cells have not been entirely satisfactory in certain aspects.

The present disclosure provides various embodiments of a semiconductor device (e.g., a memory device) formed in a CFET structure that has two frontside levels for forming respectively different conductive types of transistors. For example, the memory device may include one or more SRAM cells. Different from the existing SRAM cells formed with the CFET structure, the SRAM cell, according to one embodiment of the present disclosure, can include p-type pull-down transistors and p-type pass-gate transistors formed in one of the two frontside levels, and n-type pull-up transistors formed in the other of the two frontside levels. With the p-type pull-down transistors formed in the first frontside level, no additional tap cell configured for carrying VSS is needed. Those p-type pull-down transistors can be coupled to one or more backside interconnect structures carrying VSS. Further, by forming the pass-gate transistors and pull-down transistors in p-type, various performance of the disclosed SRAM cell can be significantly improved. For instance, a minimum voltage for a write operation can be reduced by about 30˜50 millivolts (mV), and/or during a read operation, the voltage difference between a bit line and bit line bar can be increased due to minimum threshold voltage loss across either of the pass-gate transistors. According to another embodiment of the present disclosure, the SRAM cell can include p-type pass-gate transistors formed in one of the two frontside levels, and n-type pull-up transistors and n-type pull-down transistors formed in the other of the two frontside levels. Similarly, with the pass-gate transistors formed in p-type, the performance of the disclosed SRAM cell can be improved.

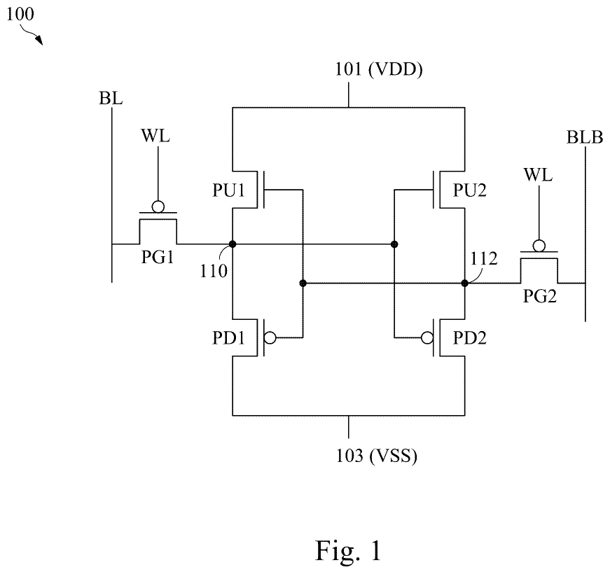

FIG. 1 illustrates an example circuit diagram of a memory cell 100, in accordance with some embodiments. As shown, the memory cell 100 includes six transistors that operatively form a 6 T SRAM cell. In various embodiments, the six transistors can be physically formed with a CFET structure which will be discussed below. The memory cell 100 includes six transistors: a first pull-up transistor PU1, a second pull-up transistor PU2, a first pull-down transistor PD1, a second pull-down transistor PD2, a first pass-gate transistor PG1, and a second pass-gate transistor PG2.

The transistors PU1 and PD1 are formed as a first inverter and the transistors PU2 and PD2 are formed as a second inverter, wherein the first and second inverters are cross coupled to each other. Specifically, the first and second inverters are each coupled between first voltage reference 101 and second voltage reference 103. In some embodiments, the first voltage reference 101 is a supply voltage applied to the memory cell 100, sometimes referred to as “VDD,” and the second voltage reference 103 is a ground voltage, sometimes referred to as “VSS.” The first inverter (formed by the transistors PU1 and PD1) is coupled to the transistor PG1, and the second inverter (formed by the transistors PU2 and PD2) is coupled to the transistor PG2. In addition to being coupled to the first and second inverters, the transistors PG1 and PG2 are each coupled to a word line (WL) and are coupled to a bit line (BL) and a bit line bar (BLB), respectively.

In some embodiments, the transistors PU1 and PU2 each include an n-type metal-oxide-semiconductor (NMOS) transistor, and the transistors PD1, PD2, PG1, and PG2 each include a p-type metal-oxide-semiconductor (PMOS) transistor. Although the illustrated embodiment of FIG. 1 shows that the transistors of the memory cell 100 are either NMOS or PMOS transistors, any of a variety of transistors or devices that are suitable for use in a memory device may be implemented as at least one of the transistors of the memory cell 100 such as, for example, a bipolar junction transistor (BJT), a high-electron-mobility transistor (HEMT), etc. Further, as will be discussed below, the p-type transistors, PG1, PG2, PD1, and PD2, are each formed as a GAA FET in a first level disposed on the frontside of a substate, and the n-type transistors, PU1 and PU2, are each formed as a GAA FET in a second level over the first level.

The transistors PG1 and PG2 each have a gate terminal coupled to the WL. The gate terminals of the transistors PG1 and PG2 are configured to receive a pulse signal, through the WL, to allow or block an access (e.g., a read operation, a write operation) of the memory cell 100 accordingly. The transistors PD1 and PU1 are coupled between VDD and VSS, and coupled to each other at node 110. For example, the transistor PU1 has a first source/drain terminal connected to VDD and the transistor PD1 has a first source/drain terminal connected to VSS, with the transistors PU1 and PD1 having their second source/drain terminals connected to each other at node 110. The transistor PG1 has a first source/drain terminal connected to the BL and a second source/drain terminal connected to node 110, which is further coupled to gate terminals of the transistors PU2 and PD2. Similarly, the transistors PD2 and PU2 are coupled between VDD and VSS, and coupled to each other at node 112. For example, the transistor PU2 has a first source/drain terminal connected to VDD and the transistor PD2 has a first source/drain terminal connected to VSS, with the transistors PU2 and PD2 having their second source/drain terminals connected to each other at node 112. The transistor PG2 has a first source/drain terminal connected to the BLB and a second source/drain terminal connected to node 112, which is further coupled to gate terminals of the transistors PU1 and PD1.

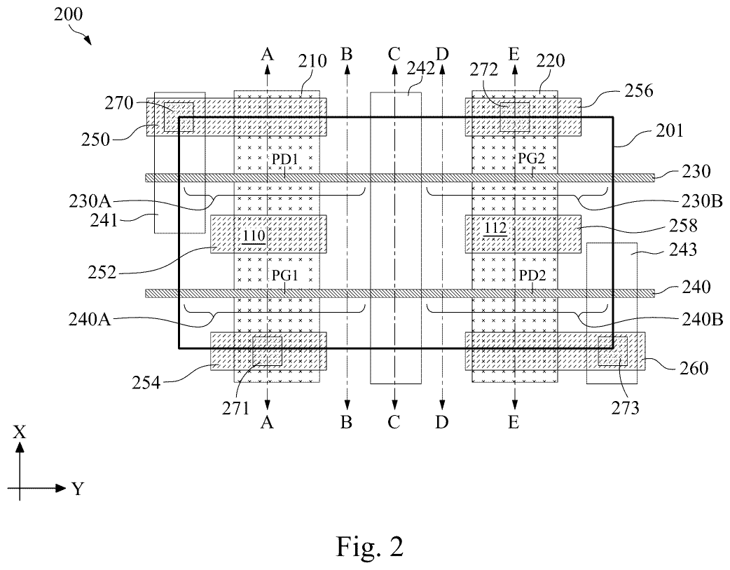

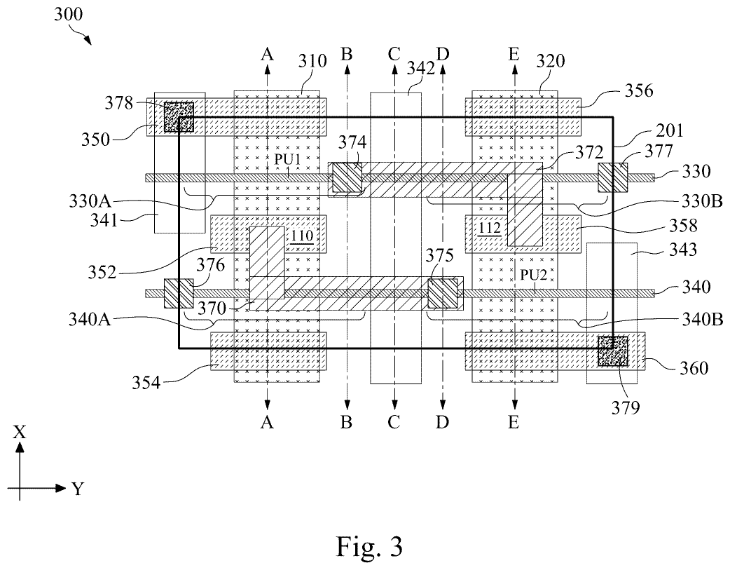

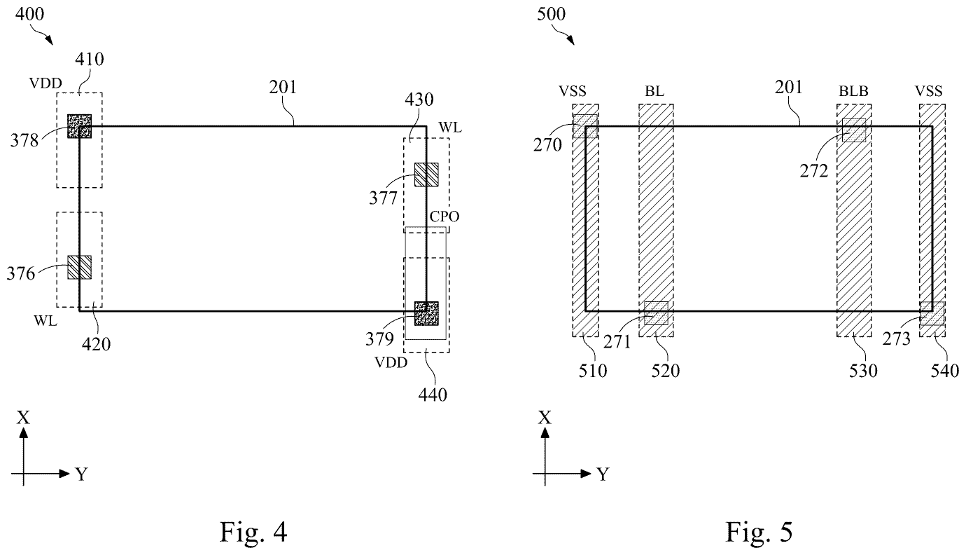

FIG. 2, FIG. 3, FIG. 4, and FIG. 5 respectively illustrate layouts 200, 300, 400, and 500 that can be collectively utilized to form the memory cell 100 (FIG. 1) configured in a CFET structure. As depicted, each of the layouts 200 to 500 includes a cell boundary 201 defining a physical area of the memory cell 100. The CFET structure can include a number of first transistors disposed at a first level on the frontside of a substate, and a number of second transistors disposed at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 200 to 500 can include a number of patterns configured for forming respective structures, and thus, such patterns of the disclosed layout are herein referred to as the structures to be formed, respectively, in the following discussion. For example, the layout 200 is configured to form structures of the first transistors at the first level on the frontside; and the layout 300 is configured to form structures of the second transistors at the second level on the frontside. Further, the layout 400 is configured to form the structures at a third level on the frontside of the substrate, over the second level; and the layout 500 is configured to form a first level on a backside of the substrate. It should be understood that each of the layouts 200 to 500 has been simplified for illustrative purposes, and thus, can include any of various other patterns while remaining within the scope of the present disclosure.

Referring first to FIG. 2, the layout 200 can include patterns for forming active regions 210 and 220 and gate structures 230 and 240, respectively. The active regions 210 and 220 may extend in the X-direction; and the gate structures 230 and 240 may extend in the Y-direction. Each of the active regions 210 and 220 may be formed as a fin structure or a stack structure extending along the X-direction, and each of the gate structures 230 and 240 may be formed to extend in the Y-direction to traverse the active regions 230 and 240. The layout 200 can further include a number of cut patterns, e.g., 241, 242, and 243, each of which can extend along the X-direction traversing one or more of the gate structures 230-240. The cut patterns 241 to 243 can each be configured to form a dielectric structure, thereby dividing one or more of the gate structures 230-240 into separate gate sections. For example, the cut pattern 242 can divide the gate structure 230 into gate sections 230A and 230B, and divide the gate structure 240 into gate sections 240A and 240B, as indicated in FIG. 2.

Referring next to FIG. 3, the layout 300 can include patterns for forming active regions 310 and 320 and gate structures 330 and 340, respectively. The active regions 310 and 320 may extend in the X-direction; and the gate structures 330 and 340 may extend in the Y-direction. Each of the active regions 310 and 320 may be formed as a fin structure or a stack structure extending along the X-direction, and each of the gate structures 330 and 340 may be formed to extend in the Y-direction to traverse the active regions 330 and 340. The layout 300 can further include a number of cut patterns, e.g., 341, 342, and 343, each of which can extend along the X-direction traversing one or more of the gate structures 330-340. The cut patterns 341 to 343 can each be configured to form a dielectric structure, thereby dividing one or more of the gate structures 330-340 into separate gate sections. For example, the cut pattern 342 can divide the gate structure 330 into gate sections 330A and 330B, and divide the gate structure 340 into gate sections 340A and 340B, as indicated in FIG. 3.

In some embodiments, the active regions 210 and 310 are vertically aligned with each other, the active regions 220 and 320 are vertically aligned with each other, the gate structures 230 and 330 are vertically aligned with each other, the gate structures 240 and 340 are vertically aligned with each other, the cut patterns 241 and 341 are vertically aligned with each other, the cut patterns 242 and 342 are vertically aligned with each other, and the cut patterns 243 and 343 are vertically aligned with each other. Further, the active regions 210 and 310 may be physically formed as a single structure (sometimes referred to as “active region 210/310”), the active regions 220 and 320 may be physically formed as a single structure (sometimes referred to as “active region 220/320”), the gate structures 230 and 330 may be physically formed as a single structure (sometimes referred to as “gate structure 230/330”), and the gate structures 240 and 340 may be physically formed as a single structure (sometimes referred to as “gate structure 240/340”).

For example, the active region 210/310 and active region 220/320 can each be first formed as a stack structure protruding from the frontside surface of a substrate. The stack may include a number of first semiconductor nanostructures (e.g., first nanosheets) extending along the X-direction and vertically separated from each other, and a number of second semiconductor nanostructures (e.g., second nanosheets) extending along the X-direction and vertically separated from each other. The first nanosheets are positioned at the first level, and the second nanosheets are positioned at the second level. According to some embodiments of the present disclosure, the first nanosheets, formed based on a lower portion of the active region 210/310 or a lower portion of the active region 220/320, can partially form the first transistors formed at the first level; and the second nanosheets, formed based on an upper portion of the active region 210/310 or an upper portion of the active region 220/320, can partially form the second transistors formed at the second level. Further, the first nanosheets and the second nanosheets can be vertically aligned with but separated from each other, with at least one dielectric layer interposed therebetween.

Next, respective portions of the first and second nanosheets in each of the stacks that are overlaid by the gate structure 230/330 and the gate structure 240/340, which are initially formed as a number of dummy (e.g., polysilicon) gate structures, respectively, may remain. Other portions of the first nanosheets are replaced with a number of first epitaxial structures, and other portions of the second nanosheets are replaced with a number of second epitaxial structures. According to some embodiments of the present disclosure, the first epitaxial structures (at the first level) may be formed with a p-type conductivity, and the second epitaxial structures (at the second level) may be formed with an n-type conductivity. The first epitaxial structures can operatively form respective source/drain terminals of the first transistors at the first level, and the second epitaxial structures can operatively form respective source/drain terminals of the second transistors at the second level.

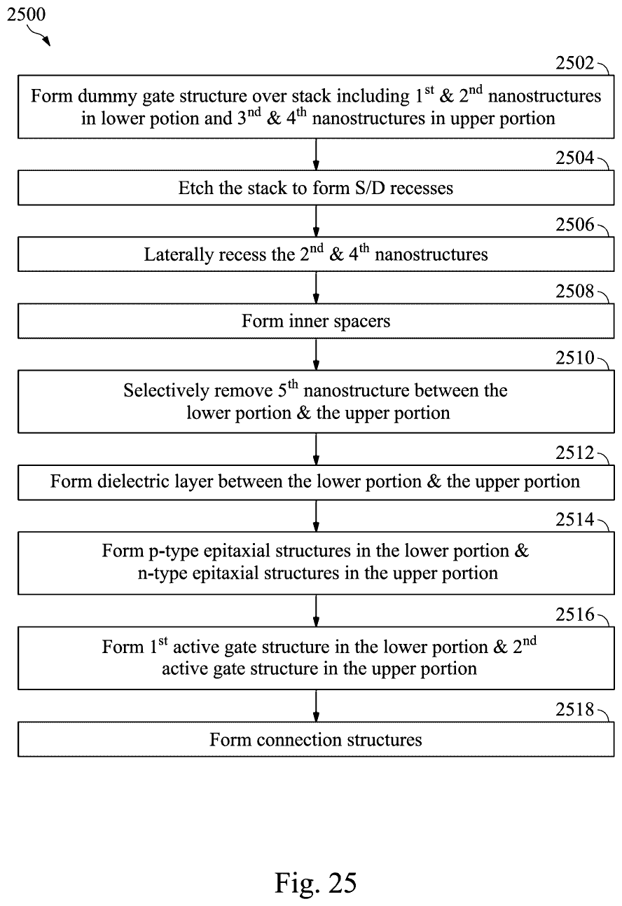

Next, each of the dummy gate structures 230/330 and 240/340 can be replaced by a corresponding active (e.g., metal) gate structure to form the first and second transistors. According to some embodiments of the present disclosure, each of the active gate structures can include a lower portion and an upper portion corresponding to the first level and the second level, respectively. For example, the lower portion of the active gate structure may include one or more first work function metals configured for forming a gate terminal of one of the first transistors with the p-type conductivity, and the upper portion of the active gate structure may include one or more second work function metals configured for forming a gate terminal of one of the second transistors with the n-type conductivity. Details of a series of manufacturing processes to form the structures of the first transistors at the first level and the second transistors at the second level will be described with respect to FIGS. 25-46.

As a brief overview, the transistors PD1, PD2, PG1, and PG2 of the memory cell 100 can be formed at the first level based on the layout 200 (as indicated in FIG. 2), and the transistors PU1 and PU2 of the memory cell 100 can be formed at the second level based on the layout 300 (as indicated in FIG. 3). Further, in some embodiments, the transistors PD1, PD2, PG1, and PG2 at the first level can be formed with the p-type conductivity, and the transistors PU1 and PU2 at the second level can be formed with the n-type conductivity.

For example, in FIG. 2, the transistor PD1 can include its channel, gate terminal, and source/drain terminals formed by a subset of the first nanosheets in the active region 210, the gate section 230A, and a subset of the first epitaxial structures formed from the active region 210 and disposed on opposite sides of the gate structure 230, respectively. The transistor PG1 can include its channel, gate terminal, and source/drain terminals formed by another subset of the first nanosheets in the active region 210, the gate section 240A, and another subset of the first epitaxial structures formed from the active region 210 and disposed on opposite sides of the gate structure 240, respectively. The transistor PD2 can include its channel, gate terminal, and source/drain terminals formed by yet another subset of the first nanosheets in the active region 220, the gate section 240B, and yet another subset of the first epitaxial structures formed from the active region 220 and disposed on opposite sides of the gate structure 240, respectively. The transistor PG2 can include its channel, gate terminal, and source/drain terminals formed by yet another subset of the first nanosheets in the active region 220, the gate section 230B, and yet another subset of the first epitaxial structures formed from the active region 220 and disposed on opposite sides of the gate structure 230, respectively.

For another example, in FIG. 3, the transistor PUI can include its channel, gate terminal, and source/drain terminals formed by a subset of the second nanosheets in the active region 310, the gate section 330A, and a subset of the second epitaxial structures formed from the active region 310 and disposed on opposite sides of the gate structure 330, respectively. The transistor PU2 can include its channel, gate terminal, and source/drain terminals formed by another subset of the second nanosheets in the active region 320, the gate section 340B, and another subset of the second epitaxial structures formed from the active region 320 and disposed on opposite sides of the gate structure 340, respectively.

Referring again to FIG. 2, the layout 200 can further include patterns for forming source/drain contact structures 250, 252, 254, 256, 258, and 260, respectively. Similarly in FIG. 3, the layout 300 can further include patterns for forming source/drain contact structures 350, 352, 354, 356, 358, and 360, respectively. Such source/drain contact structures 250 to 260 and 350 to 360 are each sometimes referred to as MD. In general, each of these MDs 250 to 260 and 350 to 360 is configured to electrically connect to the source/drain terminal of a corresponding transistor. For example, each of the MDs 250 to 260 and 350 to 360 can be physically coupled to or wrap around the epitaxial structure of a corresponding transistor. In some embodiments, each of the MDs 250 to 260 and 350 to 360 can laterally extend along the same direction as the gate structures 230-240 and 330-340, e.g., the Y-direction.

For example, in FIG. 2, the MD 250 is connected to a first source/drain terminal of the transistor PD1; the MD 252 is connected to a second source/drain terminal of the transistor PD1 and a first source/drain terminal of the transistor PG1; the MD 254 is connected to a second source/drain terminal of the transistor PG1; the MD 256 is connected to a first source/drain terminal of the transistor PG2; the MD 258 is connected to a second source/drain terminal of the transistor PG2 and a first source/drain terminal of the transistor PD2; the MD 260 is connected to a second source/drain terminal of the transistor PD2. In FIG. 3, the MD 350 is connected to a first source/drain terminal of the transistor PU1; the MD 352 is connected to a second source/drain terminal of the transistor PU1; the MD 360 is connected to a first source/drain terminal of the transistor PU2; and the MD 358 is connected to a second source/drain terminal of the transistor PU2.

In some embodiments, the MD 252 (FIG. 2) and MD 352 (FIG. 3) may be connected to each other through a first via structure (not shown), and the MD 258 (FIG. 2) and MD 358 (FIG. 3) may be connected to teach other through a second via structure (not shown). Stated another way, the first via structure can vertically extend from the first level to the second level to connect the MD 252 to the MD 352, and the second via structure can vertically extend from the first level to the second level to connect the MD 258 to the MD 358. As such, the (internal) node 110 of the memory cell 100, connecting the respective source/drain terminals of the transistors PU1, PD1, and PG1 to one another, can be operatively formed based on the MD 252, the MD 352, and the first via structure vertically interposed therebetween, and the (internal) node 112 of the memory cell 100, connecting the respective source/drain terminals of the transistors PU2, PD2, and PG2 to one another, can be operatively formed based on the MID 258, the MD 358, and the second via structure vertically interposed therebetween.

Referring again to FIG. 2, the layout 200 can further include patterns for forming a number of via structures 270, 271, 272, and 273, respectively. In some embodiments, each of the via structures 270 to 273 can be formed below an MD included in the layout 200. Particularly, the via structures 270 to 273 can each downwardly extend from the frontside of the substrate (e.g., the first level on the frontside) to the backside of the substrate (e.g., the first level on the backside). Such via structures 270 to 273 are each sometimes referred to as BVD. For example, the BVD 270 is formed below the MD 250, allowing the MD 250 to be electrically connected to one or more interconnect structures formed in the lower level (e.g., the first level on the backside formed based on the layout 500); the BVD 271 is formed below the MD 254, allowing the MD 254 to be electrically connected to one or more interconnect structures formed in the lower level (e.g., the first level on the backside formed based on the layout 500); the BVD 272 is formed below the MD 256, allowing the MD 256 to be electrically connected to one or more interconnect structures formed in the lower level (e.g., the first level on the backside formed based on the layout 500); and the BVD 273 is formed below the MD 260, allowing the MD 260 to be electrically connected to one or more interconnect structures formed in the lower level (e.g., the first level on the backside formed based on the layout 500).

Referring again to FIG. 3, the layout 300 can further include patterns for forming at least two internal contact structures 370 and 372, a number of via structures 374-377, and a number of via structures 378-379, respectively. In some embodiments, each of these internal contact structures 370 and 372 may be formed with an L-shape profile, when viewed from the top. Specifically, each of the internal contact structures 370 and 372 can include a first portion extending in the X-direction and a second portion extending in the Y-direction, where the first portion has one of its ends and the second portion has one of its ends connected to each other. Such internal contact structures are each configured to electrically connect an internal node of the memory cell 100 to the gate terminal(s) of one or more transistors.

For example, the internal contact structure 370 has a first portion extending in the X-direction and contacting the MD 352, and a second portion extending in the Y-direction and coupled to the gate structure 340 (or the gate section 340B) through the via structure 375. As such, the internal contact structure 370 can operatively connect the internal node 110 to the gate terminal of the transistor PU2 at the second level. Further, as the gate section 340B and the gate section 240B may be coupled to each other (mentioned above), the internal contact structure 370 can further operatively couple the internal node 110 to the gate terminal of the transistor PD2 at the first level.

Similarly, the internal contact structure 372 has a first portion extending in the X-direction and contacting the MD 358, and a second portion extending in the Y-direction and coupled to the gate structure 330 (or the gate section 330A) through the via structure 374. As such, the internal contact structure 372 can operatively connect the internal node 112 to the gate terminal of the transistor PU1 at the second level. Further, as the gate section 330A and the gate section 230A may be coupled to each other (mentioned above), the internal contact structure 372 can further operatively couple the internal node 112 to the gate terminal of the transistor PD1 at the first level.

Each of the via structures 374 to 377 is typically formed over a gate structure. Such via structures 374 to 377 are each sometimes referred to as VG. The layout 300 can further include a number of the via structures 378 and 379, each of which is formed over an MD included in the layout 300. Such via structures 378 and 379 are each sometimes referred to as VD. For example, the VD 378 is formed over the MD 350, allowing the MD 350 to be electrically connected to one or more interconnect structures formed in the upper level (e.g., the third level on the frontside formed based on the layout 400); and the VD 379 is formed over the MD 360, allowing the MD 360 to be electrically connected to one or more interconnect structures formed in the upper level (e.g., the third level on the frontside formed based on the layout 400).

Referring next to FIG. 4, the layout 400 can include patterns for forming interconnect structures 410, 420, 430, and 440 in the third level on the frontside, respectively. The third level, disposed over the second level formed based on the layout 300 (FIG. 3), may sometimes be referred to as a bottommost one of plural frontside metallization layers, e.g., M0 layer, and the interconnect structures 410 to 440 disposed therein are each sometimes referred to as an M0 track. The frontside metallization layer typically includes one or more dielectric materials (e.g., silicon, oxide, a low-k dielectric material, or the like) embedding the corresponding metal tracks formed of, e.g., copper. These M0 tracks can extend along the same direction as the active regions 210-220 and 310-320, e.g., the X-direction. In some embodiments, the M0 tracks 410 to 440 can each be coupled to a corresponding one of the underlying MDs or gate structures in the second level through a VD or VG. For example, the M0 track 410 is coupled to the MD 350 through the VD 378; the M0 track 420 is coupled to the gate structure 340 through the VG 376; the M0 track 430 is coupled to the gate structure 330 through the VG 377; and the M0 track 440 is coupled to the MD 360 through the VD 379. The M0 tracks 410 and 440 can each operatively serve a part of a power rail carrying the supply voltage VDD, and the M0 tracks 420 and 430 can each operatively serve as a part of the WL.

Referring then to FIG. 5, the layout 500 can include patterns for forming interconnect structures 510, 520, 530, and 540 in the first level on the backside, respectively. The first level, disposed on the backside, may sometimes be referred to as a bottommost one of plural backside metallization layers, e.g., BM0 layer, and the interconnect structures 510 to 540 disposed therein are each sometimes referred to as a BM0 track. The backside metallization layer typically includes one or more dielectric materials (e.g., silicon, oxide, a low-k dielectric material, or the like) embedding the corresponding metal tracks formed of, e.g., copper. These BM0 tracks can extend along the same direction as the active regions 210-220 and 310-320, e.g., the X-direction. In some embodiments, the BM0 tracks 510 to 540 can each be coupled to a corresponding one of the overlaying MDs in the first level on the frontside through a BVD. For example, the BM0 track 510 is coupled to the MD 250 through the BVD 270; the BM0 track 520 is coupled to the MD 254 through the BVD 271; BM0 track 530 is coupled to the MD 256 through the BVD 272; and the BM0 track 540 is coupled to the MD 260 through the BVD 273. The BM0 tracks 510 and 540 can each operatively serve a part of another power rail carrying the ground voltage VSS, the BM0 track 520 can operatively serve as a part of the BL, and the BM0 track 530 can operatively serve as a part of the BLB.

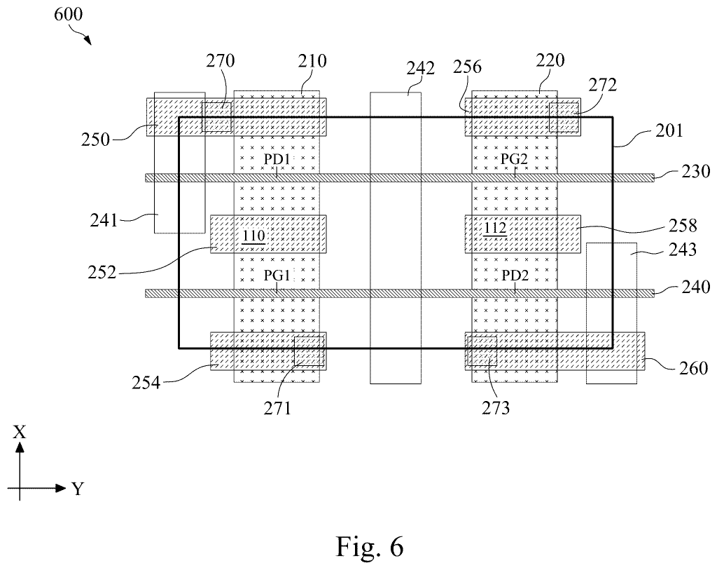

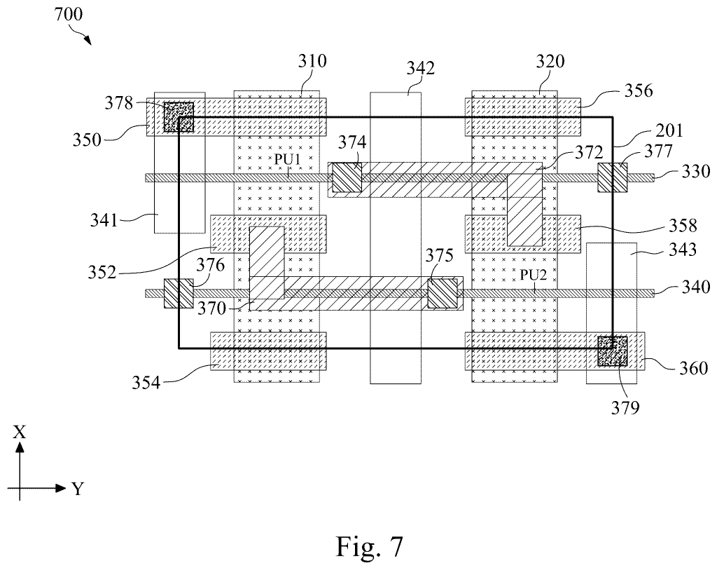

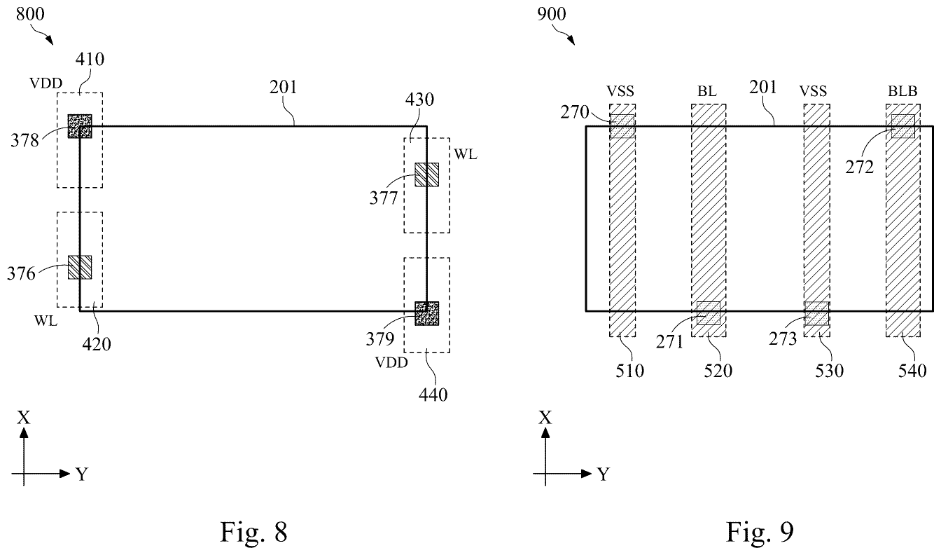

FIG. 6, FIG. 7, FIG. 8, and FIG. 9 respectively illustrate layouts 600, 700, 800, and 900 that can be collectively utilized to form the memory cell 100 (FIG. 1) configured in a CFET structure. In some embodiments, the layouts 600 to 900 are substantially similar to the layouts 200, 300, 400, and 500, respectively. Thus, the following discussions on the layouts 600 to 900 will be focused on the difference, and further, the reference numerals of FIGS. 2-5 will be again used.

Referring first to FIG. 6, similar to the layout 200 (FIG. 2), the layout 600 also includes the active regions 210-220, gate structures 230-240, MDs 250-260, and BVDs 270-273, except that locations of the BVDs 270-273 are different. Referring next to FIG. 7, the layout 700 is substantially similar to the layout 300 (FIG. 3), both of which includes the active regions 310-320, gate structures 330-340, MDs 350-360, VGs 374-377, VDs 378-379, and internal contact structures 370-372. With the layout 700 similar to the layout 300, the layout 800 of FIG. 8 is also similar to the layout 400 of FIG. 4. On the other hand, as the locations of the BVDs 270-273 in FIG. 6 are different from those shown in FIG. 2, the layout 900 of FIG. 9 is slightly different from the layout 500 of FIG. 5. For example, in FIG. 5, the BM0 tracks 510 to 540 are configured as the power rail carrying VSS, the BL, the BLB, and the power rail carrying VSS, respectively, while in FIG. 9, the BM0 tracks 510 to 540 are configured as the power rail carrying VSS, the BL, the power rail carrying VSS, and the BLB, respectively.

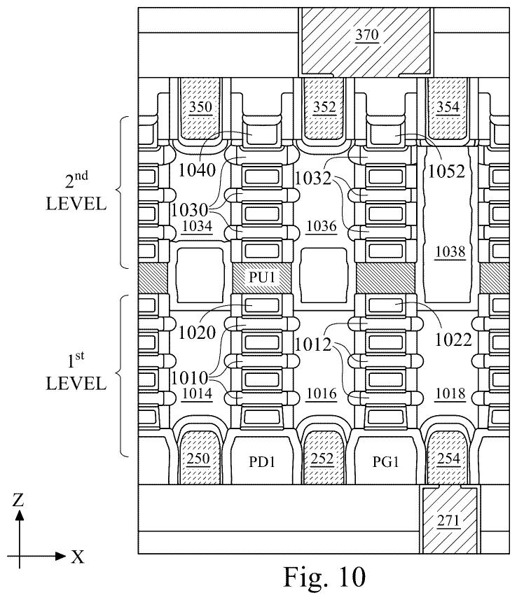

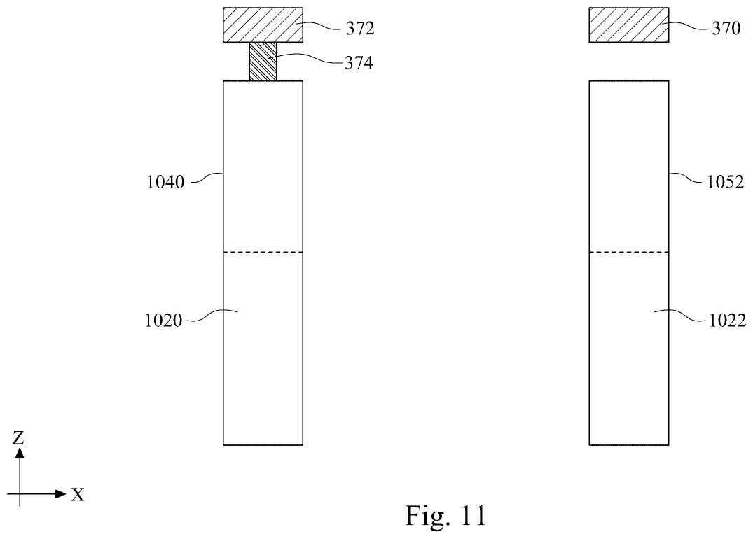

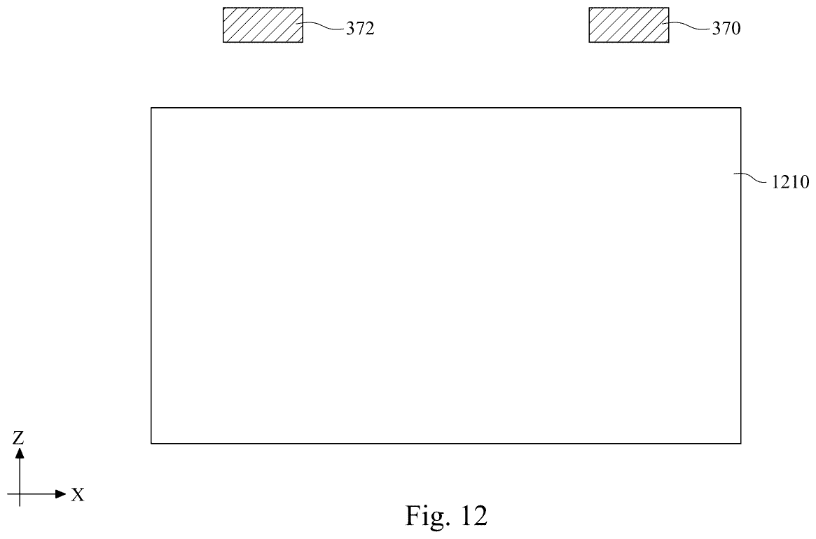

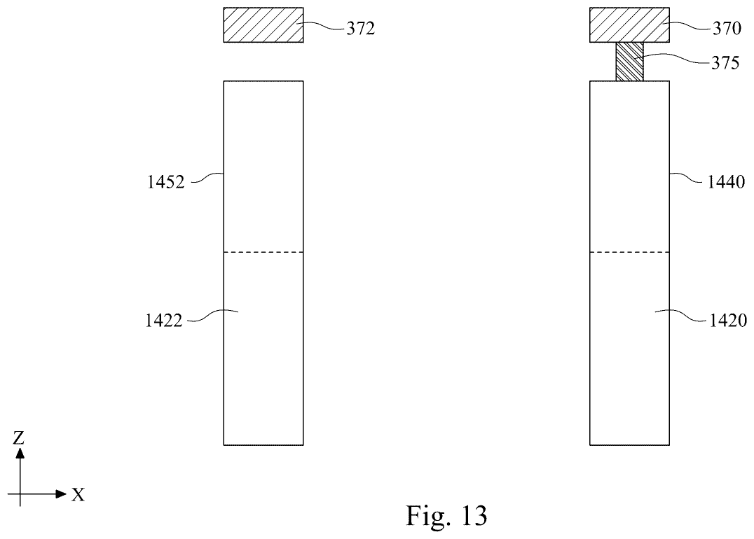

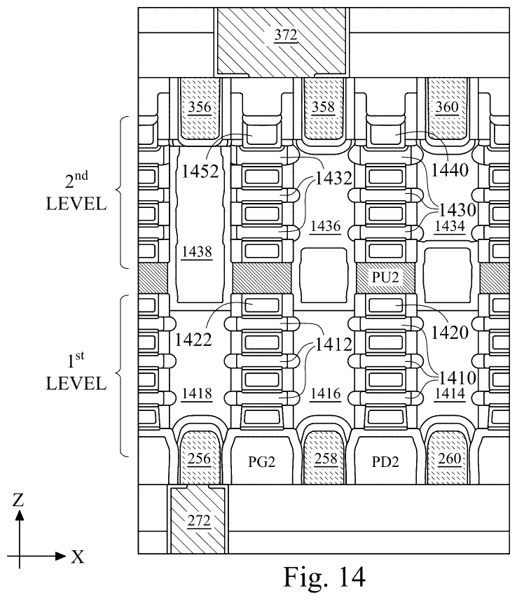

FIG. 10, FIG. 11, FIG. 12, FIG. 13, and FIG. 14 respectively illustrate cross-sectional views of a portion of a semiconductor device including at least one memory cell 100 formed based on the layouts 200 and 300 (FIGS. 2-3), in accordance with some embodiments. For example, the cross-sectional views of FIGS. 10, 11, 12, 13, and 14 are cut along lines A-A, B-B, C-C, D-D, and E-E, respectively, as indicated in FIGS. 2-3. Specifically, each of the lines A-A, B-B, C-C, D-D, and E-E is in parallel with the active regions 210-220 and 310-320.

Referring to FIG. 10, cross-sectional views of the transistors PD1, PG1, and PU1 are shown, and referring to FIG. 14, cross-sectional views of the transistors PD2, PG2, and PU2 are shown. As depicted, the transistors PD1, PG1, PD2, and PG2 are formed in the first level on the frontside of a substrate, and the transistors PU1 and PU2 are formed in the second level over the first level, where the transistors PD1, PG1, PD2, and PG2 are formed with p-type and the transistors PU1 and PU2 are formed with n-type, in accordance with various embodiments of the present disclosure.

In FIG. 10, the transistor PD1 has a number of nanosheets 1010 operatively configured as its channel, p-type epitaxial structures 1014 and 1016 operatively configured as its source/drain terminals, and gate structure 1020 operatively configured as its gate terminal; the transistor PG1 has a number of nanosheets 1012 operatively configured as its channel, p-type epitaxial structures 1016 and 1018 operatively configured as its source/drain terminals, and gate structure 1022 operatively configured as its gate terminal; and the transistor PU1 has a number of nanosheets 1030 operatively configured as its channel, n-type epitaxial structures 1034 and 1036 operatively configured as its source/drain terminals, and gate structure 1040 operatively configured as its gate terminal. Each of the nanosheets 1010 is wrapped by the gate structure 1020, and has its ends coupled to the p-type epitaxial structures 1014 and 1016, respectively. Each of the nanosheets 1012 is wrapped by the gate structure 1022, and has its ends coupled to the p-type epitaxial structures 1016 and 1018, respectively. Each of the nanosheets 1030 is wrapped by the gate structure 1040, and has its ends coupled to the n-type epitaxial structures 1034 and 1036, respectively. The cross-sectional view of FIG. 10 further includes a number of nanosheets 1032, each of which has its ends coupled to the n-type epitaxial structure 1036 and a dielectric structure 1038 and is wrapped by a gate structure 1052.

In FIG. 14, the transistor PD2 has a number of nanosheets 1410 operatively configured as its channel, p-type epitaxial structures 1414 and 1416 operatively configured as its source/drain terminals, and gate structure 1420 operatively configured as its gate terminal; the transistor PG2 has a number of nanosheets 1412 operatively configured as its channel, p-type epitaxial structures 1416 and 1418 operatively configured as its source/drain terminals, and gate structure 1422 operatively configured as its gate terminal; and the transistor PU2 has a number of nanosheets 1430 operatively configured as its channel, n-type epitaxial structures 1434 and 1436 operatively configured as its source/drain terminals, and gate structure 1440 operatively configured as its gate terminal. Each of the nanosheets 1410 is wrapped by the gate structure 1420, and has its ends coupled to the p-type epitaxial structures 1414 and 1416, respectively. Each of the nanosheets 1412 is wrapped by the gate structure 1422, and has its ends coupled to the p-type epitaxial structures 1416 and 1418, respectively. Each of the nanosheets 1430 is wrapped by the gate structure 1440, and has its ends coupled to the n-type epitaxial structures 1434 and 1436, respectively. The cross-sectional view of FIG. 14 further includes a number of nanosheets 1432, each of which has its ends coupled to the n-type epitaxial structure 1436 and a dielectric structure 1438 and is wrapped by a gate structure 1452.

The nanosheets 1010, nanosheets 1012, and p-type epitaxial structures 1014 to 1018 can be formed based on the active region 210 (FIG. 2); and the nanosheets 1030, nanosheets 1032, and n-type epitaxial structures 1034 to 1036 can be formed based on the active region 310 (FIG. 3). In some embodiments, the active regions 210 (FIG. 2) and 310 (FIG. 3) may be utilized to collectively form a first stack structure with a lower portion and an upper portion. The lower portion of the first stack structure can correspond to the nanosheets 1010 and 1012 at the first level, and the upper portion of the first stack structure can correspond to the nanosheets 1030 and 1032 at the second level. Similarly, the active regions 220 (FIG. 2) and 320 (FIG. 3) may be utilized to collectively form a second stack structure with a lower portion and an upper portion. The lower portion of the second stack structure can correspond to the nanosheets 1410 and 1412 at the first level, and the upper portion of the second stack structure can correspond to the nanosheets 1430 and 1432 at the second level.

The gate structure 1020 can be formed based on the gate structure 230 (FIG. 2); the gate structure 1022 can be formed based on the gate structure 240 (FIG. 2); the gate structure 1040 can be formed based on the gate structure 330 (FIG. 3); the gate structure 1052 can be formed based on the gate structure 340 (FIG. 3); the gate structure 1422 can be formed based on the gate structure 230 (FIG. 2); the gate structure 1420 can be formed based on the gate structure 240 (FIG. 2); the gate structure 1452 can be formed based on the gate structure 330 (FIG. 3); and the gate structure 1440 can be formed based on the gate structure 340 (FIG. 3).

As mentioned above, the gate structure 230/330 may be first formed as a first dummy gate structure and then replaced by a first active gate structure. In some embodiments, upon being formed, the first active gate structure can include a lower portion and an upper portion, where the lower portion includes one or more p-type work function metals and the upper portion includes one or more n-type work function metals. The lower portion of the first active gate structure can correspond to the gate structures 1020 and 1422 at the first level, and the upper portion of the first active gate structure can correspond to the gate structures 1040 and 1452 at the second level.

Similarly, the gate structure 240/340 may be first formed as a second dummy gate structure and then replaced by a second active gate structure. In some embodiments, upon being formed, the second active gate structure can include a lower portion and an upper portion, where the lower portion includes one or more p-type work function metals and the upper portion includes one or more n-type work function metals. In some embodiments, the lower portion of the second active gate structure can correspond to the gate structures 1022 and 1420 at the first level, and the upper portion of the second active gate structure can correspond to the gate structures 1052 and 1440 at the second level.

Specifically, the gate structures 1020 and 1040 can correspond to the gate sections 230A (FIG. 2) and 330A (FIG. 3), respectively; the gate structures 1422 and 1452 can correspond to the gate sections 230B (FIG. 2) and 330B (FIG. 3), respectively; the gate structures 1022 and 1052 can correspond to the gate sections 240A (FIG. 2) and 340A (FIG. 3), respectively; and the gate structures 1420 and 1440 can correspond to the gate sections 240B (FIG. 2) and 340B (FIG. 3), respectively.

Based on the above-described association between the structures shown in the cross-sectional views of FIGS. 10 and 14 and the layouts 200-300 of FIGS. 2-3, some of the connection structures shown in FIGS. 2-3 are also labeled in FIGS. 10 and 14. For example, in FIG. 10, the MDs 350, 352, and 354 are shown to couple to the n-type epitaxial structure 1034, n-type epitaxial structure 1036, and dielectric structure 1038, respectively; the internal contact structure 370 (or the portion extending in the X-direction) is shown to couple to the MD 352; the MDs 250, 252, and 254 are shown to couple to the p-type epitaxial structures 1014, 1016, and 1018, respectively; and the BVD 271 is shown to couple to the MD 254. In FIG. 14, the MDs 356-360 are shown to couple to the dielectric structure 1438, n-type epitaxial structure 1436, n-type epitaxial structure 1434, respectively; the internal contact structure 372 (or the portion extending in the X-direction) is shown to couple to the MD 358; the MDs 256 to 260 are shown to couple to the p-type epitaxial structures 1418 to 1414, respectively; and the BVD 272 is shown to couple to the MD 256.

Referring next to FIG. 11, the internal contact structure 372 (or the portion extending in the Y-direction) is shown to couple to the gate structure 1040 (formed based on the gate structure 330 of FIG. 3) through the VG 374, and the internal contact structure 370 (or the portion extending in the Y-direction) is shown over the gate structure 1052 (formed based on the gate structure 340 of FIG. 3). In FIG. 12, the internal contact structure 372 (or the portion extending in the Y-direction) and the internal contact structure 370 (or the portion extending in the Y-direction) are shown over a dielectric structure 1210 formed based on the cut pattern 242/342. In some embodiments, the dielectric structure 1210 may include at least one of: silicon oxide, silicon nitride, silicon oxynitride, silicon carbonitride, silicon oxycarbonitride, fluorine-doped silicate glass (FSG), or a low-k dielectric material. In FIG. 13, the internal contact structure 372 (or the portion extending in the Y-direction) is shown over the gate structure 1452 (formed based on the gate structure 330 of FIG. 3), and the internal contact structure 370 (or the portion extending in the Y-direction) is shown to couple to the gate structure 1440 (formed based on the gate structure 340 of FIG. 3) through the VG 375.

In some embodiments, the dielectric structure 1210, shown in FIG. 12, is configured to electrically isolate different sections of the gate structures 230, 240, 330, and 340. For example, the dielectric structure 1210 can isolate the gate structures 1020 and 1422 (formed based on the gate sections 230A and 230B, respectively); isolate the gate structures 1040 and 1452 (formed based on the gate sections 330A and 330B, respectively); isolate the gate structures 1022 and 1420 (formed based on the gate sections 240A and 240B, respectively); and isolate the gate structures 1052 and 1440 (formed based on the gate sections 340A and 340B, respectively).

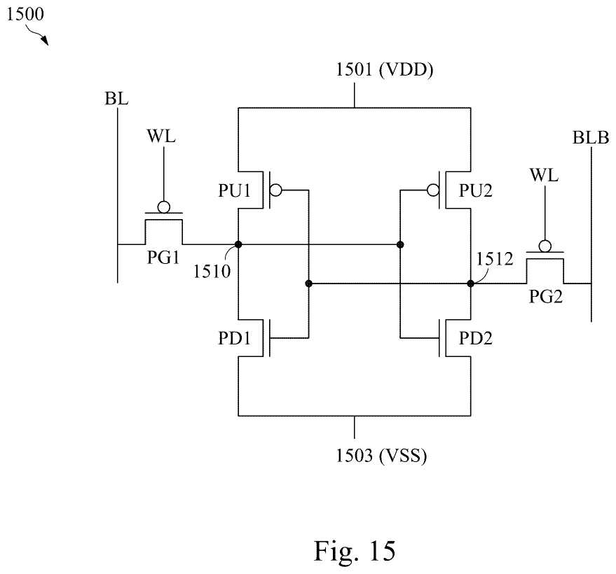

FIG. 15 illustrates an example circuit diagram of another memory cell 1500, in accordance with some embodiments. As shown, the memory cell 1500 includes six transistors that operatively form a 6 T SRAM cell. In various embodiments, the six transistors can be physically formed with the CFET structure, as discussed below. The memory cell 1500 includes six transistors: a first pull-up transistor PU1, a second pull-up transistor PU2, a first pull-down transistor PD1, a second pull-down transistor PD2, a first pass-gate transistor PG1, and a second pass-gate transistor PG2.

The transistors PU1 and PD1 are formed as a first inverter and the transistors PU2 and PD2 are formed as a second inverter, wherein the first and second inverters are cross coupled to each other. Specifically, the first and second inverters are each coupled between first voltage reference 1501 and second voltage reference 1503. In some embodiments, the first voltage reference 1501 is a supply voltage applied to the memory cell 1500, sometimes referred to as “VDD,” and the second voltage reference 1503 is a ground voltage, sometimes referred to as “VSS.” The first inverter (formed by the transistors PU1 and PD1) is coupled to the transistor PG1, and the second inverter (formed by the transistors PU2 and PD2) is coupled to the transistor PG2. In addition to being coupled to the first and second inverters, the transistors PG1 and PG2 are each coupled to a word line (WL) and are coupled to a bit line (BL) and a bit line bar (BLB), respectively.

In some embodiments, the transistors PD1 and PD2 each include an n-type metal-oxide-semiconductor (NMOS) transistor, and the transistors PU1, PU2, PG1, and PG2 each include a p-type metal-oxide-semiconductor (PMOS) transistor. Although the illustrated embodiment of FIG. 15 shows that the transistors of the memory cell 1500 are either NMOS or PMOS transistors, any of a variety of transistors or devices that are suitable for use in a memory device may be implemented as at least one of the transistors of the memory cell 1500 such as, for example, a bipolar junction transistor (BJT), a high-electron-mobility transistor (HEMT), etc. Further, as will be discussed below, the p-type transistors, PG1, PG2, PU1, and PU2, are each formed as a GAA FET in a first level disposed on the frontside of a substate, and the n-type transistors, PD1 and PD2, are each formed as a GAA FET in a second level over the first level.

The transistors PG1 and PG2 each have a gate terminal coupled to the WL. The gate terminals of the transistors PG1 and PG2 are configured to receive a pulse signal, through the WL, to allow or block an access (e.g., a read operation, a write operation) of the memory cell 1500 accordingly. The transistors PD1 and PUI are coupled between VDD and VSS, and coupled to each other at node 1510. For example, the transistor PU1 has a first source/drain terminal connected to VDD and the transistor PD1 has a first source/drain terminal connected to VSS, with the transistors PU1 and PD1 having their second source/drain terminals connected to each other at node 1510. The transistor PG1 has a first source/drain terminal connected to the BL and a second source/drain terminal connected to node 1510, which is further coupled to gate terminals of the transistors PU2 and PD2. Similarly, the transistors PD2 and PU2 are coupled between VDD and VSS, and coupled to each other at node 1512. For example, the transistor PU2 has a first source/drain terminal connected to VDD and the transistor PD2 has a first source/drain terminal connected to VSS, with the transistors PU2 and PD2 having their second source/drain terminals connected to each other at node 1512. The transistor PG2 has a first source/drain terminal connected to the BLB and a second source/drain terminal connected to node 1512, which is further coupled to gate terminals of the transistors PU1 and PD1.

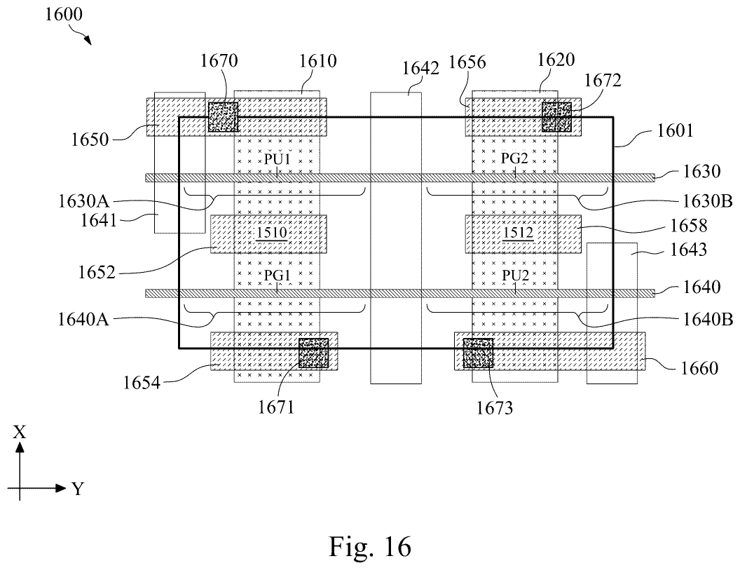

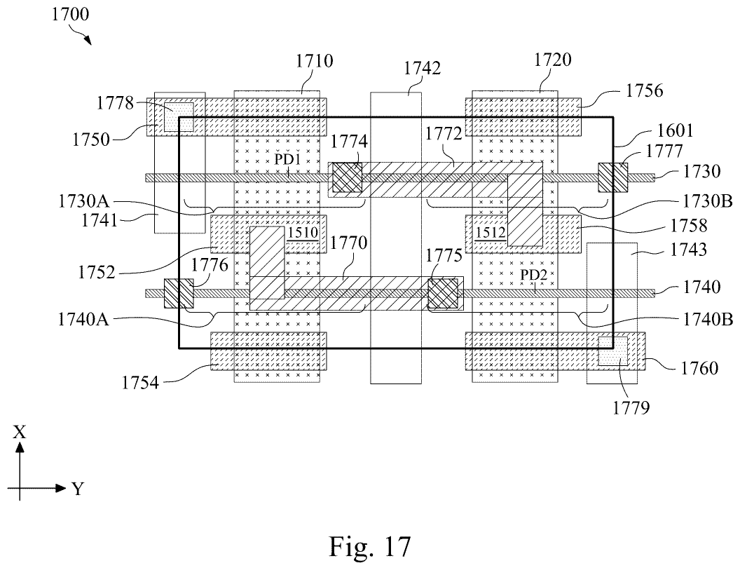

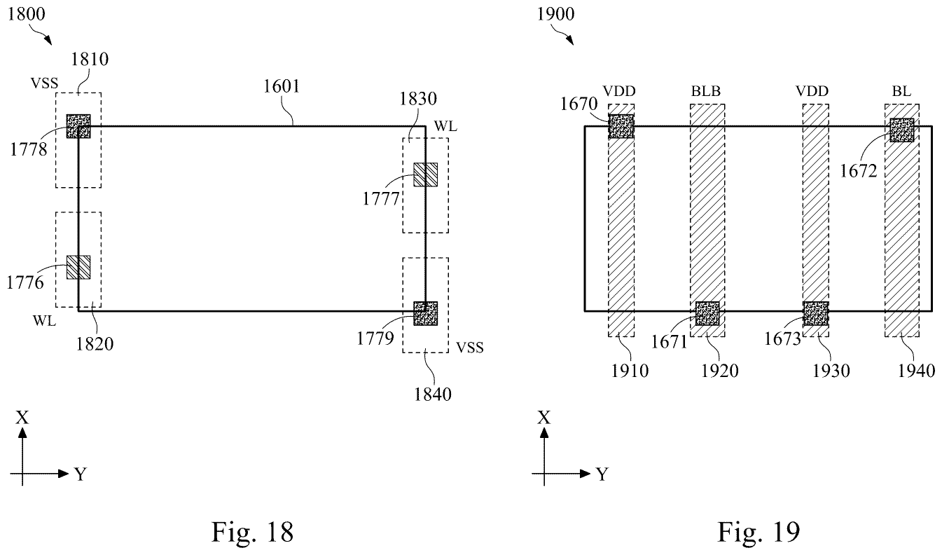

FIG. 16, FIG. 17, FIG. 18, and FIG. 19 respectively illustrate layouts 1600, 1700, 1800, and 1900 that can be collectively utilized to form the memory cell 1500 (FIG. 15) configured in a CFET structure. As depicted, each of the layouts 1600 to 1900 includes a cell boundary 1601 defining a physical area of the memory cell 1500. The CFET structure can include a number of first transistors disposed at a first level on the frontside of a substate, and a number of second transistors despised at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 1600 to 1900 can include a number of patterns configured for forming respective structures, and thus, such patterns of the disclosed layout are herein referred to as the structures to be formed, respectively, in the following discussion. For example, the layout 1600 is configured to form structures of the first transistors at the first level on the frontside; and the layout 1700 is configured to form structures of the second transistors at the second level on the frontside. Further, the layout 1800 is configured to form the structures at a third level on the frontside of the substrate, over the second level; and the layout 1900 is configured to form a first level on a backside of the substrate. It should be understood that each of the layouts 1600 to 1900 has been simplified for illustrative purposes, and thus, can include any of various other patterns while remaining within the scope of the present disclosure.

Referring first to FIG. 16, the layout 1600 can include patterns for forming active regions 1610 and 1620 and gate structures 1630 and 1640, respectively. The active regions 1610 and 1620 may extend in the X-direction; and the gate structures 1630 and 1640 may extend in the Y-direction. Each of the active regions 1610 and 1620 may be formed as a fin structure or a stack structure extending along the X-direction, and each of the gate structures 1630 and 1640 may be formed to extend in the Y-direction to traverse the active regions 1630 and 1640. The layout 1600 can further include a number of cut patterns, e.g., 1641, 1642, and 1643, each of which can extend along the X-direction traversing one or more of the gate structures 1630-1640. The cut patterns 1641 to 1643 can each be configured to form a dielectric structure, thereby dividing one or more of the gate structures 1630-1640 into separate gate sections. For example, the cut pattern 1642 can divide the gate structure 1630 into gate sections 1630A and 1630B, and divide the gate structure 1640 into gate sections 1640A and 1640B, as indicated in FIG. 16.

Referring next to FIG. 17, the layout 1700 can include patterns for forming active regions 1710 and 1720 and gate structures 1730 and 1740, respectively. The active regions 1710 and 1720 may extend in the X-direction; and the gate structures 1730 and 1740 may extend in the Y-direction. Each of the active regions 1710 and 1720 may be formed as a fin structure or a stack structure extending along the X-direction, and each of the gate structures 1730 and 1740 may be formed to extend in the Y-direction to traverse the active regions 1730 and 1740. The layout 1700 can further include a number of cut patterns, e.g., 1741, 1742, and 1743, each of which can extend along the X-direction traversing one or more of the gate structures 1730-1740. The cut patterns 1741 to 1743 can each be configured to form a dielectric structure, thereby dividing one or more of the gate structures 1730-1740 into separate gate sections. For example, the cut pattern 1742 can divide the gate structure 1730 into gate sections 1730A and 1730B, and divide the gate structure 1740 into gate sections 1740A and 1740B, as indicated in FIG. 17.

In some embodiments, the active regions 1610 and 1710 are vertically aligned with each other, the active regions 1620 and 1720 are vertically aligned with each other, the gate structures 1630 and 1730 are vertically aligned with each other, the gate structures 1640 and 1740 are vertically aligned with each other, the cut patterns 1641 and 1741 are vertically aligned with each other, the cut patterns 1642 and 1742 are vertically aligned with each other, and the cut patterns 1643 and 1743 are vertically aligned with each other. Further, the active regions 1610 and 1710 may be physically formed as a single structure (sometimes referred to as “active region 1610/1710”), the active regions 1620 and 1720 may be physically formed as a single structure (sometimes referred to as “active region 1620/1720”), the gate structures 1630 and 1730 may be physically formed as a single structure (sometimes referred to as “gate structure 1630/1730”), and the gate structures 1640 and 1740 may be physically formed as a single structure (sometimes referred to as “gate structure 1640/1740”).

For example, the active region 1610/1710 and active region 1620/1720 can each be first formed as a stack structure protruding from the frontside surface of a substrate. The stack may include a number of first semiconductor nanostructures (e.g., first nanosheets) extending along the X-direction and vertically separated from each other, and a number of second semiconductor nanostructures (e.g., second nanosheets) extending along the X-direction and vertically separated from each other. The first nanosheets are positioned at the first level, and the second nanosheets are positioned at the second level. According to some embodiments of the present disclosure, the first nanosheets, formed based on a lower portion of the active region 1610/1710 or a lower portion of the active region 1620/1720, can partially form the first transistors formed at the first level; and the second nanosheets, formed based on an upper portion of the active region 1610/1710 or an upper portion of the active region 1620/1720, can partially form the second transistors formed at the second level. Further, the first nanosheets and the second nanosheets can be vertically aligned with but separated from each other, with at least one dielectric layer interposed therebetween.

Next, respective portions of the first and second nanosheets in each of the stacks that are overlaid by the gate structure 1630/1730 and the gate structure 1640/1740, which are initially formed as a number of dummy (e.g., polysilicon) gate structures, respectively, may remain. Other portions of the first nanosheets are replaced with a number of first epitaxial structures, and other portions of the second nanosheets are replaced with a number of second epitaxial structures. According to some embodiments of the present disclosure, the first epitaxial structures (at the first level) may be formed with a p-type conductivity, and the second epitaxial structures (at the second level) may be formed with an n-type conductivity. The first epitaxial structures can operatively form respective source/drain terminals of the first transistors at the first level, and the second epitaxial structures can operatively form respective source/drain terminals of the second transistors at the second level.

Next, each of the dummy gate structures 1630/1730 and 1640/1740 can be replaced by a corresponding active (e.g., metal) gate structure to form the first and second transistors. According to some embodiments of the present disclosure, each of the active gate structures can include a lower portion and an upper portion corresponding to the first level and the second level, respectively. For example, the lower portion of the active gate structure may include one or more first work function metals configured for forming a gate terminal of one of the first transistors with the p-type conductivity, and the upper portion of the active gate structure may include one or more second work function metals configured for forming a gate terminal of one of the second transistors with the n-type conductivity. Details of manufacturing processes to form the structures of the first transistor(s) at the first level and the second transistor(s) at the second level will be described with respect to FIGS. 25-46.

As a brief overview, the transistors PU1, PU2, PG1, and PG2 of the memory cell 1500 can be formed at the first level based on the layout 1600 (as indicated in FIG. 16), and the transistors PD1 and PD2 of the memory cell 1500 can be formed at the second level based on the layout 1700 (as indicated in FIG. 17). Further, in some embodiments, the transistors PU1, PU2, PG1, and PG2 at the first level can be formed with the p-type conductivity, and the transistors PD1 and PD2 at the second level can be formed with the n-type conductivity.

For example, in FIG. 16, the transistor PU1 can include its channel, gate terminal, and source/drain terminals formed by a subset of the first nanosheets in the active region 1610, the gate section 1630A, and a subset of the first epitaxial structures formed from the active region 1610 and disposed on opposite sides of the gate structure 1630, respectively. The transistor PG1 can include its channel, gate terminal, and source/drain terminals formed by another subset of the first nanosheets in the active region 1610, the gate section 1640A, and another subset of the first epitaxial structures formed from the active region 1610 and disposed on opposite sides of the gate structure 1640, respectively. The transistor PU2 can include its channel, gate terminal, and source/drain terminals formed by yet another subset of the first nanosheets in the active region 1620, the gate section 1640B, and yet another subset of the first epitaxial structures formed from the active region 1620 and disposed on opposite sides of the gate structure 1640, respectively. The transistor PG2 can include its channel, gate terminal, and source/drain terminals formed by yet another subset of the first nanosheets in the active region 1620, the gate section 1630B, and yet another subset of the first epitaxial structures formed from the active region 1620 and disposed on opposite sides of the gate structure 1630, respectively.

For another example, in FIG. 17, the transistor PD1 can include its channel, gate terminal, and source/drain terminals formed by a subset of the second nanosheets in the active region 1710, the gate section 1730A, and a subset of the second epitaxial structures formed from the active region 1710 and disposed on opposite sides of the gate structure 1730, respectively. The transistor PD2 can include its channel, gate terminal, and source/drain terminals formed by another subset of the second nanosheets in the active region 1720, the gate section 1740B, and another subset of the second epitaxial structures formed from the active region 1720 and disposed on opposite sides of the gate structure 1740, respectively.

Referring again to FIG. 16, the layout 1600 can further include patterns for forming source/drain contact structures 1650, 1652, 1654, 1656, 1658, and 1660, respectively. Similarly in FIG. 17, the layout 1700 can further include patterns for forming source/drain contact structures 1750, 1752, 1754, 1756, 1758, and 1760, respectively. Such source/drain contact structures 1650 to 1660 and 1750 to 1760 are each sometimes referred to as MD. In general, each of these MDs 1650 to 1660 and 1750 to 1760 is configured to electrically connect to the source/drain terminal of a corresponding transistor. For example, each of the MDs 1650 to 1660 and 1750 to 1760 can be physically coupled to or wrap around the epitaxial structure of a corresponding transistor. In some embodiments, each of the MDs 1650 to 1660 and 1750 to 1760 can laterally extend along the same direction as the gate structures 1630-1640 and 1730-1740, e.g., the Y-direction.

For example, in FIG. 16, the MD 1650 is connected to a first source/drain terminal of the transistor PU1; the MD 1652 is connected to a second source/drain terminal of the transistor PU1 and a first source/drain terminal of the transistor PG1; the MD 1654 is connected to a second source/drain terminal of the transistor PG1; the MD 1656 is connected to a first source/drain terminal of the transistor PG2; the MD 1658 is connected to a second source/drain terminal of the transistor PG2 and a first source/drain terminal of the transistor PU2; the MD 1660 is connected to a second source/drain terminal of the transistor PU2. In FIG. 17, the MD 1750 is connected to a first source/drain terminal of the transistor PD1; the MD 1752 is connected to a second source/drain terminal of the transistor PD1; the MD 1760 is connected to a first source/drain terminal of the transistor PD2; and the MD 1758 is connected to a second source/drain terminal of the transistor PD2.

In some embodiments, the MD 1652 (FIG. 16) and MD 1752 (FIG. 17) may be connected to each other through a first via structure (not shown), and the MD 1658 (FIG. 16) and MD 1758 (FIG. 17) may be connected to teach other through a second via structure (not shown). Stated another way, the first via structure can vertically extend from the first level to the second level to connect the MD 1652 to the MD 1752, and the second via structure can vertically extend from the first level to the second level to connect the MD 1658 to the MD 1758. As such, the (internal) node 1510 of the memory cell 1500, connecting the respective source/drain terminals of the transistors PU1, PD1, and PG1 to one another, can be operatively formed based on the MD 1652, the MD 1752, the first via structure vertically interposed therebetween, and the (internal) node 1512 of the memory cell 1500, connecting the respective source/drain terminals of the transistors PU2, PD2, and PG2 to one another, can be operatively formed based on the MD 1658, the MD 1758, and the second via structure vertically interposed therebetween.

Referring again to FIG. 16, the layout 1600 can further include patterns for forming a number of via structures 1670, 1671, 1672, and 1673, respectively. In some embodiments, each of the via structures 1670 to 1673 can be formed below an MD included in the layout 1600. Particularly, the via structures 1670 to 1673 can each downwardly extend from the frontside of the substrate (e.g., the first level on the frontside) to the backside of the substrate (e.g., the first level on the backside). Such via structures 1670 to 1673 are each sometimes referred to as BVD. For example, the BVD 1670 is formed below the MD 1650, allowing the MD 1650 to be electrically connected to one or more interconnect structures formed in the lower level (e.g., the first level on the backside formed based on the layout 1900); the BVD 1671 is formed below the MD 1654, allowing the MD 1654 to be electrically connected to one or more interconnect structures formed in the lower level (e.g., the first level on the backside formed based on the layout 1900); the BVD 1672 is formed below the MD 1656, allowing the MD 1656 to be electrically connected to one or more interconnect structures formed in the lower level (e.g., the first level on the backside formed based on the layout 1900); and the BVD 1673 is formed below the MD 1660, allowing the MD 1660 to be electrically connected to one or more interconnect structures formed in the lower level (e.g., the first level on the backside formed based on the layout 1900).

Referring again to FIG. 17, the layout 1700 can further include patterns for forming at least two internal contact structures 1770 and 1772, a number of via structures 1774-1777, and a number of via structures 1778-1779, respectively. In some embodiments, each of these internal contact structures 1770 and 1772 may be formed with an L-shape profile, when viewed from the top. Specifically, each of the internal contact structures 1770 and 1772 can include a first portion extending in the X-direction and a second portion extending in the Y-direction, where the first portion has one of its ends and the second portion has one of its ends connected to each other. Such internal contact structures are each configured to electrically connect an internal node of the memory cell 1500 to the gate terminal(s) of one or more transistors.

For example, the internal contact structure 1770 has a first portion extending in the X-direction and contacting the MD 1752, and a second portion extending in the Y-direction and coupled to the gate structure 1740 (or the gate section 1740B) through the via structure 1775. As such, the internal contact structure 1770 can operatively connect the internal node 1510 to the gate terminal of the transistor PD2 at the second level. Further, as the gate section 1740B and the gate section 1640B may be coupled to each other (mentioned above), the internal contact structure 1770 can further operatively couple the internal node 1510 to the gate terminal of the transistor PU2 at the first level.

Similarly, the internal contact structure 1772 has a first portion extending in the X-direction and contacting the MD 1758, and a second portion extending in the Y-direction and coupled to the gate structure 1730 (or the gate section 1730A) through the via structure 1774. As such, the internal contact structure 1772 can operatively connect the internal node 1512 to the gate terminal of the transistor PD1 at the second level. Further, as the gate section 1730A and the gate section 1630A may be coupled to each other (mentioned above), the internal contact structure 1772 can further operatively couple the internal node 1512 to the gate terminal of the transistor PU1 at the first level.

Each of the via structures 1774 to 1777 is typically formed over a gate structure. Such via structures 1774 to 1777 are each sometimes referred to as VG. The layout 1700 can further include a number of the via structures 1778 and 1779, each of which is formed over an MD included in the layout 1700. Such via structures 1778 and 1779 are each sometimes referred to as VD. For example, the VD 1778 is formed over the MD 1750, allowing the MD 1750 to be electrically connected to one or more interconnect structures formed in the upper level (e.g., the third level on the frontside formed based on the layout 1800); and the VD 1779 is formed over the MD 1760, allowing the MD 1760 to be electrically connected to one or more interconnect structures formed in the upper level (e.g., the third level on the frontside formed based on the layout 1800).

Referring next to FIG. 18, the layout 1800 can include patterns for forming interconnect structures 1810, 1820, 1830, and 1840 in the third level on the frontside, respectively. The third level, disposed over the second level formed based on the layout 1700 (FIG. 17), may sometimes be referred to as a bottommost one of plural frontside metallization layers, e.g., M0 layer, and the interconnect structures 1810 to 1840 disposed therein are each sometimes referred to as an M0 track. These M0 tracks can extend along the same direction as the active regions 1610-1620 and 1710-1720, e.g., the X-direction. In some embodiments, the M0 tracks 1810 to 1840 can each be coupled to a corresponding one of the underlying MDs or gate structures in the second level through a VD or VG. For example, the M0 track 1810 is coupled to the MD 1850 through the VD 1878; the M0 track 1820 is coupled to the gate structure 1840 through the VG 1876; the M0 track 1830 is coupled to the gate structure 1830 through the VG 1877; and the M0 track 1840 is coupled to the MD 1860 through the VD 1879. The M0 tracks 1810 and 1840 can each operatively serve a part of a power rail carrying the ground voltage VSS, and the M0 tracks 1820 and 1830 can each operatively serve as a part of the WL.

Referring then to FIG. 19, the layout 1900 can include patterns for forming interconnect structures 1910, 1920, 1930, and 1940 in the first level on the backside, respectively. The first level, disposed on the backside, may sometimes be referred to as a bottommost one of plural backside metallization layers, e.g., BM0 layer, and the interconnect structures 1910 to 1940 disposed therein are each sometimes referred to as a BM0 track. These BM0 tracks can extend along the same direction as the active regions 1610-1620 and 1710-1720, e.g., the X-direction. In some embodiments, the BM0 tracks 1910 to 1940 can each be coupled to a corresponding one of the overlaying MDs in the first level on the frontside through a BVD. For example, the BM0 track 1910 is coupled to the MD 1650 through the BVD 1670; the BM0 track 1920 is coupled to the MD 1654 through the BVD 1671; BM0 track 1930 is coupled to the MD 1660 through the BVD 1673; and the BM0 track 1940 is coupled to the MD 1656 through the BVD 1672. The BM0 tracks 1910 and 1930 can each operatively serve a part of another power rail carrying the supply voltage VDD, the BM0 track 1920 can operatively serve as a part of the BLB, and the BM0 track 1940 can operatively serve as a part of the BL.

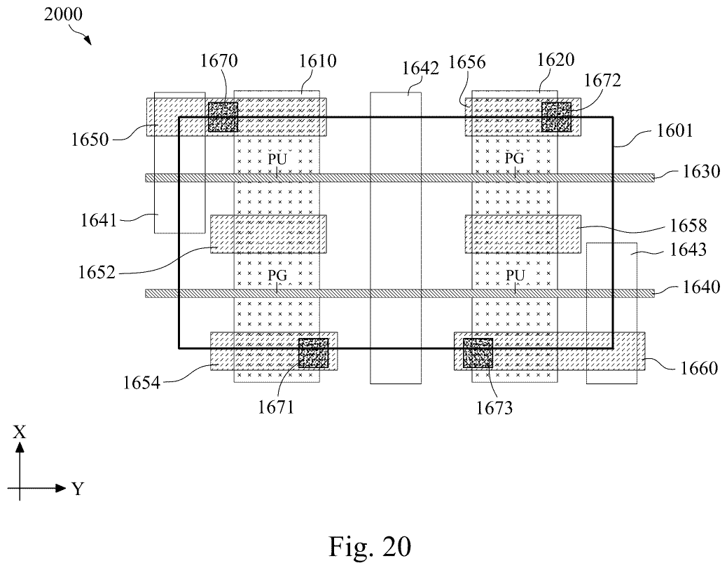

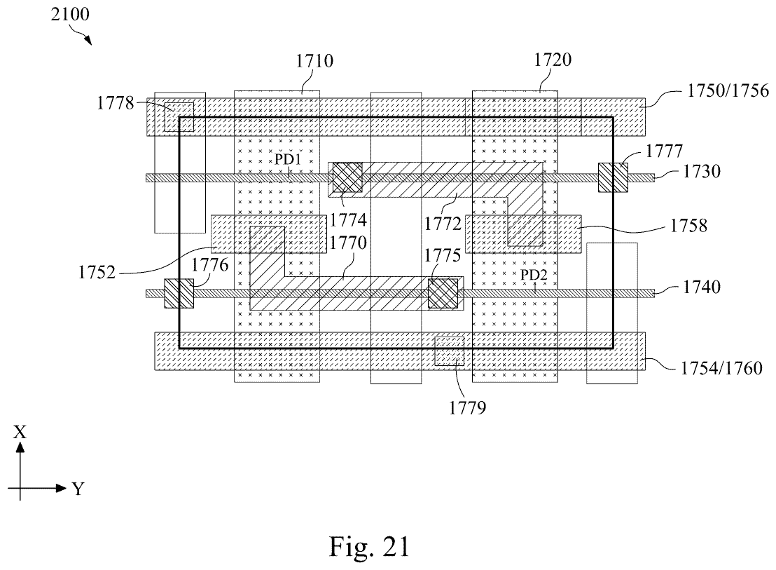

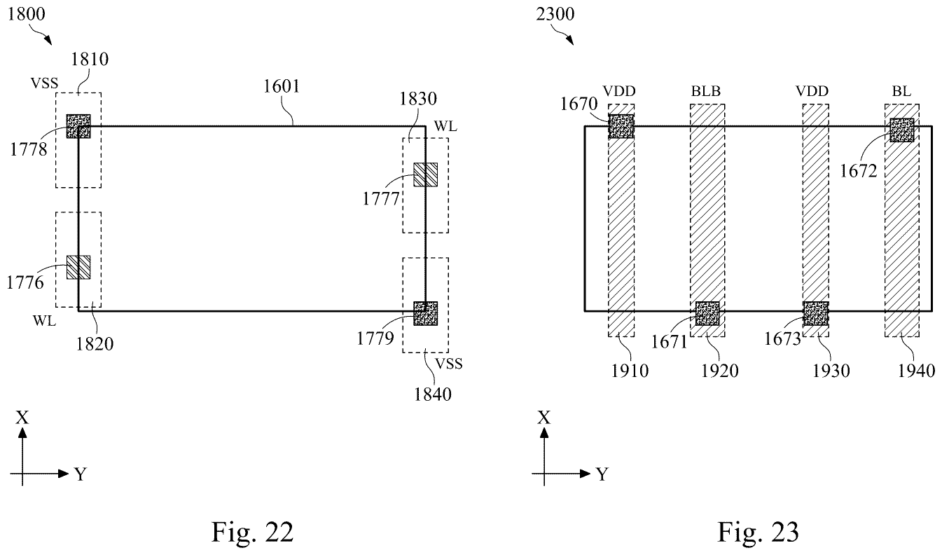

FIG. 20, FIG. 21, FIG. 22, and FIG. 23 respectively illustrate layouts 2000, 2100, 2200, and 2300 that can be collectively utilized to form the memory cell 1500 (FIG. 15) configured in a CFET structure. In some embodiments, the layouts 2000 to 2300 are substantially similar to the layouts 2000, 2100, 2200, and 2300, respectively. Thus, the following discussions on the layouts 2000 to 2300 will be focused on the difference, and further, the reference numerals of FIGS. 16-19 will be again used.

Referring first to FIG. 20, the layout 2000 is substantially similar to the layout 1600 (FIG. 16), both of which includes the active regions 1610-1620, gate structures 1630-1640, MDs 1650-1660, and BVDs 1670-1673. Referring next to FIG. 21, the layout 2100 is substantially similar to the layout 1700 (FIG. 17), which also includes the active regions 1710-1720, gate structures 1730-1740, MDs 1750-1760, VGs 1774-1777, VDs 1778-1779, and internal contact structures 1770-1772, except that the MDs 1750 and 1756 are formed as a single structure (hereinafter “MD 1750/1756”), and the MDs 1754 and 1760 are formed as another single structure (hereinafter “MD 1754/1760”). With the layout 2000 similar to the layout 1600, the layout 2200 of FIG. 22 is also similar to the layout 1800 of FIG. 18; and with the layout 2100 similar to the layout 1700, the layout 2300 of FIG. 23 is also similar to the layout 1900 of FIG. 19.

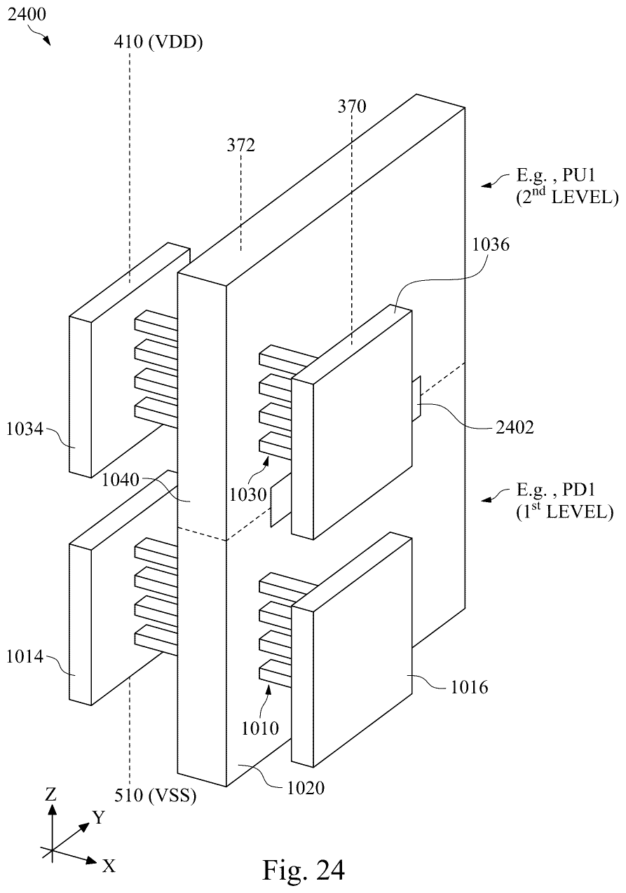

FIG. 24 illustrates a perspective view of a semiconductor device 2400 including a portion of a memory cell configured in a CFET structure, in accordance with some embodiments of the present disclosure. For example, the semiconductor device 2400 may include the memory cell 100 formed based on the layouts 200-500 (FIGS. 2-5) or the layouts 600-900 (FIGS. 6-9). Accordingly, some of the reference numerals in FIGS. 2-14 may be again used. It should be appreciated that the semiconductor device 2400 of FIG. 24 has been simplified, and thus, some of the above-described structures are omitted for purposes of clarity.

For example, in FIG. 24, the transistor PD1 formed at the first level on the frontside of a substrate and the transistor PU1 formed at the second level over the first level are shown. The channel, gate terminal, and source/drain terminals of the transistor PD1, operatively formed by the nanosheets 1010, gate structure 1020, and epitaxial structures 1014-1016 (FIG. 10), respectively, are also shown; and the channel, gate terminal, and source/drain terminals of the transistor PU1, operatively formed by the nanosheets 1030, gate structure 1040, and epitaxial structures 1034-1036 (FIG. 10), respectively, are also shown. In some embodiments, a dielectric layer 2402 may be vertically interposed between the gate structure 1020 and the gate structure 1040, as shown in FIG. 24. The dielectric layer may include at least one of: silicon oxide, silicon nitride, silicon oxynitride, silicon carbonitride, silicon oxycarbonitride, fluorine-doped silicate glass (FSG), or a low-k dielectric material.

The transistor PD1 is configured with the p-type conductivity (e.g., through forming the epitaxial structures 1014-1016 in p-type and/or forming the gate structure 1020 to include one or more p-type work function metals), and the transistor PU1 is configured with the n-type conductivity (e.g., through forming the epitaxial structures 1034-1036 in n-type and/or forming the gate structure 1040 to include one or more n-type work function metals). Accordingly, the epitaxial structure 1014 (one of the source/drain terminals of the transistor PD1) can be electrically connected to the BM0 track 510 carrying the ground voltage VSS through at least an MD and a BVD (not shown), the epitaxial structure 1034 (one of the source/drain terminals of the transistor PU1) can be electrically connected to the M0 track 410 carrying the supply voltage VDD through at least a VD (not shown), the epitaxial structure 1036 (the other one of the source/drain terminals of the transistor PU1) can be electrically connected to the internal contact structure 370 through at least another MD, and the gate structure 1040 (the gate terminal of the transistor PU1) can be electrically connected to the internal contact structure 372 through at least a VG (not shown).

Although the semiconductor device 2400 shown in FIG. 24 is directed to the memory cell 100, it should be understood that such a CFET structure is not limited thereto. In some other embodiments, the memory cell 1500 (FIG. 15) formed based on the corresponding disclosed layouts (FIGS. 16-23) can have the similar physical arrangement to the semiconductor device 2400. For example, the semiconductor device 2400 can have each of its transistors formed at the first level as one of the transistors PU1/PU2, and each of its transistors formed at the second level as one of the transistors PD1/PD2.

FIG. 25 illustrates a flow chart of an example method 2500 for forming a memory cell configured in a CFET structure, according to some embodiments of the present disclosure. For example, at least some of the operations (or steps) of the method 2500 can be used to form the memory cell 100 (FIG. 1) or the memory cell 1500 (FIG. 15) in the CFET structure, which includes a number of p-type transistors disposed at the first level on the frontside of a substrate and a number of n-type transistors disposed at the second, upper level on the frontside of the substrate.

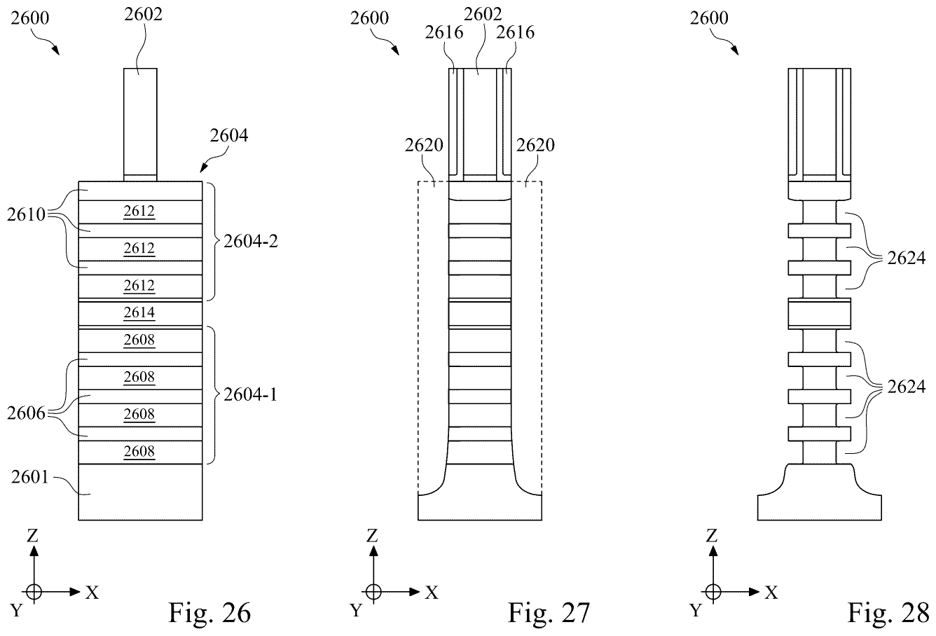

It should be appreciated that the method 2500 is merely an example, and is not intended to limit the present disclosure. Accordingly, it is understood that additional operations may be provided before, during, and after the method 2500 of FIG. 25, and that some other operations may only be briefly described herein. In some embodiments, operations of the method 2500 may be associated with cross-sectional views of a CFET structure 2600 (similar to the semiconductor device 2400 of FIG. 24) at various fabrication stages as shown in FIGS. 26, 27, 28, 29, 30, 31, 32, 33, and 34, respectively, which will be discussed in further detail below.

As a brief overview, the method 2500 starts with operation 2502 of forming a number of dummy gate structures over a stack including a lower portion and an upper portion. The lower portion includes a number of first nanostructures and a number of second nanostructures alternately stacked on top of one another, and the upper portion includes a number of third nanostructures and a number of fourth nanostructures alternately stacked on top of one another. The first and third nanostructures may be formed of a first semiconductor material, and the second and fourth nanostructures may be formed of a second semiconductor material. Further, the lower portion and the upper portion may be separated from each other with a fifth nanostructure formed of a third semiconductor material. The method 2500 continues to operation 2504 of etching the stack to form source/drain recesses. The 2500 continues to operation 2506 of laterally recessing the second nanostructures and the fourth nanostructures. The method 2500 continues to operation 2508 of forming a number of inner spacers. The method 2500 continues to operation 2510 of selectively removing the fifth nanostructure. The method 2500 continues to operation 2512 of forming a dielectric layer between the lower portion and the upper portion. The method 2500 continues to operation 2514 of forming a number of p-type epitaxial structures in the lower portion and a number of n-type epitaxial structures in the upper portion. The method 2500 continues to operation 2516 of forming a first active gate structure in the lower portion and a second active gate structure in the upper portion. The method 2500 continues to operation 2518 of forming a number of connection structures.

Corresponding to operation 2502 of FIG. 25, FIG. 26 is a cross-sectional view of the CFET structure 2600 including a number of dummy gate structures 2602 over a stack 2604, at one of the various stages of fabrication. The cross-sectional view of FIG. 26 is cut along the lengthwise direction of an active region of the CFET structure 2600 (e.g., the X-direction illustrated above).

In some embodiments, the stack 2604 may be formed over a semiconductor substrate 2601, followed by the dummy gate structure 2602 formed over the stack 2604. The stack 2604 can extend along the X-direction, and the dummy gate structure 2602 can extend along the Y-direction to straddle or otherwise traverse the stack 2604. The stack 2604 includes a lower portion 2604-1 and an upper portion 2604-2, which can correspond to the first level and the second level on the frontside of the substrate (e.g., FIGS. 10, 14, 24), respectively. The lower portion 2604-1 includes a number of first nanostructures 2606 and a number of second nanostructures 2608 alternately stacked on top of one another, and the upper portion 2604-2 includes a number of third nanostructures 2610 and a number of fourth nanostructures 2612 alternately stacked on top of one another.

The substrate 2601, the first nanostructures 2606, and the third nanostructures 2610 may be formed of a first semiconductor material, e.g., silicon (Si), while the second nanostructures 2608 and the fourth nanostructures 2612 may be formed of a second semiconductor material, e.g., silicon germanium (Si₁₋ₓGeₓ). Further, the lower portion 2604-1 and the upper portion 2604-2 are separated from each other with a fifth nanostructure 2614 formed of a third semiconductor material, e.g., silicon germanium (Si_{1-y}Ge_{y}). In some embodiments, the molar ratio “x” of the second semiconductor material may be less than 0.5, and the molar ratio “y” of the third semiconductor material may be higher than 0.5.

The nanostructures 2606 to 2612 can be epitaxially grown from the semiconductor substrate 2601. For example, each of the nanostructures 2606 to 2612 may be grown by a molecular beam epitaxy (MBE) process, a chemical vapor deposition (CVD) process such as a metal organic CVD (MOCVD) process, and/or other suitable epitaxial growth processes. Upon growing the nanostructures 2606 to 2612 on the substrate 2601 as a blanket stack, the blanket stack may be patterned to form the stack 2604 shown in FIG. 26 (e.g., having a lengthwise direction in the X-direction and a relatively narrow width in the Y-direction). After the stack 2604 is formed, the dummy gate structure 2602, including a dummy gate dielectric (e.g., silicon oxide) and a dummy gate material (e.g., polysilicon), is formed to straddle the stack 2604.

Corresponding to operation 2504 of FIG. 25, FIG. 27 is a cross-sectional view of the CFET structure 2600 in which source/drain recesses 2620 are formed, at one of the various stages of fabrication. The cross-sectional view of FIG. 27 is cut along the lengthwise direction of an active region of the CFET structure 2600 (e.g., the X-direction illustrated above).

To form the source/drain recesses 2620, a pair of gate spacers 2616 may be formed on opposite sidewalls of the dummy gate structure 2602. Next, with the dummy gate structure 2602 and the gate spacers 2616 serving as a mask, the stack 2604 is again patterned to form the source/drain recesses 2620 using an anisotropic etching process. Such an anisotropic etching process can include reactive ion etch (RIE), neutral beam etch (NBE), the like, or combinations thereof.

Corresponding to operation 2506 of FIG. 25, FIG. 28 is a cross-sectional view of the CFET structure 2600 in which the second nanostructures 2608 and the fourth nanostructures 2612 are laterally recessed, at one of the various stages of fabrication. The cross-sectional view of FIG. 28 is cut along the lengthwise direction of an active region of the CFET structure 2600 (e.g., the X-direction illustrated above).

As shown, respective end portions of each of the second nanostructures 2608 and the fourth nanostructures 2612 (formed of Si₁₋ₓGeₓ) are removed (e.g., etched) using a “pull-back” process to pull each of the nanostructures 2608 and 2612 back by a pull-back distance. For example, the pull-back process may include a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, the nanostructures 2606 (Si), 2610 (Si), and 2614 (Si_{1-y}Ge_{y}) may remain substantially intact during this process, and a number of recess 2624, each inwardly extending from the source/drain recess 2620, can be formed.

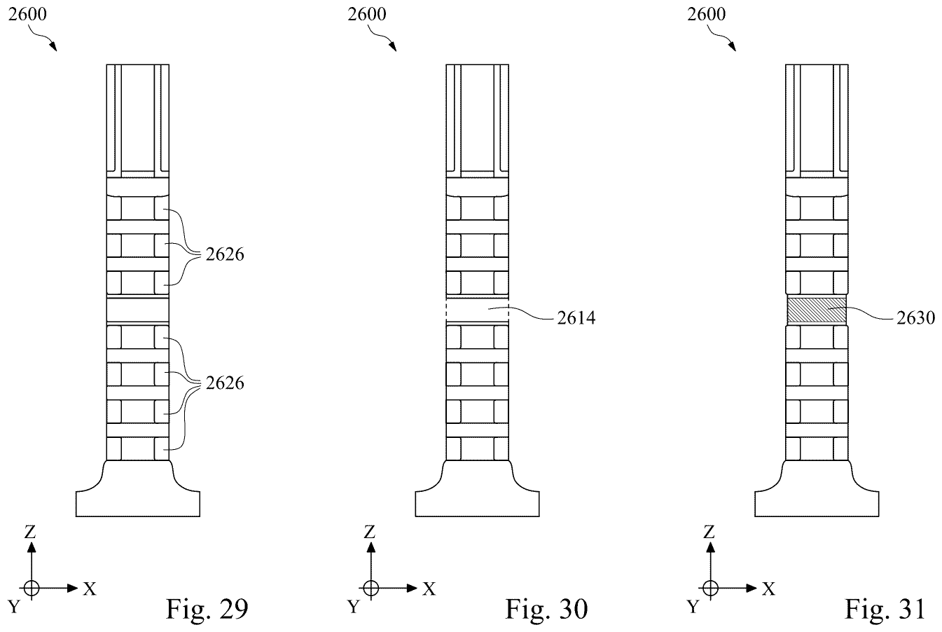

Corresponding to operation 2508 of FIG. 25, FIG. 29 is a cross-sectional view of the CFET structure 2600 including a number of inner spacers 2626, at one of the various stages of fabrication. The cross-sectional view of FIG. 29 is cut along the lengthwise direction of an active region of the CFET structure 2600 (e.g., the X-direction illustrated above).

The inner spacers 2626 can be formed by filling the recesses 2624 with a dielectric material. For example, the inner spacers 2626 can be deposited using, e.g., a conformal deposition process and subsequent isotropic or anisotropic etch back to remove excess spacer material on the sidewalls of the stack 2604. The dielectric material, used to form the inner spacer 2626, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

Corresponding to operation 2510 of FIG. 25, FIG. 30 is a cross-sectional view of the CFET structure 2600 in which the fifth nanostructure 2614 is removed, at one of the various stages of fabrication. The cross-sectional view of FIG. 30 is cut along the lengthwise direction of an active region of the CFET structure 2600 (e.g., the X-direction illustrated above).

After forming the inner spacers 2626, the fifth nanostructure 2614 can be selectively removed using an isotropic etching process that etches Si_{1-y}Ge_{y} without attacking Si. As such, the first nanostructures 2606 (Si) and third nanostructures 2610 (Si) can remain substantially intact, the fifth nanostructure 2614 (Si_{1-y}Ge_{y}) can be completely removed, and the remaining portions of the second nanostructures 2608 (Si₁₋ₓGeₓ) and fourth nanostructures 2612 (Si₁₋ₓGeₓ) can remain with the protection of the inner spacers 2626.

Corresponding to operation 2512 of FIG. 25, FIG. 31 is a cross-sectional view of the CFET structure 2600 including a dielectric layer 2630, at one of the various stages of fabrication. The cross-sectional view of FIG. 31 is cut along the lengthwise direction of an active region of the CFET structure 2600 (e.g., the X-direction illustrated above).

After the fifth nanostructure 2614 is removed, a space is formed between the lower portion 2604-1 and the upper portion 2604-2. The dielectric layer 2630 can be formed by filling the space with a dielectric material. The dielectric material, used to form the dielectric layer 2630, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

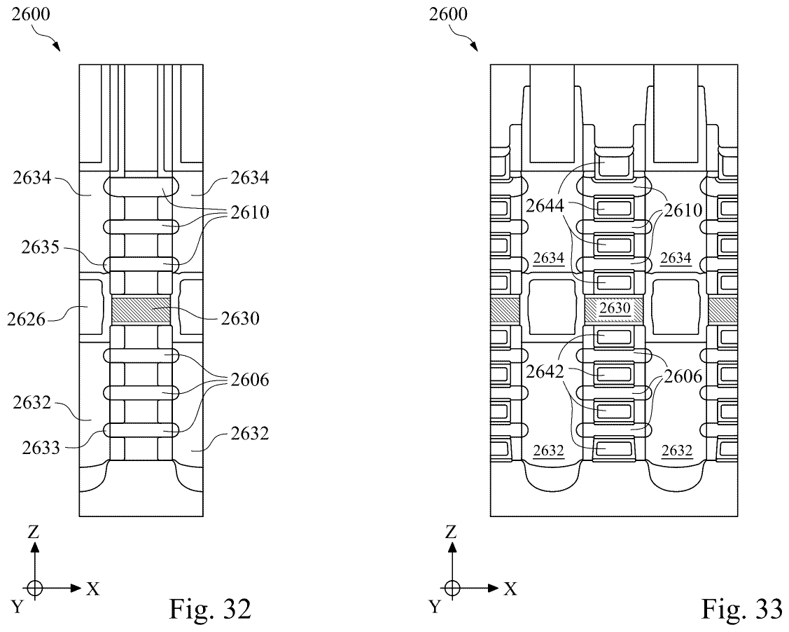

Corresponding to operation 2514 of FIG. 25, FIG. 32 is a cross-sectional view of the CFET structure 2600 including a number of first epitaxial structures 2632 and a number of second epitaxial structures 2634, at one of the various stages of fabrication. The cross-sectional view of FIG. 32 is cut along the lengthwise direction of an active region of the CFET structure 2600 (e.g., the X-direction illustrated above).

As shown, a pair of the first epitaxial structure 2632 are coupled to ends of each of the first nanostructures 2606, respectively; and a pair of the second epitaxial structure 2634 are coupled to ends of each of the third nanostructures 2610, respectively. The first epitaxial structures 2632 can be formed through a first epitaxial growth process, followed by a second epitaxial growth process for forming the second epitaxial structures 2634. Further, between the first epitaxial growth process and the second epitaxial growth process, one or more dielectric layers 2636 can be formed to electrically isolate the first epitaxial structures 2632 and the second epitaxial structures 2634. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the first epitaxial structures 2632 can be grown from the first nanostructures 2606, and the second epitaxial structures 2634 can be grown from the third nanostructures 2610.

The first epitaxial structures 2632 and the second epitaxial structures 2634 may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAlP), indium phosphide (InP), any other suitable material, or combinations thereof. Further, in-situ doping (ISD) may be applied during the formation of each of the first epitaxial structures 2632 and the second epitaxial structures 2634. For example, the first epitaxial structures 2632 can be doped by implanting p-type dopants, e.g., boron (B), etc., into them; and the second epitaxial structures 2634 can be doped by implanting n-type dopants, e.g., arsenic (As), phosphorous (P), etc., into them. In some embodiments, the first epitaxial structure 2632 can be coupled to each of the first nanostructures 2606 through a lightly doped region 2633 (e.g., SiGeB); and the second epitaxial structure 2634 can be coupled to each of the third nanostructures 2610 through a lightly doped region 2635 (e.g., SiP).

Corresponding to operation 2516 of FIG. 25, FIG. 33 is a cross-sectional view of the CFET structure 2600 including a first active gate structure 2642 and a second active gate structure 2644, at one of the various stages of fabrication. The cross-sectional view of FIG. 33 is cut along the lengthwise direction of an active region of the CFET structure 2600 (e.g., the X-direction illustrated above).

As shown, the first active gate structure 2642 wraps around each of the first nanostructures 2606; and the second active gate structure 2644 wraps around each of the third nanostructures 2610. To form the first active gate structure 2642 and second active gate structure 2644, the dummy gate structure 2602, the remaining portions of the second nanostructures 2608, and the remaining portions of the fourth nanostructures 2612 are removed. As such, a first gate trench, exposing each of the first nanostructures 2606, may be formed in the lower portion 2604-1 (e.g., the first level); and a second gate trench, exposing each of the third nanostructures 2610, may be formed in the upper portion 2604-2 (e.g., the second level). Next, the first active gate structure 2642 can be formed in the first gate trench to wrap around each of the first nanostructures 2606; and the second active gate structure 2644 can be formed in the second gate trench to wrap around each of the third nanostructures 2610.

In some embodiments, the first active gate structure 2642 can include a first gate dielectric and a first gate metal; and the second active gate structure 2644 can include a second gate dielectric and a second gate metal. The first/second gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The first/second gate dielectric may include a stack of multiple high-k dielectric materials. The first gate metal may include one or more p-type work function metals, which may include TiN, TaN, Ru, Mo, Al, WN, ZrSi₂, MoSi₂, TaSi₂, NiSi₂, WN, other suitable p-type work function materials, or combinations thereof; and the second gate metal may include one or more n-type work function metals, may include Ti, Ag, TaAl, TaAlC, TiAlN, TaC, TaCN, TaSiN, Mn, Zr, other suitable n-type work function materials, or combinations thereof.

Upon the first and second active gate structures 2642-2644 being formed, at least one p-type transistor can be formed at the first level, and at least one n-type transistor can be formed at the second level. The p-type transistor can be operatively formed based on the first nanostructures 2606, the gate structure 2642, and the pair of first epitaxial structures 2632, which can, for example, correspond to the nanostructures 1010, gate structure 1020, and epitaxial structures 1014-1016 (FIGS. 10, 14, 24), respectively. The n-type transistor can be operatively formed based on the third nanostructures 2610, the gate structure 2644, and the pair of second epitaxial structures 2634, which can, for example, correspond to the nanostructures 1030, gate structure 1040, and epitaxial structures 1034-1036 (FIGS. 10, 14, 24), respectively.

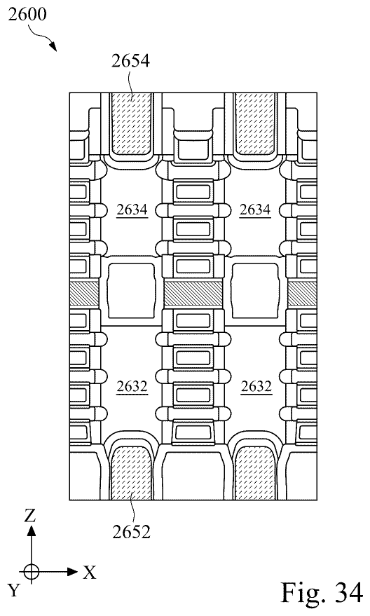

Corresponding to operation 2518 of FIG. 25, FIG. 34 is a cross-sectional view of the CFET structure 2600 including first connection structures 2652 and second connection structures 2654, at one of the various stages of fabrication. The cross-sectional view of FIG. 34 is cut along the lengthwise direction of an active region of the CFET structure 2600 (e.g., the X-direction illustrated above).

As shown, the first connection structure 2652 is coupled to a corresponding one of the first epitaxial structures 2632; and the second connection structure 2654 is coupled to a corresponding one of the second epitaxial structures 2634. For example, the first connection structure 2652 may be formed below the first epitaxial structure 2632; and the second connection structure 2654 may be formed above the second epitaxial structure 2634. For another example, the first connection structure 2652 may wrap around the first epitaxial structure 2632; and the second connection structure 2654 may wrap around the second epitaxial structure 2634. In some embodiments, the first connection structure 2652 and the second connection structure 2654 may each be configured as MD, as described above, which can include titanium, aluminum, nickel, tungsten, tantalum, or other suitable metal materials.

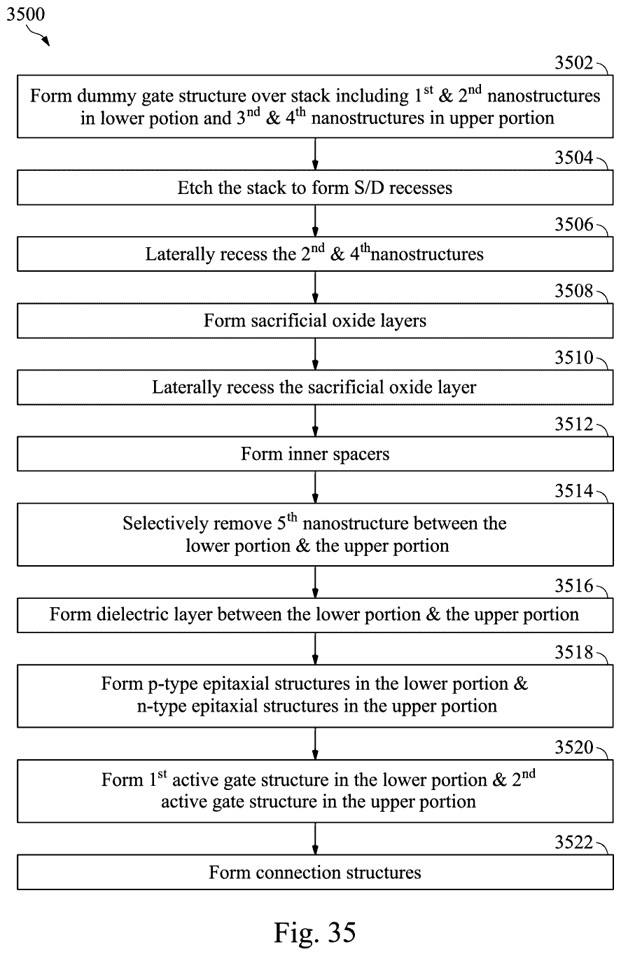

FIG. 35 illustrates a flow chart of another example method 3500 for forming a memory cell configured in a CFET structure, according to some embodiments of the present disclosure. For example, at least some of the operations (or steps) of the method 3500 can be used to form the memory cell 100 (FIG. 1) or the memory cell 1500 (FIG. 15) in the CFET structure, which includes a number of p-type transistors disposed at the first level on the frontside of a substrate and a number of n-type transistors disposed at the second, upper level on the frontside of the substrate.

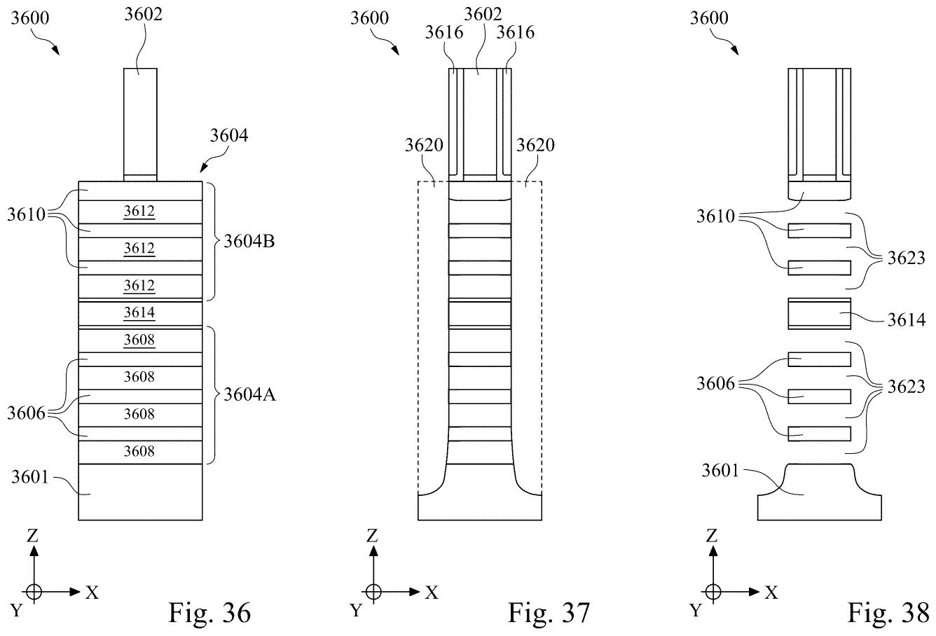

It should be appreciated that the method 3500 is merely an example, and is not intended to limit the present disclosure. Accordingly, it is understood that additional operations may be provided before, during, and after the method 3500 of FIG. 35, and that some other operations may only be briefly described herein. In some embodiments, operations of the method 3500 may be associated with cross-sectional views of a CFET structure 3600 (similar to the semiconductor device 2400 of FIG. 24) at various fabrication stages as shown in FIGS. 37, 38, 39, 40, 41, 42, 43, 44, 45, 46, and 47, respectively, which will be discussed in further detail below.

As a brief overview, the method 3500 starts with operation 3502 of forming a number of dummy gate structures over a stack including a lower portion and an upper portion. The lower portion includes a number of first nanostructures and a number of second nanostructures alternately stacked on top of one another, and the upper portion includes a number of third nanostructures and a number of fourth nanostructures alternately stacked on top of one another. The first and third nanostructures may be formed of a first semiconductor material, and the second and fourth nanostructures may be formed of a second semiconductor material. Further, the lower portion and the upper portion may be separated from each other with a fifth nanostructure formed of a third semiconductor material. The method 3500 continues to operation 3504 of etching the stack to form source/drain recesses. The 3500 continues to operation 3506 of removing the second nanostructures and the fourth nanostructures. The method 3500 continues to operation 3508 of forming a plural number of sacrificial oxide layers each interposed between adjacent ones of the first nanostructures or between adjacent ones of the third nanostructures. The method 3500 continues to operation 3510 of laterally recessing the sacrificial oxide layers. The method 3500 continues to operation 3512 of forming a number of inner spacers. The method 3500 continues to operation 3514 of selectively removing the fifth nanostructure. The method 3500 continues to operation 3516 of forming a dielectric layer between the lower portion and the upper portion. The method 3500 continues to operation 3518 of forming a number of p-type epitaxial structures in the lower portion and a number of n-type epitaxial structures in the upper portion. The method 3500 continues to operation 3520 of forming a first active gate structure in the lower portion and a second active gate structure in the upper portion. The method 3500 continues to operation 3522 of forming a number of connection structures.

Corresponding to operation 3502 of FIG. 35, FIG. 36 is a cross-sectional view of the CFET structure 3600 including a number of dummy gate structures 3602 over a stack 3604, at one of the various stages of fabrication. The cross-sectional view of FIG. 36 is cut along the lengthwise direction of an active region of the CFET structure 3600 (e.g., the X-direction illustrated above).

In some embodiments, the stack 3604 may be formed over a semiconductor substrate 3601, followed by the dummy gate structure 3602 formed over the stack 3604. The stack 3604 can extend along the X-direction, and the dummy gate structure 3602 can extend along the Y-direction to straddle or otherwise traverse the stack 3604. The stack 3604 includes a lower portion 3604-1 and an upper portion 3604-2, which can correspond to the first level and the second level on the frontside of the substrate (e.g., FIGS. 10, 14, 24), respectively. The lower portion 3604-1 includes a number of first nanostructures 3606 and a number of second nanostructures 3608 alternately stacked on top of one another, and the upper portion 3604-2 includes a number of third nanostructures 3610 and a number of fourth nanostructures 3612 alternately stacked on top of one another.

The substrate 3601, the first nanostructures 3606, and the third nanostructures 3610 may be formed of a first semiconductor material, e.g., silicon (Si), while the second nanostructures 3608 and the fourth nanostructures 3612 may be formed of a second semiconductor material, e.g., silicon germanium (Si₁₋ₓGeₓ). Further, the lower portion 3604-1 and the upper portion 3604-2 are separated from each other with a fifth nanostructure 3614 formed of a third semiconductor material, e.g., silicon germanium (Si_{1-y}Ge_{y}). In some embodiments, the molar ratio “x” of the second semiconductor material may be less than 0.5, and the molar ratio “y” of the third semiconductor material may be higher than 0.5.

The nanostructures 3606 to 3612 can be epitaxially grown from the semiconductor substrate 3601. For example, each of the nanostructures 3606 to 3612 may be grown by a molecular beam epitaxy (MBE) process, a chemical vapor deposition (CVD) process such as a metal organic CVD (MOCVD) process, and/or other suitable epitaxial growth processes. Upon growing the nanostructures 3606 to 3612 on the substrate 3601 as a blanket stack, the blanket stack may be patterned to form the stack 3604 shown in FIG. 36 (e.g., having a lengthwise direction in the X-direction and a relatively narrow width in the Y-direction). After the stack 3604 is formed, the dummy gate structure 3602, including a dummy gate dielectric (e.g., silicon oxide) and a dummy gate material (e.g., polysilicon), is formed to straddle the stack 3604.

Corresponding to operation 3504 of FIG. 35, FIG. 37 is a cross-sectional view of the CFET structure 3600 in which source/drain recesses 3620 are formed, at one of the various stages of fabrication. The cross-sectional view of FIG. 37 is cut along the lengthwise direction of an active region of the CFET structure 3600 (e.g., the X-direction illustrated above).

To form the source/drain recesses 3620, a pair of gate spacers 3616 may be formed on opposite sidewalls of the dummy gate structure 3602. Next, with the dummy gate structure 3602 and the gate spacers 3616 serving as a mask, the stack 3604 is again patterned to form the source/drain recesses 3620 using an anisotropic etching process. Such an anisotropic etching process can include reactive ion etch (RIE), neutral beam etch (NBE), the like, or combinations thereof.

Corresponding to operation 3506 of FIG. 35, FIG. 38 is a cross-sectional view of the CFET structure 3600 in which the second nanostructures 3608 and the fourth nanostructures 3612 are removed, at one of the various stages of fabrication. The cross-sectional view of FIG. 38 is cut along the lengthwise direction of an active region of the CFET structure 3600 (e.g., the X-direction illustrated above).

In some embodiments, the second nanostructures 3608 and the fourth nanostructures 3612 may be selectively removed (e.g. etched), with the first nanostructures 3606, the third nanostructures 3610, and the fifth nanostructure 3614 remaining substantially intact. The second nanostructures 3608 and the fourth nanostructures 3612 may be completely removed using a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, a plural number of spaces 3623 can be formed. Each of the spaces 3623 can be vertically interposed between the substrate 3601 and a bottommost one of the first nanostructures 3606, between the adjacent ones of the first nanostructures 3606, between a topmost one of the first nanostructures 3606 and the fifth nanostructure 3614, between the fifth nanostructure 3614 and a bottommost one of the third nanostructures 3610, or between the adjacent ones of the third nanostructures 3610, as shown in FIG. 38.

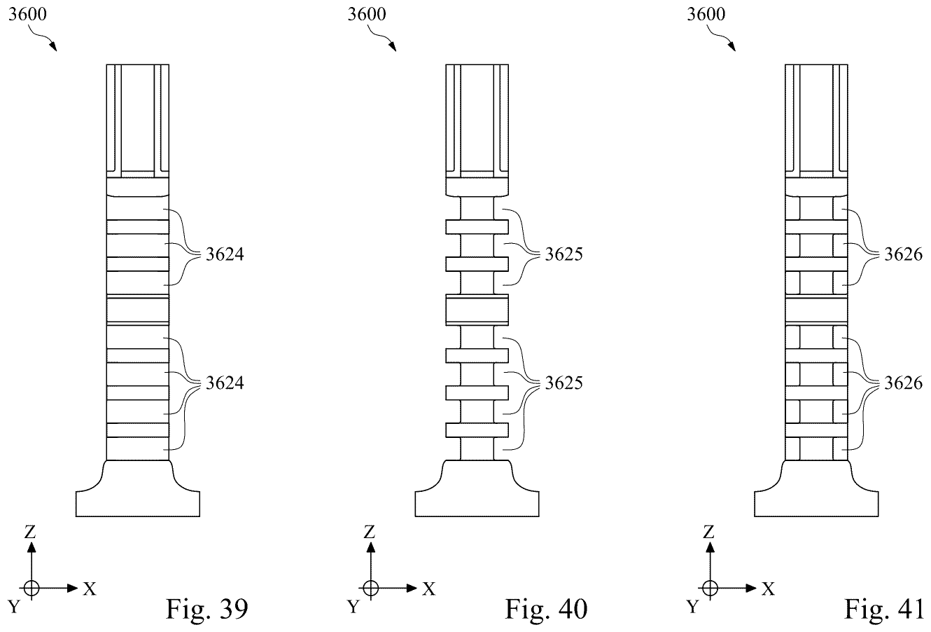

Corresponding to operation 3508 of FIG. 35, FIG. 39 is a cross-sectional view of the CFET structure 3600 including a plural number of sacrificial oxide layers 3624, at one of the various stages of fabrication. The cross-sectional view of FIG. 39 is cut along the lengthwise direction of an active region of the CFET structure 3600 (e.g., the X-direction illustrated above).

As shown, the sacrificial oxide layers 3624 are formed at least in the spaces 3623, respectively. In some embodiments, the sacrificial oxide layers 3624 may be formed using, e.g., a conformal deposition process to deposit an oxide material and one or more subsequent isotropic or anisotropic etching processes to remove the excessive oxide material on the sidewalls of the stack 3604. As such, the sacrificial oxide layers 3624 can each be vertically interposed between the substrate 3601 and the bottommost first nanostructures 3606, between the adjacent first nanostructures 3606, between the topmost first nanostructure 3606 and the fifth nanostructure 3614, between the fifth nanostructure 3614 and the bottommost third nanostructure 3610, or between the adjacent third nanostructures 3610, as shown in FIG. 39.

Corresponding to operation 3510 of FIG. 35, FIG. 40 is a cross-sectional view of the CFET structure 3600 in which the sacrificial oxide layers 3624 are laterally recessed, at one of the various stages of fabrication. The cross-sectional view of FIG. 39 is cut along the lengthwise direction of an active region of the CFET structure 3600 (e.g., the X-direction illustrated above).

As shown, respective end portions of each of the sacrificial oxide layers 3624 are removed (e.g., etched) using a “pull-back” process to pull each of the sacrificial oxide layers 3624 back by a pull-back distance. For example, the pull-back process may include a hydrofluoric acid (HF) gas isotropic etching process, which etches silicon oxide without attacking Si or SiGe with the higher Ge composition (e.g., Si_{1-y}Ge_{y}). As such, the nanostructures 3606 (Si), 3610 (Si), and 3614 (Si_{1-y}Ge_{y}) may remain substantially intact during this process, and a number of recess 3625, each inwardly extending from the source/drain recess 3620, can be formed.

Corresponding to operation 3512 of FIG. 35, FIG. 41 is a cross-sectional view of the CFET structure 3600 including a number of inner spacers 3626, at one of the various stages of fabrication. The cross-sectional view of FIG. 41 is cut along the lengthwise direction of an active region of the CFET structure 3600 (e.g., the X-direction illustrated above).

The inner spacers 3626 can be formed by filling the recesses 3625 with a dielectric material. For example, the inner spacers 3626 can be deposited using, e.g., a conformal deposition process and subsequent isotropic or anisotropic etch back to remove excess spacer material on the sidewalls of the stack 3604. The dielectric material, used to form the inner spacer 3626, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

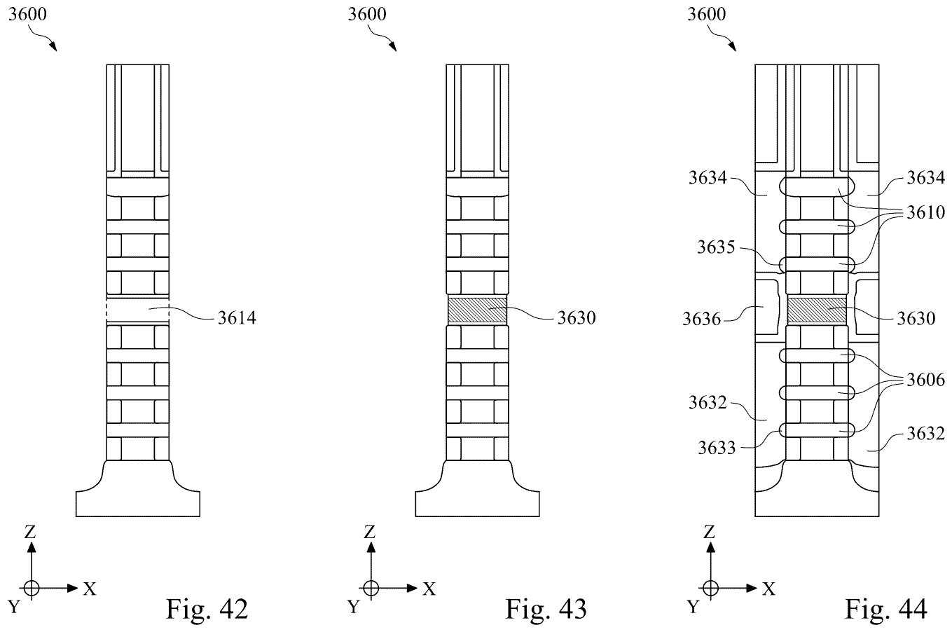

Corresponding to operation 3514 of FIG. 35, FIG. 42 is a cross-sectional view of the CFET structure 3600 in which the fifth nanostructure 3614 is removed, at one of the various stages of fabrication. The cross-sectional view of FIG. 42 is cut along the lengthwise direction of an active region of the CFET structure 3600 (e.g., the X-direction illustrated above).

After forming the inner spacers 3626, the fifth nanostructure 3614 can be selectively removed using an isotropic etching process that etches Si_{1-y}Ge_{y} without attacking Si. As such, the first nanostructures 3606 (Si) and third nanostructures 3610 (Si) can remain substantially intact, the fifth nanostructure 3614 (Si_{1-y}Ge_{y}) can be completely removed, and the remaining portions of the sacrificial oxide layers 3624 can remain with the protection of the inner spacers 3626.

Corresponding to operation 3516 of FIG. 35, FIG. 43 is a cross-sectional view of the CFET structure 3600 including a dielectric layer 3630, at one of the various stages of fabrication. The cross-sectional view of FIG. 43 is cut along the lengthwise direction of an active region of the CFET structure 3600 (e.g., the X-direction illustrated above).

After the fifth nanostructure 3614 is removed, a space is formed between the lower portion 3604-1 and the upper portion 3604-2. The dielectric layer 3630 can be formed by filling the space with a dielectric material. The dielectric material, used to form the dielectric layer 3630, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

Corresponding to operation 3518 of FIG. 35, FIG. 44 is a cross-sectional view of the CFET structure 3600 including a number of first epitaxial structures 3632 and a number of second epitaxial structures 3634, at one of the various stages of fabrication. The cross-sectional view of FIG. 44 is cut along the lengthwise direction of an active region of the CFET structure 3600 (e.g., the X-direction illustrated above).

As shown, a pair of the first epitaxial structure 3632 are coupled to ends of each of the first nanostructures 3606, respectively; and a pair of the second epitaxial structure 3634 are coupled to ends of each of the third nanostructures 3610, respectively. The first epitaxial structures 3632 can be formed through a first epitaxial growth process, followed by a second epitaxial growth process for forming the second epitaxial structures 3634. Further, between the first epitaxial growth process and the second epitaxial growth process, one or more dielectric layers 3636 can be formed to electrically isolate the first epitaxial structures 3632 and the second epitaxial structures 3634. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the first epitaxial structures 3632 can be grown from the first nanostructures 3606, and the second epitaxial structures 3634 can be grown from the third nanostructures 3610.

The first epitaxial structures 3632 and the second epitaxial structures 3634 may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAlP), indium phosphide (InP), any other suitable material, or combinations thereof. Further, in-situ doping (ISD) may be applied during the formation of each of the first epitaxial structures 3632 and the second epitaxial structures 3634. For example, the first epitaxial structures 3632 can be doped by implanting p-type dopants, e.g., boron (B), etc., into them; and the second epitaxial structures 3634 can be doped by implanting n-type dopants, e.g., arsenic (As), phosphorous (P), etc., into them. In some embodiments, the first epitaxial structure 3632 can be coupled to each of the first nanostructures 3606 through a lightly doped region 3633 (e.g., SiGeB); and the second epitaxial structure 3634 can be coupled to each of the third nanostructures 3610 through a lightly doped region 3635 (e.g., SiP).

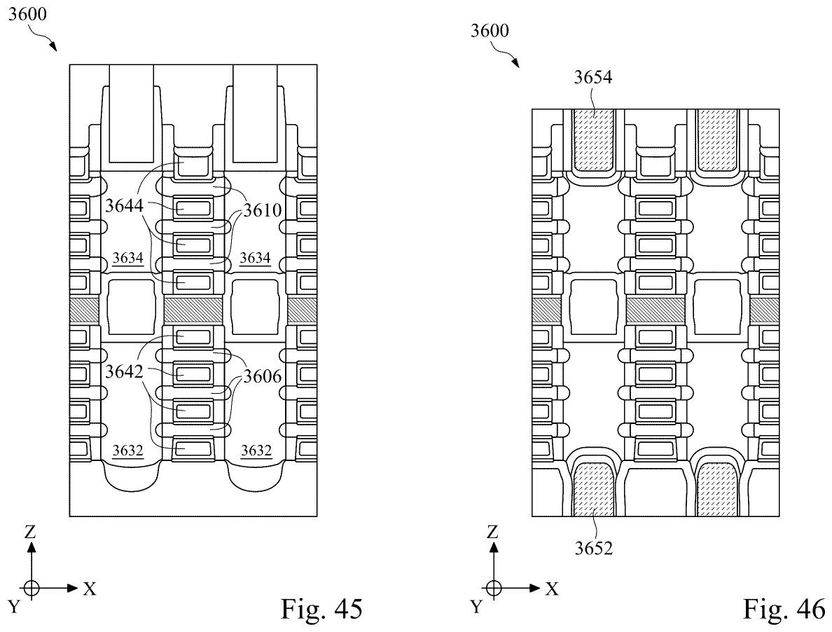

Corresponding to operation 3520 of FIG. 35, FIG. 45 is a cross-sectional view of the CFET structure 3600 including a first active gate structure 3642 and a second active gate structure 3644, at one of the various stages of fabrication. The cross-sectional view of FIG. 45 is cut along the lengthwise direction of an active region of the CFET structure 3600 (e.g., the X-direction illustrated above).

As shown, the first active gate structure 3642 wraps around each of the first nanostructures 3606; and the second active gate structure 3644 wraps around each of the third nanostructures 3610. To form the first active gate structure 3642 and second active gate structure 3644, the dummy gate structure 3602, and the remaining portions of the sacrificial oxide layers 3624 are removed. As such, a first gate trench, exposing each of the first nanostructures 3606, may be formed in the lower portion 3604-1 (e.g., the first level); and a second gate trench, exposing each of the third nanostructures 3610, may be formed in the upper portion 3604-2 (e.g., the second level). Next, the first active gate structure 3642 can be formed in the first gate trench to wrap around each of the first nanostructures 3606; and the second active gate structure 3644 can be formed in the second gate trench to wrap around each of the third nanostructures 3610.

In some embodiments, the first active gate structure 3642 can include a first gate dielectric and a first gate metal; and the second active gate structure 3644 can include a second gate dielectric and a second gate metal. The first/second gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The first/second gate dielectric may include a stack of multiple high-k dielectric materials. The first gate metal may include one or more p-type work function metals, which may include TiN, TaN, Ru, Mo, Al, WN, ZrSi₂, MoSi₂, TaSi₂, NiSi₂, WN, other suitable p-type work function materials, or combinations thereof; and the second gate metal may include one or more n-type work function metals, may include Ti, Ag, TaAl, TaAlC, TiAlN, TaC, TaCN, TaSiN, Mn, Zr, other suitable n-type work function materials, or combinations thereof.

Upon the first and second active gate structures 3642-3644 being formed, at least one p-type transistor can be formed at the first level, and at least one n-type transistor can be formed at the second level. The p-type transistor can be operatively formed based on the first nanostructures 3606, the gate structure 3642, and the pair of first epitaxial structures 3632, which can, for example, correspond to the nanostructures 1010, gate structure 1020, and epitaxial structures 1014-1016 (FIGS. 10, 14, 24), respectively. The n-type transistor can be operatively formed based on the third nanostructures 3610, the gate structure 3644, and the pair of second epitaxial structures 3634, which can, for example, correspond to the nanostructures 1030, gate structure 1040, and epitaxial structures 1034-1036 (FIGS. 10, 14, 24), respectively.

Corresponding to operation 3522 of FIG. 35, FIG. 46 is a cross-sectional view of the CFET structure 3600 including first connection structures 3652 and second connection structures 3654, at one of the various stages of fabrication. The cross-sectional view of FIG. 46 is cut along the lengthwise direction of an active region of the CFET structure 3600 (e.g., the X-direction illustrated above).

As shown, the first connection structure 3652 is coupled to a corresponding one of the first epitaxial structures 3632; and the second connection structure 3654 is coupled to a corresponding one of the second epitaxial structures 3634. For example, the first connection structure 3652 may be formed below the first epitaxial structure 3632; and the second connection structure 3654 may be formed above the second epitaxial structure 3634. For another example, the first connection structure 3652 may wrap around the first epitaxial structure 3632; and the second connection structure 3654 may wrap around the second epitaxial structure 3634. In some embodiments, the first connection structure 3652 and the second connection structure 3654 may each be configured as MD, as described above, which can include titanium, aluminum, nickel, tungsten, tantalum, or other suitable metal materials.

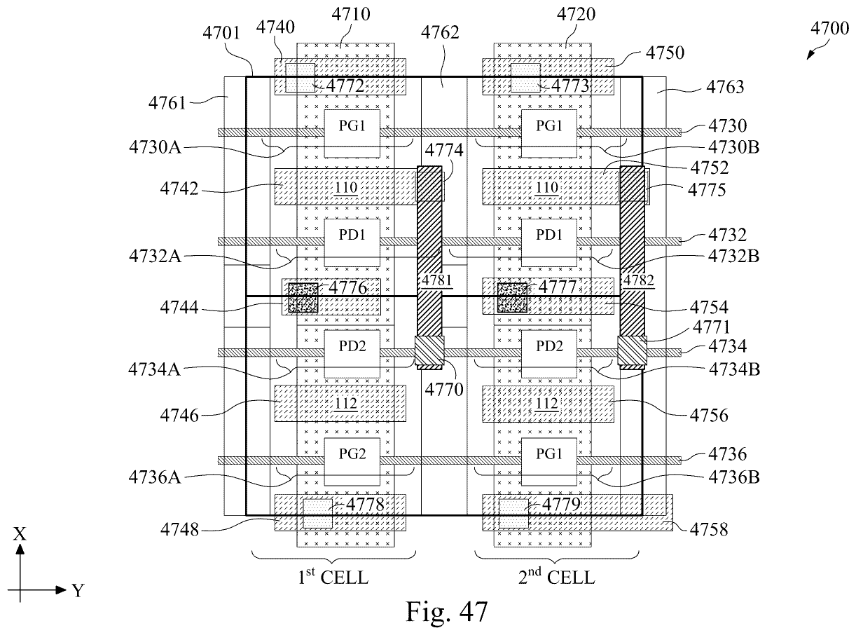

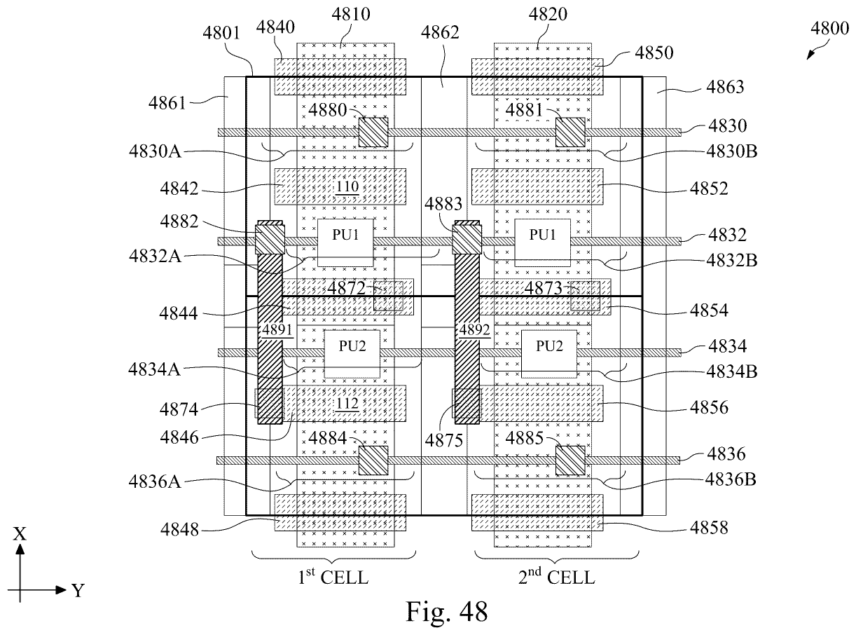

FIG. 47 and FIG. 48 respectively illustrate layouts 4700 and 4800 that can be collectively utilized to form a pair of the memory cells 100 (FIG. 1) configured in a CFET structure. As depicted, each of the layouts 4700 to 4800 includes a cell boundary 4701 defining a physical area of the pair of memory cells 100. The CFET structure can include a number of first transistors disposed at a first level on the frontside of a substate, and a number of second transistors despised at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 4700 to 4800 can include a number of patterns configured for forming respective structures, and thus, such patterns of the disclosed layout are herein referred to as the structures to be formed, respectively, in the following discussion. For example, the layout 4700 is configured to form structures of the first transistors at the first level on the frontside; and the layout 4800 is configured to form structures of the second transistors at the second level on the frontside. It should be understood that each of the layouts 4700 to 4800 has been simplified for illustrative purposes, and thus, can include any of various other patterns while remaining within the scope of the present disclosure.

Referring first to FIG. 47, the layout 4700 can include patterns for forming active regions 4710 and 4720 and gate structures 4730, 4732, 4734 and 4736, respectively. The active regions 4710 and 4720 may extend in the X-direction; and the gate structures 4730 to 4736 may extend in the Y-direction. Each of the active regions 4710 and 4720 may be formed as a fin structure or a stack structure extending along the X-direction, and each of the gate structures 4730 to 4736 may be formed to extend in the Y-direction to traverse the active regions 4710 and 4720. The layout 4700 can further include a number of cut patterns, e.g., 4761, 4762, and 4763, each of which can extend along the X-direction traversing the gate structures 4730 to 4736. The cut patterns 4761 to 4763 can each be configured to form a dielectric structure, thereby dividing the gate structures 4730-4736 into separate gate sections. For example, the cut pattern 4761-4763 can divide the gate structures 4730, 4732, 4734, and 4736 into gate sections 4730A and 4730B, gate sections 4732A and 4732B, gate sections 4734A and 4734B, and gate sections 4736A and 4736B, respectively, as indicated in FIG. 47.

Referring next to FIG. 48, the layout 4800 can include patterns for forming active regions 4810 and 4820 and gate structures 4830, 4832, 4834 and 4836, respectively. The active regions 4810 and 4820 may extend in the X-direction; and the gate structures 4830 to 4836 may extend in the Y-direction. Each of the active regions 4810 and 4820 may be formed as a fin structure or a stack structure extending along the X-direction, and each of the gate structures 4830 to 4836 may be formed to extend in the Y-direction to traverse the active regions 4810 and 4820. The layout 4800 can further include a number of cut patterns, e.g., 4862, 4862, and 4863, each of which can extend along the X-direction traversing the gate structures 4830 to 4836. The cut patterns 4861 to 4863 can each be configured to form a dielectric structure, thereby dividing the gate structures 4830-4836 into separate gate sections. For example, the cut pattern 4861-4863 can divide the gate structures 4830, 4832, 4834, and 4836 into gate sections 4830A and 4830B, gate sections 4832A and 4832B, gate sections 4834A and 4834B, and gate sections 4836A and 4836B, respectively, as indicated in FIG. 48.

In some embodiments, the active regions 4710 and 4810 are vertically aligned with each other, the active regions 4720 and 4820 are vertically aligned with each other, the gate structures 4730 and 4830 are vertically aligned with each other, the gate structures 4732 and 4832 are vertically aligned with each other, the gate structures 4734 and 4834 are vertically aligned with each other, the gate structures 4736 and 4836 are vertically aligned with each other, the cut patterns 4761 and 4861 are vertically aligned with each other, the cut patterns 4762 and 4862 are vertically aligned with each other, and the cut patterns 4763 and 4863 are vertically aligned with each other. Further, the active regions 4710 and 4810 may be physically formed as a single structure (sometimes referred to as “active region 4710/4810”), the active regions 4720 and 4820 may be physically formed as a single structure (sometimes referred to as “active region 4720/4820”), the gate structures 4730 and 4830 may be physically formed as a single structure (sometimes referred to as “gate structure 4730/4830”), the gate structures 4732 and 4832 may be physically formed as a single structure (sometimes referred to as “gate structure 4732/4832”), the gate structures 4734 and 4834 may be physically formed as a single structure (sometimes referred to as “gate structure 4734/4834”), and the gate structures 4736 and 4836 may be physically formed as a single structure (sometimes referred to as “gate structure 4736/4836”).

Based on the manufacturing processes described in FIGS. 25-46, the layouts 4700 and 4800 can be collectively utilized to form a number of first transistors at a first level on the frontside of a substrate and a number of second transistor at a second, upper level on the frontside, in which the first transistors are operatively formed based on a plural number of first nanosheets and a plural number of first epitaxial structures, and the second transistors are operatively formed based on a plural number of second nanosheets and a plural number of second epitaxial structures.

For example, the transistors PD1, PD2, PG1, and PG2 of a first memory cell 100 and the transistors PD1, PD2, PG1, and PG2 of a second memory cell 100 can be formed at the first level based on the layout 4700 (as indicated in FIG. 47), and the transistors PU1 and PU2 of the first memory cell 100 and the transistors PU1 and PU2 of the second memory cell 100 can be formed at the second level based on the layout 4800 (as indicated in FIG. 48). Further, in some embodiments, the transistors PD1, PD2, PG1, and PG2 of the first and second memory cells 100 at the first level can be formed with the p-type conductivity, and the transistors PU1 and PU2 of the first and second memory cells 100 at the second level can be formed with the n-type conductivity.

As a representative example, in FIG. 47, the transistor PD1 of the first memory cell 100 (e.g., between the cut patterns 4761 and 4762) can include its channel, gate terminal, and source/drain terminals formed by a subset of the first nanosheets in the active region 4710, the gate section 4732A, and a subset of the first epitaxial structures formed from the active region 4710 and disposed on opposite sides of the gate structure 4732, respectively. The transistor PG1 of the first memory cell 100 can include its channel, gate terminal, and source/drain terminals formed by another subset of the first nanosheets in the active region 4710, the gate section 4730A, and another subset of the first epitaxial structures formed from the active region 4710 and disposed on opposite sides of the gate structure 4730, respectively. The transistor PD2 of the first memory cell 100 can include its channel, gate terminal, and source/drain terminals formed by yet another subset of the first nanosheets in the active region 4710, the gate section 4734A, and yet another subset of the first epitaxial structures formed from the active region 4710 and disposed on opposite sides of the gate structure 4734, respectively. The transistor PG2 of the first memory cell 100 can include its channel, gate terminal, and source/drain terminals formed by yet another subset of the first nanosheets in the active region 4710, the gate section 4736A, and yet another subset of the first epitaxial structures formed from the active region 4710 and disposed on opposite sides of the gate structure 4736, respectively.

As another representative example, in FIG. 48, the transistor PU1 of the first memory cell 100 (e.g., between the cut patterns 4861 and 4862) can include its channel, gate terminal, and source/drain terminals formed by a subset of the second nanosheets in the active region 4810, the gate section 4832A, and a subset of the second epitaxial structures formed from the active region 4810 and disposed on opposite sides of the gate structure 4832, respectively. The transistor PU2 of the first memory cell 100 can include its channel, gate terminal, and source/drain terminals formed by another subset of the second nanosheets in the active region 4810, the gate section 4834A, and another subset of the second epitaxial structures formed from the active region 4810 and disposed on opposite sides of the gate structure 4834, respectively.

Referring again to FIG. 47, the layout 4700 can further include patterns for forming source/drain contact structures (MDs) 4740, 4742, 4744, 4746, 4748, 4750, 4752, 4754, 4756, and 4758, respectively. Similarly in FIG. 48, the layout 4800 can further include patterns for forming source/drain contact structures (MDs) 4840, 4842, 4844, 4846, 4848, 4850, 4852, 4854, 4856, and 4858, respectively. Each of these MDs is configured to electrically connect to the source/drain terminal of a corresponding transistor.

For example, in FIG. 47, the MD 4740 is connected to a first source/drain terminal of the transistor PG1 of the first memory cell 100; the MD 4742 is connected to a second source/drain terminal of the transistor PG1 and a first source/drain terminal of the transistor PD1 of the first memory cell 100; the MD 4744 is connected to a second source/drain terminal of the transistor PD1 and a first source/drain terminal of the transistor PD2 of the first memory cell 100; the MD 4746 is connected to a second source/drain terminal of the transistor PD2 and a first source/drain terminal of the transistor PG2 of the first memory cell 100; and the MD 4748 is connected to a second source/drain terminal of the transistor PG2 of the first memory cell 100. In FIG. 48, the MD 4842 is connected to a first source/drain terminal of the transistor PU1 of the first memory cell 100; the MD 4844 is connected to a second source/drain terminal of the transistor PU1 and a first source/drain terminal of the transistor PU2 of the first memory cell 100; and the MD 4846 is connected to a second source/drain terminal of the transistor PU2 of the first memory cell 100.

In some embodiments, for the first memory cell 100, the MD 4742 (FIG. 47) and MD 4842 (FIG. 48) may be connected to each other through a first via structure (not shown), and the MD 4746 (FIG. 47) and MD 4846 (FIG. 48) may be connected to teach other through a second via structure (not shown). Stated another way, the first via structure can vertically extend from the first level to the second level to connect the MD 4742 to the MD 4842, and the second via structure can vertically extend from the first level to the second level to connect the MD 4746 to the MID 4846. As such, the (internal) node 110 of the first memory cell 100, connecting the respective source/drain terminals of the transistors PU1, PD1, and PG1 to one another, can be operatively formed based on the MD 4742, the MID 4842, and the first via structure vertically interposed therebetween, and the (internal) node 112 of the first memory cell 100, connecting the respective source/drain terminals of the transistors PU2, PD2, and PG2 to one another, can be operatively formed based on the MD 4746, the MID 4846, and the second via structure vertically interposed therebetween. The connections among the MDs for the second memory cell 100 are the same, so that the description is not repeated.

Referring again to FIG. 47, the layout 4700 can further include patterns for forming a number of first via structures (BVDs) 4772, 4773, 4774, 4775, 4776, 4777, 4778, and 4779, respectively. In some embodiments, each of the BVDs 4772 to 4779 can be formed below an MD included in the layout 4700. Particularly, the BVDs 4772 to 4779 can each downwardly extend from the corresponding MD to a backside of the substrate. For example, the BVD 4772 can be coupled to and downwardly extend from the MD 4742; the BVD 4773 can be coupled to and downwardly extend from the MID 4750; the BVD 4774 can be coupled to and downwardly extend from the MD 4742; the BVD 4775 can be coupled to and downwardly extend from the MD 4752; the BVD 4776 can be coupled to and downwardly extend from the MD 4744; the BVD 4777 can be coupled to and downwardly extend from the MD 4754; the BVD 4778 can be coupled to and downwardly extend from the MD 4748; and the BVD 4779 can be coupled to and downwardly extend from the MD 4758.

Further, in some embodiments, the BVD 4772 can electrically connect the MD 4740 to a first interconnect structure formed on the backside (e.g., a first BM0 track) and configured as the BL of the first memory cell 100; the BVD 4776 can electrically connect the MD 4744 to a second interconnect structure formed on the backside (e.g., a second BM0 track) and configured to carry the ground voltage VSS for the first memory cell 100; the BVD 4778 can electrically connect the MD 4748 to a third interconnect structure formed on the backside (e.g., a third BM0 track) and configured as the BLB of the first memory cell 100; the BVD 4773 can electrically connect the MD 4750 to a fourth interconnect structure formed on the backside (e.g., a fourth BM0 track) and configured as the BL of the second memory cell 100; the BVD 4777 can electrically connect the MD 4754 to a fifth interconnect structure formed on the backside (e.g., a fifth BM0 track) and configured to carry the ground voltage VSS for the second memory cell 100; and the BVD 4779 can electrically connect the MD 4758 to a sixth interconnect structure formed on the backside (e.g., a sixth BM0 track) and configured as the BLB of the second memory cell 100.

The layout 4700 can further include patterns for forming a number of second via structures (BVGs) 4770 and 4771, respectively. In some embodiments, each of the BVGs 4770 and 4771 can be formed below a gate structure in the layout 4700. Particularly, the BVGs 4770 and 4771 can each downwardly extend from the corresponding gate structure. For example, the BVG 4770 can be coupled to and downwardly extend from the gate structure 4734 (or the gate section 4734A); and the BVG 4771 can be coupled to and downwardly extend from the gate structure 4734 (or the gate section 4734B).

The layout 4700 can further include patterns form forming internal contact structures 4781 and 4782, respectively. The internal contact structures 4781 and 4782 can extend along the X-direction, and be formed on the backside of the substrate (e.g., as BM0 tracks). In some embodiments, the internal contact structures 4781 and 4782 can each be configured to electrically connect an internal node of the memory cell 100 to the gate terminal(s) of one or more transistors. For example, in the first memory cell 100, the internal contact structure 4781 can electrically connect the MD 4742 (the common source/drain terminals of the transistors PG1 and PD1, or the internal node 110) to the gate section 4734A (the gate terminal of the transistor PD2) through the BVD 4774 and the BVG 4770; and, in the second memory cell 100, the internal contact structure 4782 can electrically connect the MD 4752 (the common source/drain terminals of the transistors PG1 and PD1, or the internal node 110) to the gate section 4734B (the gate terminal of the transistor PD2) through the BVD 4775 and the BVG 4771.

Referring again to FIG. 48, the layout 4800 can further include patterns for forming a number of first via structures (VDs) 4872, 4873, 4874, and 4875, respectively. In some embodiments, each of the VDs 4872 to 4875 can be formed above an MD included in the layout 4800. Particularly, the VDs 4872 to 4875 can each upwardly extend from the corresponding MD. For example, the VD 4872 can be coupled to and upwardly extend from the MD 4844; the VD 4873 can be coupled to and upwardly extend from the MD 4854; the VD 4874 can be coupled to and upwardly extend from the MID 4846; and the VD 4875 can be coupled to and upwardly extend from the MD 4856. In some embodiments, the VD 4872 allows the MD 4844 (the common source/drain terminals of the transistors PU1 and PU2 of the first memory cell 100) to one or more interconnect structures formed in an upper level (e.g., a first interconnect structure formed at a third, upper level on the frontside and configured to carry the supply voltage VDD); and the VD 4873 allows the MD 4854 (the common source/drain terminals of the transistors PU1 and PU2 of the second memory cell 100) to one or more interconnect structures formed in the upper level (e.g., a second interconnect structure formed at the third, upper level on the frontside and configured to carry the supply voltage VDD). The layout 4800 can further include patterns for forming a number of second via structures (VGs) 4880, 4881, 4882, 4883, 4884, and 4885, respectively. In some embodiments, each of the VGs 4880 and 4885 can be formed above a gate structure in the layout 4800. Particularly, the VGs 4880 and 4885 can upwardly extend from the corresponding gate structure.

The layout 4800 can further include patterns for forming internal contact structures 4891 and 4892, respectively. The internal contact structures 4891 and 4892 can extend along the X-direction, and be formed on third, upper level on the frontside (e.g., as M0 tracks). In some embodiments, the internal contact structures 4891 and 4892 can each be configured to electrically connect an internal node of the memory cell 100 to the gate terminal(s) of one or more transistors. For example, in the first memory cell 100, the internal contact structure 4891 can electrically connect the MD 4846 (the common source/drain terminals of the transistors PD2 and PU2, or the internal node 112) to the gate section 4832A (the gate terminal of the transistor PU1) through the VD 4874 and the VG 4882; and, in the second memory cell 100, the internal contact structure 4892 can electrically connect the MD 4856 (the common source/drain terminals of the transistors PD2 and PU2, or the internal node 112) to the gate section 4832B (the gate terminal of the transistor PU1) through the VD 4875 and the VG 4883.

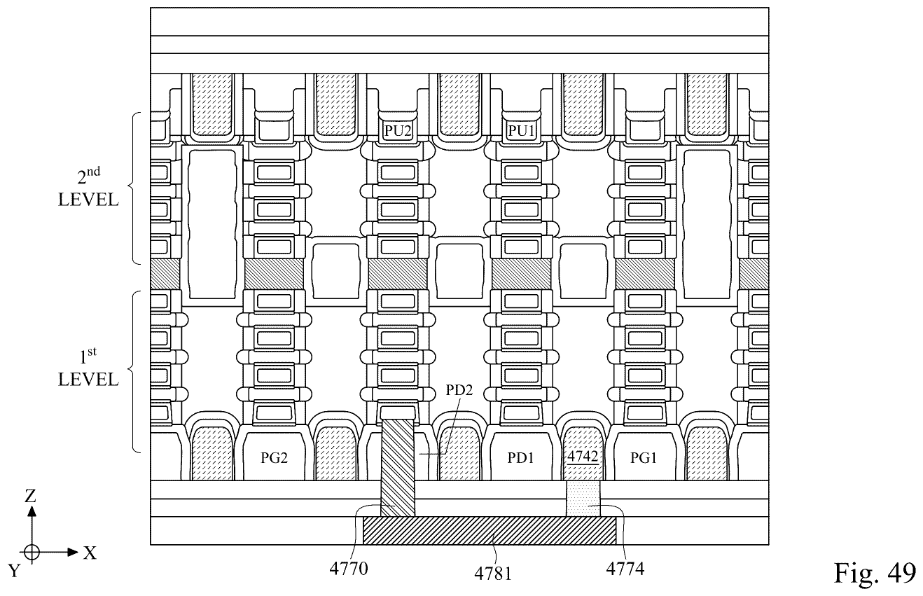

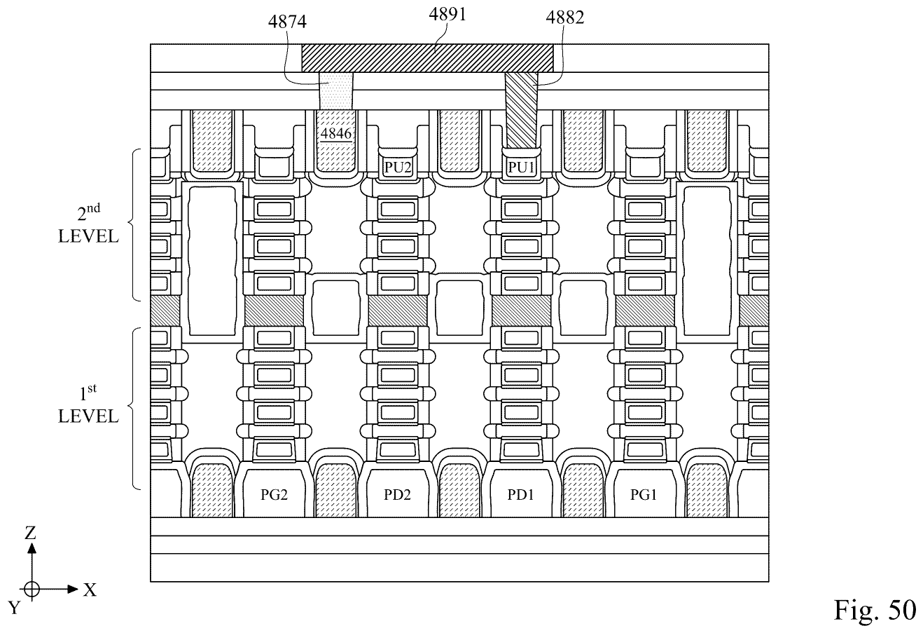

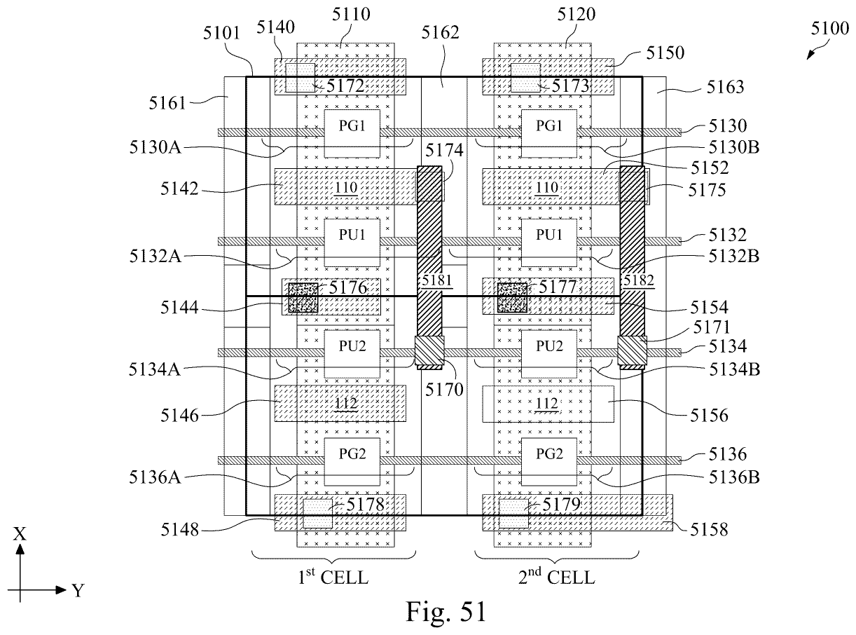

FIGS. 49 and 50 illustrate cross-sectional views of a portion of a semiconductor device including at least one memory cell 100 formed based on the layouts 4700 and 4800 (FIGS. 47-48), in accordance with some embodiments. For example, the cross-sectional views of FIGS. 49 and 50 are cut along the internal connect structure 4781 (FIG. 47) and the internal connect structure 4891 (FIG. 48), respectively. The cross-sectional views of FIGS. 49-50 are each substantially similar to the cross-sectional views shown in FIGS. 10 and 14, and thus, the following description will be focused on the difference.

As shown in FIGS. 49-50, the transistors PG1, PD1, PD2, and PG2 of the first memory cell 100 are formed at the first level, and the transistors PU1 and PU2 of the first memory cell 100 are formed at the second level. Each of the transistors PG1, PD1, PD2, PG2, PU1, and PU2 includes a number of nanostructures (collectively serving as its channel), a gate structure wrapping around each of the nanostructures, and a pair of epitaxial structures coupled to ends of each of the nanostructures, as described above. Further, the epitaxial structures of the transistors PG1, PD1, PD2, and PG2 have the p-type conductivity, and the epitaxial structures of the transistors PU1 and PU2 have the n-type conductivity.

In FIG. 49, the internal contact structure 4781 may be formed as a BM0 track extending along the X-direction, so as to connect the BVD 4774 (coupled to the MD 4742) to the BVG 4770, which operatively couples the common source/drain terminals of the transistors PD1 and PG1 to the gate terminal of the transistor PD2. As mentioned above, the gate terminal of the transistor PD2 and the gate terminal of the transistor PU2 are formed as the lower portion and the upper portion of an active gate structure, and thus, it should be understood that the gate terminal of the transistor PD2 and the gate terminal of the transistor PU2 are connected to each other. In FIG. 50, the internal contact structure 4891 may be formed as an M0 track extending along the X-direction, so as to connect the VD 4874 (coupled to the MD 4846) to the VG 4882, which operatively couples one of the source/drain terminals of the transistors PU2 to the gate terminal of the transistor PU1. As mentioned above, the gate terminal of the transistor PD1 and the gate terminal of the transistor PU1 are formed as the lower portion and the upper portion of an active gate structure, and thus, it should be understood that the gate terminal of the transistor PD1 and the gate terminal of the transistor PUI are connected to each other.

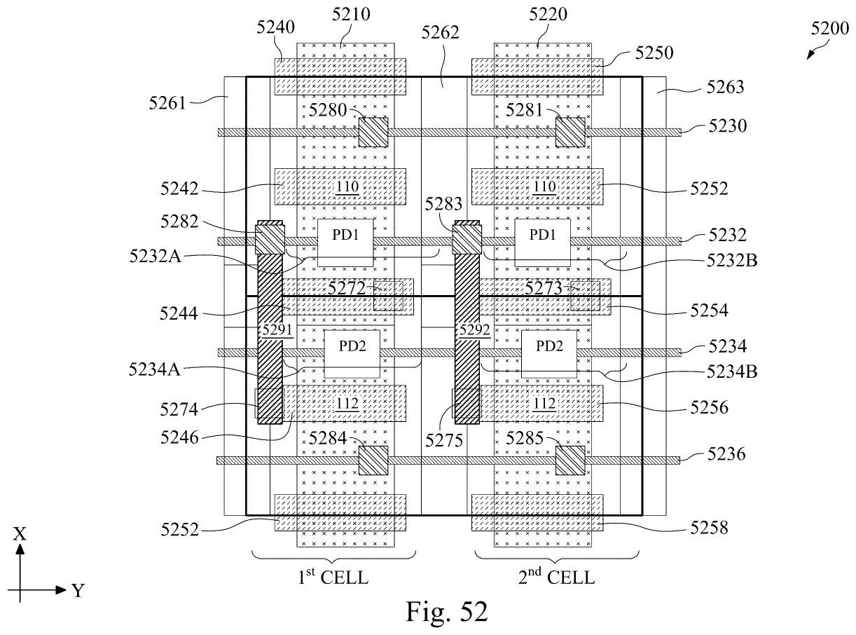

FIG. 51 and FIG. 52 respectively illustrate layouts 5100 and 5200 that can be collectively utilized to form a pair of the memory cells 1500 (FIG. 15) configured in a CFET structure. As depicted, each of the layouts 5100 to 5200 includes a cell boundary 5101 defining a physical area of the pair of memory cells 1500. The CFET structure can include a number of first transistors disposed at a first level on the frontside of a substate, and a number of second transistors despised at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 5100 to 5200 can include a number of patterns configured for forming respective structures, and thus, such patterns of the disclosed layout are herein referred to as the structures to be formed, respectively, in the following discussion. For example, the layout 5100 is configured to form structures of the first transistors at the first level on the frontside; and the layout 5200 is configured to form structures of the second transistors at the second level on the frontside. It should be understood that each of the layouts 5100 to 5200 has been simplified for illustrative purposes, and thus, can include any of various other patterns while remaining within the scope of the present disclosure.

Referring first to FIG. 51, the layout 5100 can include patterns for forming active regions 5110 and 5120 and gate structures 5130, 5132, 5134 and 5136, respectively. The active regions 5110 and 5120 may extend in the X-direction; and the gate structures 5130 to 5136 may extend in the Y-direction. Each of the active regions 5110 and 5120 may be formed as a fin structure or a stack structure extending along the X-direction, and each of the gate structures 5130 to 5136 may be formed to extend in the Y-direction to traverse the active regions 5110 and 5120. The layout 5100 can further include a number of cut patterns, e.g., 5162, 5162, and 5163, each of which can extend along the X-direction traversing the gate structures 5130 to 5136. The cut patterns 5161 to 5163 can each be configured to form a dielectric structure, thereby dividing the gate structures 5130-5136 into separate gate sections. For example, the cut pattern 5161-5163 can divide the gate structures 5130, 5132, 5134, and 5136 into gate sections 5130A and 5130B, gate sections 5132A and 5132B, gate sections 5134A and 5134B, and gate sections 5136A and 5136B, respectively, as indicated in FIG. 51.

Referring next to FIG. 52, the layout 5200 can include patterns for forming active regions 5210 and 5220 and gate structures 5230, 5232, 5234 and 5236, respectively. The active regions 5210 and 5220 may extend in the X-direction; and the gate structures 5230 to 5236 may extend in the Y-direction. Each of the active regions 5210 and 5220 may be formed as a fin structure or a stack structure extending along the X-direction, and each of the gate structures 5230 to 5236 may be formed to extend in the Y-direction to traverse the active regions 5210 and 5220. The layout 5200 can further include a number of cut patterns, e.g., 5261, 5262, and 5263, each of which can extend along the X-direction traversing the gate structures 5230 to 5236. The cut patterns 5261 to 5263 can each be configured to form a dielectric structure, thereby dividing the gate structures 5230-5236 into separate gate sections. For example, the cut pattern 5261-5263 can divide the gate structures 5230, 5232, 5234, and 5236 into gate sections 5230A and 5230B, gate sections 5232A and 5232B, gate sections 5234A and 5234B, and gate sections 5236A and 5236B, respectively, as indicated in FIG. 52.

In some embodiments, the active regions 5110 and 5210 are vertically aligned with each other, the active regions 5120 and 5220 are vertically aligned with each other, the gate structures 5130 and 5230 are vertically aligned with each other, the gate structures 5132 and 5232 are vertically aligned with each other, the gate structures 5134 and 5234 are vertically aligned with each other, the gate structures 5136 and 5236 are vertically aligned with each other, the cut patterns 5161 and 5261 are vertically aligned with each other, the cut patterns 5162 and 5262 are vertically aligned with each other, and the cut patterns 5163 and 5263 are vertically aligned with each other. Further, the active regions 5110 and 5210 may be physically formed as a single structure (sometimes referred to as “active region 5110/5210”), the active regions 5120 and 5220 may be physically formed as a single structure (sometimes referred to as “active region 5120/5220”), the gate structures 5130 and 5230 may be physically formed as a single structure (sometimes referred to as “gate structure 5130/5230”), the gate structures 5132 and 5232 may be physically formed as a single structure (sometimes referred to as “gate structure 5132/5232”), the gate structures 5134 and 5234 may be physically formed as a single structure (sometimes referred to as “gate structure 5134/5234”), and the gate structures 5136 and 5236 may be physically formed as a single structure (sometimes referred to as “gate structure 5136/5236”).

Based on the manufacturing processes described in FIGS. 25-46, the layouts 5100 and 5200 can be collectively utilized to form a number of first transistors at a first level on the frontside of a substrate and a number of second transistor at a second, upper level on the frontside, in which the first transistors are operatively formed based on a plural number of first nanosheets and a plural number of first epitaxial structures, and the second transistors are operatively formed based on a plural number of second nanosheets and a plural number of second epitaxial structures.

For example, the transistors PU1, PU2, PG1, and PG2 of a first memory cell 100 and the transistors PU1, PU2, PG1, and PG2 of a second memory cell 1500 can be formed at the first level based on the layout 5100 (as indicated in FIG. 51), and the transistors PD1 and PD2 of the first memory cell 100 and the transistors PD1 and PD2 of the second memory cell 1500 can be formed at the second level based on the layout 5200 (as indicated in FIG. 52). Further, in some embodiments, the transistors PU1, PU2, PG1, and PG2 of the first and second memory cells 1500 at the first level can be formed with the p-type conductivity, and the transistors PD1 and PD2 of the first and second memory cells 1500 at the second level can be formed with the n-type conductivity.

As a representative example, in FIG. 51, the transistor PU1 of the first memory cell 1500 (e.g., between the cut patterns 5161 and 5162) can include its channel, gate terminal, and source/drain terminals formed by a subset of the first nanosheets in the active region 5110, the gate section 5132A, and a subset of the first epitaxial structures formed from the active region 5110 and disposed on opposite sides of the gate structure 5132, respectively. The transistor PG1 of the first memory cell 1500 can include its channel, gate terminal, and source/drain terminals formed by another subset of the first nanosheets in the active region 5110, the gate section 5130A, and another subset of the first epitaxial structures formed from the active region 5110 and disposed on opposite sides of the gate structure 5130, respectively. The transistor PU2 of the first memory cell 1500 can include its channel, gate terminal, and source/drain terminals formed by yet another subset of the first nanosheets in the active region 5110, the gate section 5134A, and yet another subset of the first epitaxial structures formed from the active region 5110 and disposed on opposite sides of the gate structure 5134, respectively. The transistor PG2 of the first memory cell 1500 can include its channel, gate terminal, and source/drain terminals formed by yet another subset of the first nanosheets in the active region 5110, the gate section 5136A, and yet another subset of the first epitaxial structures formed from the active region 5110 and disposed on opposite sides of the gate structure 5136, respectively.

As another representative example, in FIG. 52, the transistor PD1 of the first memory cell 1500 (e.g., between the cut patterns 5261 and 5262) can include its channel, gate terminal, and source/drain terminals formed by a subset of the second nanosheets in the active region 5210, the gate section 5232A, and a subset of the second epitaxial structures formed from the active region 5210 and disposed on opposite sides of the gate structure 5232, respectively. The transistor PD2 of the first memory cell 1500 can include its channel, gate terminal, and source/drain terminals formed by another subset of the second nanosheets in the active region 5210, the gate section 5234A, and another subset of the second epitaxial structures formed from the active region 5210 and disposed on opposite sides of the gate structure 5234, respectively.

Referring again to FIG. 51, the layout 5100 can further include patterns for forming source/drain contact structures (MDs) 5140, 5142, 5144, 5146, 5148, 5150, 5152, 5154, 5156, and 5158, respectively. Similarly in FIG. 52, the layout 5200 can further include patterns for forming source/drain contact structures (MDs) 5240, 5242, 5244, 5246, 5248, 5250, 5252, 5254, 5256, and 5258, respectively. Each of these MDs is configured to electrically connect to the source/drain terminal of a corresponding transistor.

For example, in FIG. 51, the MD 5140 is connected to a first source/drain terminal of the transistor PG1 of the first memory cell 1500; the MD 5142 is connected to a second source/drain terminal of the transistor PG1 and a first source/drain terminal of the transistor PU1 of the first memory cell 1500; the MD 5144 is connected to a second source/drain terminal of the transistor PU1 and a first source/drain terminal of the transistor PU2 of the first memory cell 1500; the MD 5146 is connected to a second source/drain terminal of the transistor PU2 and a first source/drain terminal the transistor PG2 of the first memory cell 1500; and the MD 5148 is connected to a second source/drain terminal of the transistor PG2 of the first memory cell 1500. In FIG. 52, the MD 5242 is connected to a first source/drain terminal of the transistor PD1 of the first memory cell 1500; the MD 5244 is connected to a second source/drain terminal of the transistor PD1 and a first source/drain terminal of the transistor PD2 of the first memory cell 1500; and the MD 5246 is connected to a second source/drain terminal of the transistor PD2 of the first memory cell 1500.

In some embodiments, for the first memory cell 1500, the MD 5142 (FIG. 51) and MD 5242 (FIG. 52) may be connected to each other through a first via structure (not shown), and the MD 5146 (FIG. 51) and MD 5246 (FIG. 52) may be connected to teach other through a second via structure (not shown). Stated another way, the first via structure can vertically extend from the first level to the second level to connect the MD 5142 to the MD 5242, and the second via structure can vertically extend from the first level to the second level to connect the MD 5146 to the MD 5246. As such, the (internal) node 1510 of the first memory cell 1500, connecting the respective source/drain terminals of the transistors PU1, PD1, and PG1 to one another, can be operatively formed based on the MD 5142, the MD 5242, and the first via structure vertically interposed therebetween, and the (internal) node 1512 of the first memory cell 1500, connecting the respective source/drain terminals of the transistors PU2, PD2, and PG2 to one another, can be operatively formed based on the MD 5146, the MD 5246, and the second via structure vertically interposed therebetween. The connections among the MDs for the second memory cell 1500 are the same, so that the description is not repeated.

Referring again to FIG. 51, the layout 5100 can further include patterns for forming a number of first via structures (BVDs) 5172, 5173, 5174, 5175, 5176, 5177, 5178, and 5179, respectively. In some embodiments, each of the BVDs 5172 to 5179 can be formed below an MD included in the layout 5100. Particularly, the BVDs 5172 to 5179 can each downwardly extend from the corresponding MD to a backside of the substrate. For example, the BVD 5172 can be coupled to and downwardly extend from the MD 5142; the BVD 5173 can be coupled to and downwardly extend from the MD 5150; the BVD 5174 can be coupled to and downwardly extend from the MD 5142; the BVD 5175 can be coupled to and downwardly extend from the MD 5152; the BVD 5176 can be coupled to and downwardly extend from the MD 5144; the BVD 5177 can be coupled to and downwardly extend from the MD 5154; the BVD 5178 can be coupled to and downwardly extend from the MD 5148; and the BVD 5179 can be coupled to and downwardly extend from the MD 5158.

Further, in some embodiments, the BVD 5172 can electrically connect the MD 5140 to a first interconnect structure formed on the backside (e.g., a first BM0 track) and configured as the BL of the first memory cell 1500; the BVD 5176 can electrically connect the MD 5144 to a second interconnect structure formed on the backside (e.g., a second BM0 track) and configured to carry the ground voltage VSS for the first memory cell 1500; the BVD 5178 can electrically connect the MD 5148 to a third interconnect structure formed on the backside (e.g., a third BM0 track) and configured as the BLB of the first memory cell 1500; the BVD 5173 can electrically connect the MD 5150 to a fourth interconnect structure formed on the backside (e.g., a fourth BM0 track) and configured as the BL of the second memory cell 1500; the BVD 5177 can electrically connect the MD 5154 to a fifth interconnect structure formed on the backside (e.g., a fifth BM0 track) and configured to carry the ground voltage VSS for the second memory cell 1500; and the BVD 5179 can electrically connect the MD 5158 to a sixth interconnect structure formed on the backside (e.g., a sixth BM0 track) and configured as the BLB of the second memory cell 1500.

The layout 5100 can further include patterns for forming a number of second via structures (BVGs) 5170 and 5171, respectively. In some embodiments, each of the BVGs 5170 and 5171 can be formed below a gate structure in the layout 5100. Particularly, the BVGs 5170 and 5171 can each downwardly extend from the corresponding gate structure. For example, the BVG 5170 can be coupled to and downwardly extend from the gate structure 5134 (or the gate section 5134A); and the BVG 5171 can be coupled to and downwardly extend from the gate structure 5134 (or the gate section 5134B).

The layout 5100 can further include patterns form forming internal contact structures 5181 and 5182, respectively. The internal contact structures 5181 and 5182 can extend along the X-direction, and be formed on the backside of the substrate (e.g., as BM0 tracks). In some embodiments, the internal contact structures 5181 and 5182 can each be configured to electrically connect an internal node of the memory cell 1500 to the gate terminal(s) of one or more transistors. For example, in the first memory cell 1500, the internal contact structure 5181 can electrically connect the MD 5142 (the common source/drain terminals of the transistors PG1 and PU1, or the internal node 1510) to the gate section 5134A (the gate terminal of the transistor PU2) through the BVD 5174 and the VG 5170; and, in the second memory cell 1500, the internal contact structure 5182 can electrically connect the MD 5152 (the common source/drain terminals of the transistors PG1 and PU1, the internal node 1510) to the gate section 5134B (the gate terminal of the transistor PU2) through the BVD 5175 and the VG 5171.

Referring again to FIG. 52, the layout 5200 can further include patterns for forming a number of first via structures (VDs) 5272, 5273, 5274, and 5275, respectively. In some embodiments, each of the VDs 5272 to 5275 can be formed above an MD included in the layout 5200. Particularly, the VDs 5272 to 5275 can each upwardly extend from the corresponding MD. For example, the VD 5272 can be coupled to and upwardly extend from the MD 5244; the VD 5273 can be coupled to and upwardly extend from the MD 5254; the VD 5274 can be coupled to and upwardly extend from the MD 5246; and the VD 5275 can be coupled to and upwardly extend from the MD 5256. In some embodiments, the VD 5272 allows the MD 5244 (the common source/drain terminals of the transistors PD1 and PD2 of the first memory cell 1500) to one or more interconnect structures formed in an upper level (e.g., a first interconnect structure formed at a third, upper level on the frontside and configured to carry the ground voltage VSS); and the VD 5273 allows the MD 5254 (the common source/drain terminals of the transistors PD1 and PD2 of the second memory cell 1500) to one or more interconnect structures formed in the upper level (e.g., a second interconnect structure formed at the third, upper level on the frontside and configured to carry the ground voltage VSS). The layout 5200 can further include patterns for forming a number of second via structures (VGs) 5280, 5281, 5282, 5283, 5284, and 5285, respectively. In some embodiments, each of the VGs 5280 and 5285 can be formed above a gate structure in the layout 5200. Particularly, the VGs 5280 and 5285 can upwardly extend from the corresponding gate structure.

The layout 5200 can further include patterns for forming internal contact structures 5291 and 5292, respectively. The internal contact structures 5291 and 5292 can extend along the X-direction, and be formed on third, upper level on the frontside (e.g., as M0 tracks). In some embodiments, the internal contact structures 5291 and 5292 can each be configured to electrically connect an internal node of the memory cell 1500 to the gate terminal(s) of one or more transistors. For example, in the first memory cell 1500, the internal contact structure 5291 can electrically connect the MD 5246 (the common source/drain terminals of the transistors PD2 and PU2, or the internal node 1512) to the gate section 5232A (the gate terminal of the transistor PD1) through the VD 5274 and the VG 5282; and, in the second memory cell 1500, the internal contact structure 5292 can electrically connect the MD 5256 (the common source/drain terminals of the transistors PD2 and PU2, or the internal node 1512) to the gate section 5232B (the gate terminal of the transistor PD1) through the VD 5275 and the VG 5283.

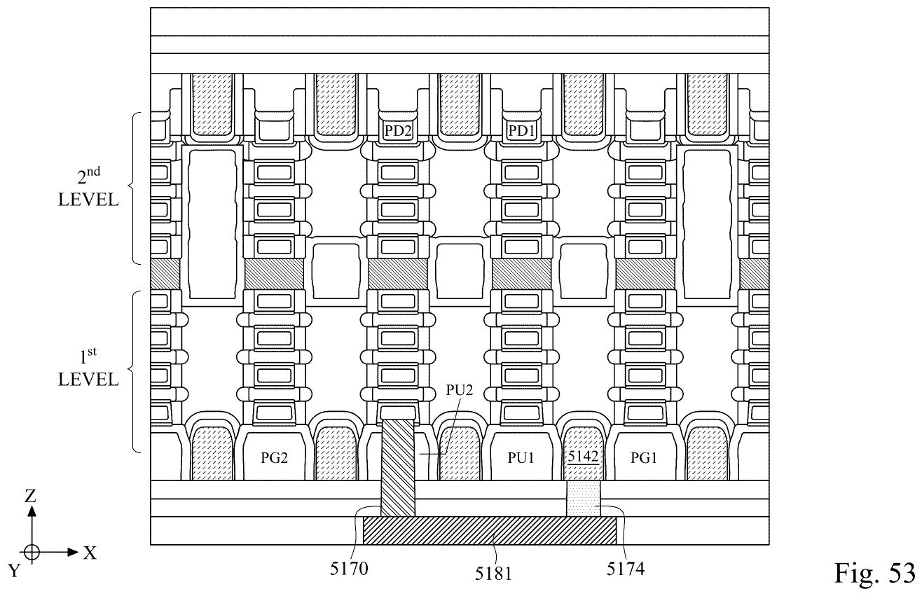

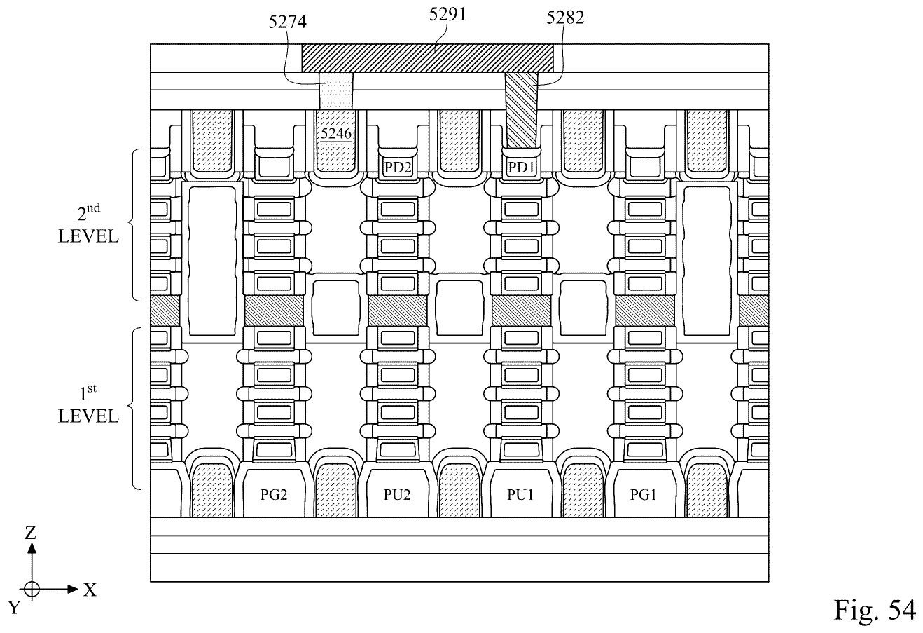

FIGS. 53 and 54 illustrate cross-sectional views of a portion of a semiconductor device including at least one memory cell 1500 formed based on the layouts 5100 and 5200 (FIGS. 51-52), in accordance with some embodiments. For example, the cross-sectional views of FIGS. 53 and 54 are cut along the internal connect structure 5181 (FIG. 51) and the internal connect structure 5291 (FIG. 52), respectively. The cross-sectional views of FIGS. 51-52 are each substantially similar to the cross-sectional views shown in FIGS. 10 and 14, and thus, the following description will be focused on the difference.

As shown in FIGS. 53-54, the transistors PG1, PU1, PU2, and PG2 of the first memory cell 1500 are formed at the first level, and the transistors PD1 and PD2 of the first memory cell 1500 are formed at the second level. Each of the transistors PG1, PD1, PD2, PG2, PU1, and PU2 includes a number of nanostructures (collectively serving as its channel), a gate structure wrapping around each of the nanostructures, and a pair of epitaxial structures coupled to ends of each of the nanostructures, as described above. Further, the epitaxial structures of the transistors PG1, PU1, PU2, and PG2 have the p-type conductivity, and the epitaxial structures of the transistors PD1 and PD2 have the n-type conductivity.

In FIG. 53, the internal contact structure 5181 may be formed as a BM0 track extending along the X-direction, so as to connect the BVD 5174 (coupled to the MD 5142) to the BVG 5170, which operatively couples the common source/drain terminals of the transistors PU1 and PG1 to the gate terminal of the transistor PU2. As mentioned above, the gate terminal of the transistor PU2 and the gate terminal of the transistor PD2 are formed as the lower portion and the upper portion of an active gate structure, and thus, it should be understood that the gate terminal of the transistor PD2 and the gate terminal of the transistor PU2 are connected to each other. In FIG. 54, the internal contact structure 5291 may be formed as an M0 track extending along the X-direction, so as to connect the VD 5274 (coupled to the MD 5246) to the VG 5282, which operatively couples one of the source/drain terminals of the transistors PD2 to the gate terminal of the transistor PD1. As mentioned above, the gate terminal of the transistor PU1 and the gate terminal of the transistor PD1 are formed as the lower portion and the upper portion of an active gate structure, and thus, it should be understood that the gate terminal of the transistor PD1 and the gate terminal of the transistor PU1 are connected to each other.

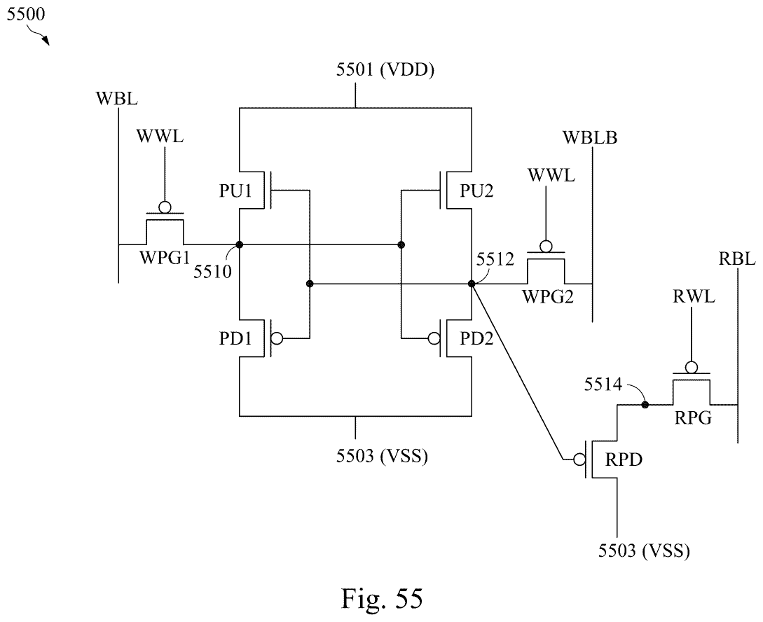

FIG. 55 illustrates an example circuit diagram of a memory cell 5500, in accordance with some embodiments. As shown, the memory cell 5500 includes eight transistors that operatively form an 8 T SRAM cell. In various embodiments, the eight transistors can be physically formed with the CFET structure, as discussed below. The memory cell 5500 includes eight transistors: a first pull-up transistor PU1, a second pull-up transistor PU2, a first pull-down transistor PD1, a second pull-down transistor PD2, a first write pass-gate transistor WPG1, a second write pass-gate transistor WPG2, a first read transistor RPD, and a second read transistor RPG.

The transistors PU1 and PD1 are formed as a first inverter and the transistors PU2 and PD2 are formed as a second inverter, wherein the first and second inverters are cross coupled to each other. Specifically, the first and second inverters are each coupled between first voltage reference 5501 and second voltage reference 5503. In some embodiments, the first voltage reference 5501 is a supply voltage applied to the memory cell 5500, sometimes referred to as “VDD,” and the second voltage reference 5503 is a ground voltage, sometimes referred to as “VSS.” The first inverter (formed by the transistors PU1 and PD1) is coupled to the transistor WPG1, and the second inverter (formed by the transistors PU2 and PD2) is coupled to the transistor WPG2. In addition to being coupled to the first and second inverters, the transistors WPG1 and WPG2 are each coupled to a write word line (WWL) and are coupled to a write bit line (WBL) and a write bit line bar (WBLB), respectively.

The transistors WPG1 and WPG2 each have a gate terminal coupled to the WWL. The gate terminals of the transistors WPG1 and WPG2 are configured to receive a pulse signal, through the WWL, to allow or block an access (e.g., a write operation) of the memory cell 5500 accordingly. The transistors PD1 and PUI are coupled between VDD and VSS, and coupled to each other at node 5510. For example, the transistor PU1 has a first source/drain terminal connected to VDD and the transistor PD1 has a first source/drain terminal connected to VSS, with the transistors PU1 and PD1 having their second source/drain terminals connected to each other at node 5510. The transistor WPG1 has a first source/drain terminal connected to the WBL and a second source/drain terminal connected to node 5510, which is further coupled to gate terminals of the transistors PU2 and PD2. Similarly, the transistors PD2 and PU2 are coupled between VDD and VSS, and coupled to each other at node 5512. For example, the transistor PU2 has a first source/drain terminal connected to VDD and the transistor PD2 has a first source/drain terminal connected to VSS, with the transistors PU2 and PD2 having their second source/drain terminals connected to each other at node 5512. The transistor PG2 has a first source/drain terminal connected to the WBLB and a second source/drain terminal connected to node 5512, which is further coupled to gate terminals of the transistors PU1 and PD1. Further, the transistor RPD has a gate terminal connected to node 5512, a first source/drain terminal connected to VSS, and a second source/drain terminal connected to a first source/drain terminal of the transistor RPG at node 5514. The transistor RPG has a gate terminal connected to a read word line (RWL) and a second source/drain terminal connected to a read bit line (RBL).

In some embodiments, the transistors PU1 and PU2 each include an n-type metal-oxide-semiconductor (NMOS) transistor, and the transistors PD1, PD2, WPG1, WPG2, RPD, and RPG each include a p-type metal-oxide-semiconductor (PMOS) transistor. Although the illustrated embodiment of FIG. 55 shows that the transistors of the memory cell 5500 are either NMOS or PMOS transistors, any of a variety of transistors or devices that are suitable for use in a memory device may be implemented as at least one of the transistors of the memory cell 5500 such as, for example, a bipolar junction transistor (BJT), a high-electron-mobility transistor (HEMT), etc. Further, the p-type transistors, PD1, PD2, WPG1, WPG2, RPD, and RPG, are each formed as a GAA FET in a first level disposed on the frontside of a substate, and the n-type transistors, PU1 and PU2, are each formed as a GAA FET in a second level over the first level.

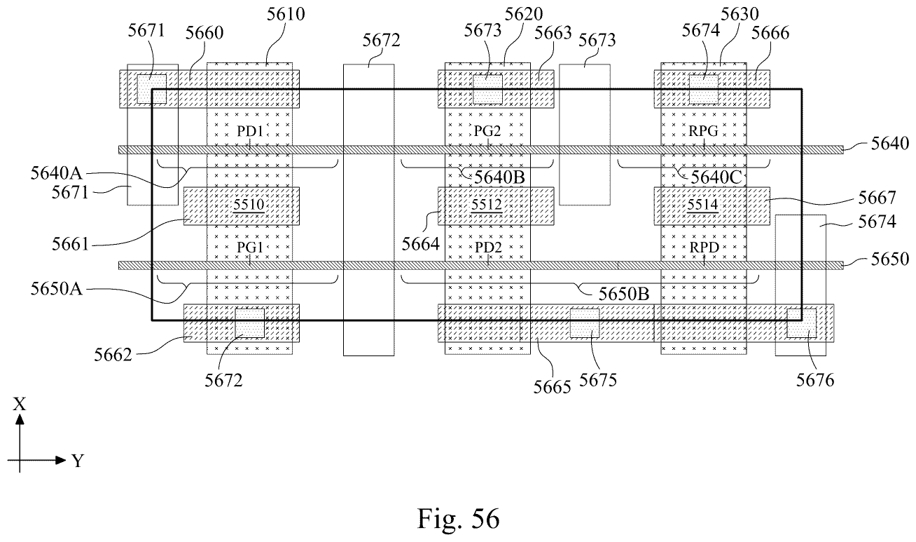

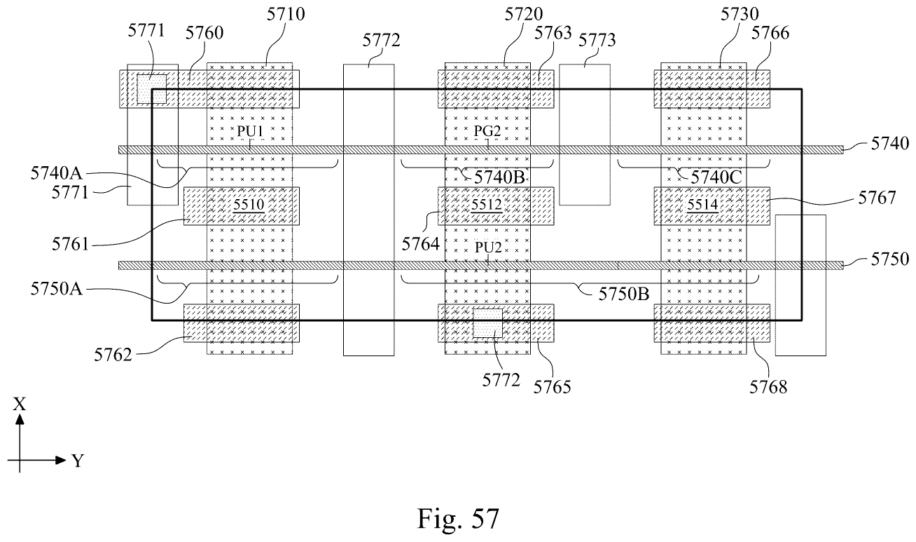

FIG. 56 and FIG. 57 respectively illustrate layouts 5600 and 5700 that can be collectively utilized to form a pair of the memory cells 5500 (FIG. 55) configured in a CFET structure. As depicted, each of the layouts 5600 to 5700 includes a cell boundary 5601 defining a physical area of the memory cell 5500. The CFET structure can include a number of first transistors disposed at a first level on the frontside of a substate, and a number of second transistors despised at a second, upper level on the frontside of the substrate. In some embodiments, each of these first and second transistors is configured as a GAA FET, while the first transistors and the second transistors have opposite conductive types. In some other embodiments, each of the first and second transistors can be formed as other type of transistor structures while remaining within the scope of the present disclosure.

Generally, each of the layouts 5600 to 5700 can include a number of patterns configured for forming respective structures, and thus, such patterns of the disclosed layout are herein referred to as the structures to be formed, respectively, in the following discussion. For example, the layout 5600 is configured to form structures of the first transistors at the first level on the frontside; and the layout 5700 is configured to form structures of the second transistors at the second level on the frontside. It should be understood that each of the layouts 5600 to 5700 has been simplified for illustrative purposes, and thus, can include any of various other patterns while remaining within the scope of the present disclosure.

Referring first to FIG. 56, the layout 5600 can include patterns for forming active regions 5610, 5620, and 5630, and gate structures 5640 and 5650, respectively. The active regions 5610 to 5630 may extend in the X-direction; and the gate structures 5640 and 5650 may extend in the Y-direction. Each of the active regions 5610 to 5630 may be formed as a fin structure or a stack structure extending along the X-direction, and each of the gate structures 5640 and 5650 may be formed to extend in the Y-direction to traverse the active regions 5610 to 5630. The layout 5600 can further include a number of cut patterns, e.g., 5671, 5672, 5673, and 5674, each of which can extend along the X-direction traversing one or more of the gate structures 5640 and 5650. The cut patterns 5671 to 5674 can each be configured to form a dielectric structure, thereby dividing the gate structures 5640-5650 into separate gate sections. For example, the cut patterns 5671, 5672, and 5673 can divide the gate structures 5640 into gate sections 5640A, 5640B, and 5640C; and the cut patterns 5671, 5672, and 5674 can divide the gate structure 5650 into gate sections 5650A and 5650B, as indicated in FIG. 56.

Referring next to FIG. 57, the layout 5700 can include patterns for forming active regions 5710, 5720, and 5730, and gate structures 5740 and 5750, respectively. The active regions 5710 to 5730 may extend in the X-direction; and the gate structures 5740 and 5750 may extend in the Y-direction. Each of the active regions 5710 to 5730 may be formed as a fin structure or a stack structure extending along the X-direction, and each of the gate structures 5740 and 5750 may be formed to extend in the Y-direction to traverse the active regions 5710 to 5730. The layout 5700 can further include a number of cut patterns, e.g., 5771, 5772, 5773, and 5774, each of which can extend along the X-direction traversing one or more of the gate structures 5740 and 5750. The cut patterns 5771 to 5774 can each be configured to form a dielectric structure, thereby dividing the gate structures 5740-5750 into separate gate sections. For example, the cut patterns 5771, 5772, and 5773 can divide the gate structures 5740 into gate sections 5740A, 5740B, and 5740C; and the cut patterns 5771, 5772, and 5774 can divide the gate structure 5750 into gate sections 5750A and 5750B, as indicated in FIG. 57.

In some embodiments, the active regions 5610 and 5710 are vertically aligned with each other, the active regions 5620 and 5720 are vertically aligned with each other, the active regions 5630 and 5730 are vertically aligned with each other, the gate structures 5640 and 5740 are vertically aligned with each other, the gate structures 5650 and 5750 are vertically aligned with each other, the cut patterns 5671 and 5771 are vertically aligned with each other, the cut patterns 5672 and 5772 are vertically aligned with each other, the cut patterns 5673 and 5773 are vertically aligned with each other, and the cut patterns 5674 and 5774 are vertically aligned with each other. Further, the active regions 5610 and 5710 may be physically formed as a single structure (sometimes referred to as “active region 5610/5710”), the active regions 5620 and 5720 may be physically formed as a single structure (sometimes referred to as “active region 5620/5720”), the active regions 5630 and 5730 may be physically formed as a single structure (sometimes referred to as “active region 5630/5730”), the gate structures 5640 and 5740 may be physically formed as a single structure (sometimes referred to as “gate structure 5640/5740”), and the gate structures 5650 and 5750 may be physically formed as a single structure (sometimes referred to as “gate structure 5650/5750”).

Based on the manufacturing processes described in FIGS. 25-46, the layouts 5600 and 5700 can be collectively utilized to form a number of first transistors at a first level on the frontside of a substrate and a number of second transistor at a second, upper level on the frontside, in which the first transistors are operatively formed based on a plural number of first nanosheets and a plural number of first epitaxial structures, and the second transistors are operatively formed based on a plural number of second nanosheets and a plural number of second epitaxial structures.

For example, the transistors PD1, PD2, PG1, PG2, RPG, and RPD of the memory cell 5500 can be formed at the first level based on the layout 5600 (as indicated in FIG. 56), and the transistors PU1 and PU2 of the memory cell 5500 can be formed at the second level based on the layout 5700 (as indicated in FIG. 57). Further, in some embodiments, the transistors PD1, PD2, PG1, PG2, RPG, and RPD of the memory cell 5500 at the first level can be formed with the p-type conductivity, and the transistors PU1 and PU2 of the memory cell 5500 at the second level can be formed with the n-type conductivity.

As a representative example, in FIG. 56, the transistor PD1 of the memory cell 5500 can include its channel, gate terminal, and source/drain terminals formed by a subset of the first nanosheets in the active region 5610, the gate section 5640A, and a subset of the first epitaxial structures formed from the active region 5610 and disposed on opposite sides of the gate structure 5640, respectively. The transistor PG1 of the memory cell 5500 can include its channel, gate terminal, and source/drain terminals formed by another subset of the first nanosheets in the active region 5610, the gate section 5650A, and another subset of the first epitaxial structures formed from the active region 5610 and disposed on opposite sides of the gate structure 5650, respectively. The transistor PG2 of the memory cell 5500 can include its channel, gate terminal, and source/drain terminals formed by yet another subset of the first nanosheets in the active region 5620, the gate section 5640B, and yet another subset of the first epitaxial structures formed from the active region 5620 and disposed on opposite sides of the gate structure 5640, respectively. The transistor PD2 of the memory cell 5500 can include its channel, gate terminal, and source/drain terminals formed by yet another subset of the first nanosheets in the active region 5620, the gate section 5650B, and yet another subset of the first epitaxial structures formed from the active region 5620 and disposed on opposite sides of the gate structure 5650, respectively. The transistor RPG of the memory cell 5500 can include its channel, gate terminal, and source/drain terminals formed by yet another subset of the first nanosheets in the active region 5630, the gate section 5640C, and yet another subset of the first epitaxial structures formed from the active region 5630 and disposed on opposite sides of the gate structure 5640, respectively. The transistor RPD of the memory cell 5500 can include its channel, gate terminal, and source/drain terminals formed by yet another subset of the first nanosheets in the active region 5630, the gate section 5650B, and yet another subset of the first epitaxial structures formed from the active region 5630 and disposed on opposite sides of the gate structure 5650, respectively.

As another representative example, in FIG. 57, the transistor PU1 of the memory cell 5500 can include its channel, gate terminal, and source/drain terminals formed by a subset of the second nanosheets in the active region 5710, the gate section 5740A, and a subset of the second epitaxial structures formed from the active region 5710 and disposed on opposite sides of the gate structure 5740, respectively. The transistor PU2 of the memory cell 5500 can include its channel, gate terminal, and source/drain terminals formed by another subset of the second nanosheets in the active region 5720, the gate section 5750B, and another subset of the second epitaxial structures formed from the active region 5720 and disposed on opposite sides of the gate structure 5750, respectively.

Referring again to FIG. 56, the layout 5600 can further include patterns for forming source/drain contact structures (MDs) 5660, 5661, 5662, 5663, 5664, 5665, 5666, and 5667, respectively. Similarly in FIG. 57, the layout 5700 can further include patterns for forming source/drain contact structures (MDs) 5760, 5761, 5762, 5763, 5764, 5765, 5766, 5767, and 5768, respectively. Each of these MDs is configured to electrically connect to the source/drain terminal of a corresponding transistor.

For example, in FIG. 56, the MD 5660 is connected to a first source/drain terminal of the transistor PD1 of the memory cell 5500; the MD 5661 is connected to a second source/drain terminal of the transistor PD1 and a first source/drain terminal of the transistor PG1 of the memory cell 5500; the MD 5663 is connected to a first source/drain terminal of the transistor PG2; the MD 5664 is connected to a second source/drain terminal of the transistor PG2 and a first source/drain terminal of the transistor PD2 of the memory cell 5500; the MD 5665 is connected to a second source/drain terminal of the transistor PD2 and a first source/drain terminal of the transistor RPD of the memory cell 5500; the MD 5514 is connected to a second source/drain terminal of the transistor RPD and a first source/drain terminal of the transistor RPG of the memory cell 5500; and the MD 5566 is connected to a second source/drain terminal of the transistor RPG of the memory cell 5500. In FIG. 57, the MD 5760 is connected to a first source/drain terminal of the transistor PU1 of the memory cell 5500; the MD 5761 is connected to a second source/drain terminal of the transistor PU1 of the memory cell 5500; the MD 5764 is connected to a first source/drain terminal of the transistor PU2 of the memory cell 5500; and the MD 5765 is connected to a second source/drain terminal of the transistor PU2 of the memory cell 5500.

In some embodiments, the MDs 5661, 5664, and 5667 of FIG. 56 may be operatively configured as nodes 5510, 5512, and 5514 of the memory cell 5500, respectively; and the MDs 5761, 5764, and 5767 of FIG. 57 may be operatively configured as nodes 5510, 5512, and 5514 of the memory cell 5500, respectively. For example, the MDs 5661 and 5761 may be connected to each other with a first via structure that extends from the first level to the second level; the MDs 5664 and 5764 may be connected to each other with a second via structure that extends from the first level to the second level; and MDs 5668 and 5768 may be connected to each other with a third via structure that extends from the first level to the second level.

Referring again to FIG. 56, the layout 5600 can further include patterns for forming a number of via structures (BVDs) 5671, 5672, 5673, 5674, 5675, and 5676, respectively. In some embodiments, each of the BVDs 5671 to 5676 can be formed below an MD included in the layout 5600. Particularly, the BVDs 5671 to 5676 can each downwardly extend from the corresponding MD to a backside of the substrate. For example, the BVD 5671 can be coupled to and downwardly extend from the MD 5660; the BVD 5672 can be coupled to and downwardly extend from the MD 5662; the BVD 5673 can be coupled to and downwardly extend from the MD 5663; the BVD 5674 can be coupled to and downwardly extend from the MD 5666; and the BVDs 5675 and 5676 can each be coupled to and downwardly extend from the MD 5665.

Further, in some embodiments, the BVD 5671 can electrically connect the MD 5660 to a first interconnect structure formed on the backside (e.g., a first BM0 track) and configured carry the ground voltage VSS for the memory cell 5500; the BVD 5672 can electrically connect the MD 5662 to a second interconnect structure formed on the backside (e.g., a second BM0 track) and configured as the BL of the memory cell 5500; the BVD 5673 can electrically connect the MD 5663 to a third interconnect structure formed on the backside (e.g., a third BM0 track) and configured as the BLB of the memory cell 5500; the BVD 5674 can electrically connect the MD 5666 to a fourth interconnect structure formed on the backside (e.g., a fourth BM0 track) and configured as the RBL of the memory cell 5500; and the BVDs 5675 and 5676 can electrically connect the MD 5665 to a fifth interconnect structure formed on the backside (e.g., a fifth BM) track) and configured to carry the ground voltage VSS for the memory cell 5500X.

Referring again to FIG. 57, the layout 5700 can further include patterns for forming a number of via structures (VDs) 5771 and 5772, respectively. In some embodiments, each of the VDs 5771 and 5772 can be formed above an MD included in the layout 5700. Particularly, the VDs 5771 to 5772 can each upwardly extend from the corresponding MD. For example, the VD 5771 can be coupled to and upwardly extend from the MD 5760; and the VD 5772 can be coupled to and upwardly extend from the MD 5765. In some embodiments, the VD 5771 allows the MD 5760 (one of the source/drain terminals of the transistor PU1) to one or more interconnect structures formed in an upper level (e.g., a first interconnect structure formed at a third, upper level on the frontside and configured to carry the supply voltage VDD); and the VD 5772 allows the MD 5765 (one of the source/drain terminals of the transistor PU2) to one or more interconnect structures formed in the upper level (e.g., a second interconnect structure formed at the third level on the frontside and configured to carry the supply voltage VDD).

In one aspect of the present disclosure, a device is disclosed. The device includes a substrate having a first side and a second side opposite to each other; a first transistor, a second transistor, a third transistor, and a fourth transistor formed on the first side of the substrate, the first to fourth transistors each formed with a p-type conductivity; a fifth transistor and a sixth transistor formed on the first side of the substrate and over the first to fourth transistors, the fifth to sixth transistors each formed with an n-type conductivity; a plurality of first interconnect structures formed on the first side of the substate and over the fifth to sixth transistors, each of the plurality of first interconnect structures coupled at least to the fifth and sixth transistors and configured to carry a supply voltage; and a plurality of second interconnect structures formed on the second side of the substate, each of the plurality of second interconnect structures coupled at least to the first and second transistors and configured to carry a ground voltage.

In another aspect of the present disclosure, a semiconductor device is disclosed. The semiconductor device includes a first active region formed on a first side of a substrate and extending along a first lateral direction; a second active region formed on the first side of the substrate and extending along the first lateral direction; a first gate structure formed on the first side of the substrate, extending in a second lateral direction, and traversing the first and second active regions; a second gate structure formed on the first side of the substrate, extending in the second lateral direction, and traversing the first and second active regions; a third active region formed on the first side of the substrate, extending in the first lateral direction, and vertically above and aligned with the first active region; a fourth active region formed on the first side of the substrate, extending in the first lateral direction, and vertically above and aligned with the second active region; a third gate structure formed on the first side of the substrate, extending in the second lateral direction, and vertically above and aligned with the third active region; and a fourth gate structure formed on the first side of the substrate, extending in the second lateral direction, and vertically above and aligned with the fourth active region. The first to second active regions and the first to second gate structures operatively form first, second, third, and fourth transistors of a memory cell that have a first conductivity, and the third to fourth active regions and the third to fourth gate structures operatively form fifth and sixth transistors of the memory cell that have a second conductivity.

In yet another aspect of the present disclosure, a method for forming memory devices is disclosed. The method includes forming, on a first side of a substrate, a first active region extending along a first lateral direction. The method includes forming, on the first side of the substrate, a second active region extending along the first lateral direction. The method includes forming, on the first side of the substrate, a first gate structure extending along a second lateral direction and traversing the first and second active regions. The method includes forming, on the first side of the substrate, a second gate structure extending along the second lateral direction and traversing the first and second active regions. The method includes forming, on the first side of the substrate and vertically above the first active region, a third active region extending in the first lateral direction. The method includes forming, on the first side of the substrate and vertically above the second active region, a fourth active region extending along the first lateral direction. The method includes forming, on the first side of the substrate and vertically above the first gate structure, a third gate structure extending along the second lateral direction. The method includes forming, on the first side of the substrate and vertically above the second gate structure, a fourth gate structure extending along the second lateral direction. The first to second active regions and the first to second gate structures operatively form first, second, third, and fourth transistors of a memory cell that have a first conductivity, and the third to fourth active regions and the third to fourth gate structures operatively form fifth and sixth transistors of the memory cell that have a second conductivity.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate having a first side and a second side opposite to each other;
a first transistor, a second transistor, a third transistor, and a fourth transistor formed on the first side of the substrate, the first to fourth transistors each formed with a p-type conductivity;
a fifth transistor and a sixth transistor formed on the first side of the substrate and over the first to fourth transistors, the fifth to sixth transistors each formed with an n-type conductivity;
a plurality of first interconnect structures formed on the first side of the substate and over the fifth to sixth transistors, each of the plurality of first interconnect structures coupled at least to the fifth and sixth transistors and configured to carry a supply voltage; and
a plurality of second interconnect structures formed on the second side of the substate, each of the plurality of second interconnect structures coupled at least to the first and second transistors and configured to carry a ground voltage.

2. The device of claim 1, wherein the first to sixth transistors operatively form a Static Random Access Memory (SRAM) cell.

3. The device of claim 1, further comprising:
a plurality of third interconnect structures formed on the second side of the substate, each of the plurality of third interconnect structures coupled at least to the third and fourth transistors and configured as a bit line.

4. The device of claim 1, further comprising:
a first contact structure formed on the first side of the substrate and over the fifth to sixth transistors, wherein the first contact structure is configured to couple one of source/drain terminals of the fifth transistor to a gate terminal of the sixth transistor; and
a second contact structure formed on the first side of the substrate and over the fifth to sixth transistors, wherein the second contact structure is configured to couple one of source/drain terminals of the sixth transistor to a gate terminal of the fifth transistor.

5. The device of claim 4, wherein each of the first and second contact structures has an L-shape.

6. The device of claim 4, wherein the first contact structure includes a first portion extending in a first lateral direction and a second portion extending in a second lateral direction, and wherein the first portion has one of its ends coupled to one of source/drain terminals of the fifth transistor and the second portion has one of its ends coupled to a gate terminal of the sixth transistor.

7. The device of claim 4, wherein the second contact structure includes a first portion extending in a first lateral direction and a second portion extending in a second lateral direction, and wherein the first portion has one of its ends coupled to one of source/drain terminals of the sixth transistor and the second portion has one of its ends coupled to a gate terminal of the fifth transistor.

8. The device of claim 1, wherein the first to fourth transistors are formed at least by a first active region extending in a first lateral direction, a second active region extending in the first lateral direction, a first gate structure extending in a second lateral direction and traversing the first and second active regions, and a second gate structure extending in the second lateral direction and traversing the first and second active regions.

9. The device of claim 8, wherein the fifth and sixth transistors are formed at least by a third active region extending in the first lateral direction, a fourth active region extending in the first lateral direction, a third gate structure extending in the second lateral direction and traversing the third and fourth active regions, and a fourth gate structure extending in the second lateral direction and traversing the third and fourth active regions.

10. The device of claim 9, wherein the first active region and the second active region are vertically aligned with the third active region and the fourth active region, respectively, and the first gate structure and the second gate structure and vertically aligned with the third gate structure and the fourth gate structure, respectively.

11. A semiconductor device, comprising:
a first active region formed on a first side of a substrate and extending along a first lateral direction;
a second active region formed on the first side of the substrate and extending along the first lateral direction;
a first gate structure formed on the first side of the substrate, extending in a second lateral direction, and traversing the first and second active regions;
a second gate structure formed on the first side of the substrate, extending in the second lateral direction, and traversing the first and second active regions;
a third active region formed on the first side of the substrate, extending in the first lateral direction, and vertically above and aligned with the first active region;
a fourth active region formed on the first side of the substrate, extending in the first lateral direction, and vertically above and aligned with the second active region;
a third gate structure formed on the first side of the substrate, extending in the second lateral direction, and vertically above and aligned with the third active region; and
a fourth gate structure formed on the first side of the substrate, extending in the second lateral direction, and vertically above and aligned with the fourth active region;
wherein the first to second active regions and the first to second gate structures operatively form first, second, third, and fourth transistors of a memory cell that have a first conductivity, and the third to fourth active regions and the third to fourth gate structures operatively form fifth and sixth transistors of the memory cell that have a second conductivity.

12. The semiconductor device of claim 11, wherein the first to sixth transistors operatively form a Static Random Access Memory (SRAM) cell.

13. The semiconductor device of claim 11,
wherein the first active region includes a plurality of first nanostructures, a plurality of second nanostructures, a first epitaxial structure, a second epitaxial structure, and a third epitaxial structure, the plurality of first nanostructures each wrapped by the first gate structure and having its ends connected to the first epitaxial structure and the second epitaxial structure, respectively, the plurality of second nanostructures each wrapped by the second gate structure and having its ends connected to the second epitaxial structure and the third epitaxial structure, respectively; and
wherein the second active region includes a plurality of third nanostructures, a plurality of fourth nanostructures, a fourth epitaxial structure, a fifth epitaxial structure, and a sixth epitaxial structure, the plurality of third nanostructures each wrapped by the first gate structure and having its ends connected to the fourth epitaxial structure and the fifth epitaxial structure, respectively, the plurality of fourth nanostructures each wrapped by the second gate structure and having its ends connected to the fifth epitaxial structure and the sixth epitaxial structure, respectively.

14. The semiconductor device of claim 13,
wherein the third active region includes a plurality of fifth nanostructures, a plurality of sixth nanostructures, a seventh epitaxial structure, an eighth epitaxial structure, and a first dielectric structure, the plurality of fifth nanostructures each wrapped by the third gate structure and having its ends connected to the seventh epitaxial structure and the eighth epitaxial structure, respectively, the plurality of sixth nanostructures each wrapped by the fourth gate structure and having its ends connected to the eighth epitaxial structure and the first dielectric structure, respectively; and
wherein the fourth active region includes a plurality of seventh nanostructures, a plurality of eighth nanostructures, a ninth epitaxial structure, a tenth epitaxial structure, and a second dielectric structure, the plurality of seventh nanostructures each wrapped by the third gate structure and having its ends connected to the second dielectric structure and the ninth epitaxial structure, respectively, the plurality of eighth nanostructures each wrapped by the fourth gate structure and having its ends connected to the ninth epitaxial structure and the tenth epitaxial structure, respectively.

15. The semiconductor device of claim 14, wherein the first dielectric structure is aligned with the tenth epitaxial structure along the second lateral direction, and the seventh epitaxial structure is aligned with the second dielectric structure along the second lateral direction.

16. The semiconductor device of claim 14, wherein the first to sixth epitaxial structures each have the first conductivity, and the seventh to tenth epitaxial structures each have the second conductivity.

17. The semiconductor device of claim 11, further comprising:
a plurality of first interconnect structures formed on the first side of the substate and over the fifth to sixth transistors, each of the plurality of first interconnect structures coupled at least to the fifth and sixth transistors and configured to carry a supply voltage; and
a plurality of second interconnect structures formed on a second side of the substate, each of the plurality of second interconnect structures coupled at least to the first and second transistors and configured to carry a ground voltage.

18. The semiconductor device of claim 17, further comprising:
a plurality of third interconnect structures formed on the second side of the substate, each of the plurality of third interconnect structures coupled at least to the third and fourth transistors and configured as a bit line.

19. A method for forming devices, comprising:
forming, on a first side of a substrate, a first active region extending along a first lateral direction;
forming, on the first side of the substrate, a second active region extending along the first lateral direction;
forming, on the first side of the substrate, a first gate structure extending along a second lateral direction and traversing the first and second active regions;
forming, on the first side of the substrate, a second gate structure extending along the second lateral direction and traversing the first and second active regions;
forming, on the first side of the substrate and vertically above the first active region, a third active region extending in the first lateral direction;
forming, on the first side of the substrate and vertically above the second active region, a fourth active region extending along the first lateral direction;
forming, on the first side of the substrate and vertically above the first gate structure, a third gate structure extending along the second lateral direction; and
forming, on the first side of the substrate and vertically above the second gate structure, a fourth gate structure extending along the second lateral direction;
wherein the first to second active regions and the first to second gate structures operatively form first, second, third, and fourth transistors of a memory cell that have a first conductivity, and the third to fourth active regions and the third to fourth gate structures operatively form fifth and sixth transistors of the memory cell that have a second conductivity.

20. The method of claim 19, further comprising:
forming, on the first side of the substrate over the fifth to sixth transistors, a plurality of first interconnect structures, wherein each of the plurality of first interconnect structures is coupled at least to the fifth and sixth transistors and configured to carry a supply voltage;
forming, on a second side of the substrate, a plurality of second interconnect structures, wherein each of the plurality of second interconnect structures is coupled at least to the first and second transistors and configured to carry a ground voltage; and
forming, on the second side of the substrate, a plurality of third interconnect structures, wherein each of the plurality of third interconnect structures is coupled at least to the third and fourth transistors and configured as a bit line.
